(19) United States
(12) Patent Application Publication
(10) Pub. No.: US 2026/0003282 A1
(43) Pub. Date: Jan. 1, 2026

(54) PHOTOSENSITIVE COMPOSITION, AND METHOD FOR PRODUCING PATTERNED CURED FILM

(71) Applicant: TOKYO OHKA KOGYO CO., LTD., Kawasaki-shi (JP)

(72) Inventors: Tomotaka Yamada, Kawasaki-shi (JP); Keiichi Ibata, Kawasaki-shi (JP); Masaru Takeshita, Kawasaki-shi (JP)

(21) Appl. No.: 19/226,515

(22) Filed: Jun. 3, 2025

(30) Foreign Application Priority Data
Jun. 26, 2024 (JP) 2024-103332
Apr. 15, 2025 (JP) 2025-067105

(51) Int. Cl. G03F 7/075; G03F 7/00; G03F 7/004

(52) U.S. Cl. CPC G03F 7/0757; G03F 7/0045; G03F 7/0046; G03F 7/70033

(57) ABSTRACT

A photosensitive composition having both etching resistance and good lithography properties, and capable of forming patterns with very small dimensions, and a method for producing a patterned cured film. The photosensitive composition includes a silicon-containing polymer including a phenolic hydroxy group, and an alkali-soluble group protected by an acid-dissociable group, and a photoacid generating agent, the photoacid generating agent including a photoacid generating agent having a sulfonium cation including an iodine atom.

### RELATED APPLICATION

The application claims priority to Japanese Patent Application No. 2024-103332, filed Jun. 26, 2024; and Japanese Patent Application No. 2025-067105, filed Apr. 15, 2025, the entire contents of which are incorporated herein by reference.

### BACKGROUND OF THE INVENTION

### Field of the Invention

The present invention relates to a photosensitive composition, and a method for producing a patterned cured film.

### Related Art

In the production of electronic components, a laminate obtained by forming a resist film on a substrate such as a silicon wafer using a resist material is subjected to a treatment including etching. For example, a treatment is carried out in which a resist pattern is formed on a resist film by selectively exposing the resist film, and dry etching is performed using the resist pattern as a mask to form a pattern on a substrate.

In recent years, in the production of semiconductor devices and liquid crystal display devices, advances in lithography techniques have led to rapid progress in the field of pattern miniaturization. As a method for miniaturizing a pattern, a wavelength of an exposure light source is generally shortened (energy is increased).

Resist materials are required to exhibit lithography properties such as sensitivity to these exposure light sources and resolution capable of reproducing patterns having very small dimensions.

As a resist material that satisfies these requirements, a chemically amplified resist composition which contains a base material component that exhibits changed solubility in a developing solution under action of an acid and an acid generation agent component to generate an acid upon exposure is conventionally used.

In a chemically amplified resist composition, a resin having a plurality of constituent units is generally used for improving lithography properties and the like. Furthermore, a chemically amplified resist composition obtained by using an acid diffusion control agent for controlling diffusion of the acid generated from the acid generation agent component upon exposure in combination with the acid generation agent component has been proposed.

In addition, the resist material is required to be a material having etching resistance in order to function as a mask for substrate processing. Therefore, from the viewpoint of etching resistance, a silicon-containing compound may be used as a base material component.

For example, Patent Document 1 discloses a resist composition containing a silicon-containing resin, an acid generation agent component, and a photodegradable base for controlling acid diffusion in order to deal with pattern miniaturization and etching processing. In [Examples] of Patent Document 1, a pattern on the order of several μm is formed by irradiation with KrF excimer laser, and a pattern of 50 nm is formed by drawing of electron beams.
Patent Document 1: Japanese Unexamined Patent Application, Publication No. 2022-59575

### SUMMARY OF THE INVENTION

With further progress in lithography technologies and expansion of application fields, pattern miniaturization is rapidly progressing. Accordingly, when a semiconductor device or the like is manufactured, a technology capable of forming a pattern having very small dimension in a good shape is required. For example, lithography using EUV (extreme ultraviolet) targets formation of fine patterns with more than 10 and less than 20 nanometers. In this way, as the pattern dimension is reduced, it becomes more difficult to achieve both etching resistance and lithography properties.

The present invention has been made in view of the above circumstances, and an object of the present invention is to provide a photosensitive composition satisfying both etching resistance and lithography properties and being capable of forming patterns with very small dimensions, and a method for producing a patterned cured film.

As a result of intensive studies to solve the above problems, the present inventors have found that the above problems can be solved by using a silicon-containing polymer having a phenolic hydroxy group and an alkali-soluble group protected by an acid-dissociable group, and a predetermined photoacid generating agent, and have completed the present invention. Specifically, the present invention provides the followings.

A first aspect is a photosensitive composition containing a silicon-containing polymer (A) including a phenolic hydroxy group and an alkali-soluble group protected by an acid-dissociable group, and a photoacid generating agent (B), the photoacid generating agent (B) including a photoacid generating agent (B1) including a sulfonium cation including an iodine atom.

A second aspect is a method for producing a patterned cured film, the method including:
forming a coating film made of the photosensitive composition according to the first aspect on a support,
exposing the coating film in a position-selective manner, and
developing the exposed coating film to form a patterned cured film.

The present invention can provide a photosensitive composition satisfying both etching resistance and lithography properties and being capable of forming patterns with very small dimensions, and a method for producing a patterned cured film.

### DETAILED DESCRIPTION OF THE INVENTION

Hereinafter, embodiments of the present invention will be described in detail, but the present invention is not limited to the following embodiments, and can be implemented with appropriate modifications within the scope of the object of the present invention.

### <<Photosensitive Composition>>

The photosensitive composition contains a silicon-containing polymer (A) including a phenolic hydroxy group, and an alkali-soluble group protected by an acid-dissociable group, and a photoacid generating agent (B). The photoacid generating agent (B) includes a photoacid generating agent (B1) including a sulfonium cation including an iodine atom. The photosensitive composition of this embodiment can exhibit excellent etching resistance and lithography properties regardless of whether photosensitive composition is a positive type or a negative type, but is more likely to exhibit properties when the photosensitive composition is used, in particular, as a positive-type photosensitive composition.

### <Silicon-Containing Polymer (A)>

A photosensitive composition contains a silicon-containing polymer (A) including a phenolic hydroxy group, and an alkali-soluble group protected by an acid-dissociable group. The silicon-containing polymer (A) includes a phenolic hydroxy group, an alkali-soluble group protected by an acid-dissociable group, and a silicon atom in the same polymer. Note here that the “acid-dissociable group” includes both (i) a group having an acid dissociable property in which the bond between the acid dissociable group and an atom adjacent to the acid dissociable group can be cleaved by the action of an acid; or (ii) a group in which the bond between the acid dissociable group and an atom adjacent to the acid dissociable group can be cleaved by decarboxylation reaction after cleaving of a part of the bond by the action of an acid.

Use of the silicon-containing polymer (A) can enhance etching resistance of a cured film formed by the photosensitive composition. Furthermore, by being affected by the action of acid generated from the photoacid generating agent (B) upon exposure, the acid-dissociable group in the silicon-containing polymer (A) dissociates, and an alkali-soluble group is generated. Thus, the silicon-containing polymer (A) exhibits solubility to an alkaline developing solution. Accordingly, when the photosensitive composition is exposed in a position-selective manner, the exposed part is soluble in the alkaline developing solution. Therefore, the photosensitive composition has photolithography properties capable of being patterned by position-selective exposure and development with an alkaline developing solution.

The content rate of silicon atoms in the silicon-containing polymer (A) is preferably 10% by mass or more and 30% by mass or less, and more preferably 15% by mass or more and 25% by mass or less with respect to the total mass of all the atoms constituting the silicon-containing polymer.

When content rate of silicon atoms in the silicon-containing polymer (A) is equal to or more than the lower limit value in the above-mentioned preferable range, a cured film having excellent etching resistance is easily formed. On the other hand, the content rate of silicon atoms is equal to or less than the upper limit value in the preferable range, the good lithography properties of the photosensitive composition are achieved.

The content rate of the silicon atom in the silicon-containing polymer (A) can be calculated by the following formula. Note here that the atomic mass to be used for the calculation of the following formula is the value obtained by rounding off to the second decimal place for atomic mass values corrected based on the isotope abundance ratio. The content rate (%) of silicon atoms calculated from the following formula is a value rounded off to the first decimal place.

Content rate (%) of silicon atoms=(number of silicon atoms present in silicon-containing polymer (A)×atomic mass of silicon atoms)/(the sum of the values obtained by multiplying the number of each atoms constituting silicon-containing polymer (A) by the atomic mass of each atom)×100

For example, in the case of a polysiloxane consisting of a repeating structure of a constituent unit represented by —[Si(H)O_{3/2}]—, the content rate of the silicon atom is [(28.09×1)/{(28.09× 1)+ (16.00×1.5)+ (1.01× 1)}×100]≈52.9%.

Preferable examples of the silicon-containing polymer (A) include, polysilane, and polysiloxane. As the silicon-containing polymer (A), polysiloxane is preferable, and polysiloxane including a silsesquioxane unit is more preferable.

The silicon-containing polymer (A) will be described below using polysiloxane as an example.

Polysiloxane is not particularly limited as long as it is resin having a main chain consisting of siloxane bond (Si—O—Si). The polysiloxane may be a linear polysiloxane, a branched polysiloxane, or a silsesquioxane. The silsesquioxane may be any of cage silsesquioxane, incomplete cage silsesquioxane, ladder silsesquioxane, and random silsesquioxane. The polysiloxane may have a combination of a linear polysiloxane skeleton and/or a branched polysiloxane skeleton and a silsesquioxane skeleton.

[Constituent Unit (a1)]

Polysiloxane preferably includes a constituent unit (a1) represented by the following formula (a1).

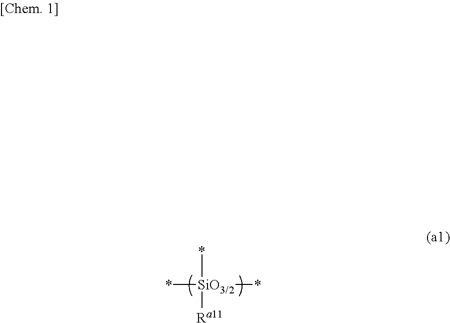

(In the formula (a1), R^{a11} is an organic group including a phenolic hydroxy group, and * represents a bonding.)

The number of carbon atoms in the organic group for R^{a11} is preferably 6 or more and 40 or less, more preferably 6 or more and 20 or less, and further preferably 6 or more and 10 or less.

Preferable examples of the organic group for R^{a11} include a hydrocarbon group including a phenolic hydroxy group. Note here that a hydrocarbon group including a phenolic hydroxy group is a hydrocarbon group including an aromatic hydrocarbon group in which the aromatic hydrocarbon group described above is substituted with one or more hydroxy groups.

The aromatic hydrocarbon group herein is a group consisting of only an aromatic hydrocarbon ring or two or more aromatic hydrocarbon rings linked via a single bond. The aromatic hydrocarbon ring may be a monocyclic ring or a condensed ring obtained by condensing two or more rings. Specific examples of aromatic hydrocarbon rings constituting the aromatic hydrocarbon group include a benzene ring, a fluorene ring, a naphthalene ring, an anthracene ring, a phenanthrene ring, a biphenyl ring, and the like.

The hydrocarbon group including the aromatic hydrocarbon group may consist only of the aromatic hydrocarbon group or may be a combination of the aromatic hydrocarbon group and the aliphatic hydrocarbon group. The aliphatic hydrocarbon group may be a saturated aliphatic hydrocarbon group or an unsaturated aliphatic hydrocarbon group, and the saturated aliphatic hydrocarbon group is preferable.

Examples of the hydrocarbon group constituting the hydrocarbon group having the phenolic hydroxy group include a group obtained by removing one hydrogen atom from the above aromatic hydrocarbon ring and a group obtained by substituting one hydrogen atom of the above aromatic hydrocarbon ring with an alkylene group. The number of carbon atoms of the alkylene group for substituting a hydrogen atom on the aromatic hydrocarbon ring is preferably 1 or more and 4 or less, more preferably 1 or more and 2 or less, and particularly preferably 1.

The group obtained by removing one hydrogen atom from the aromatic hydrocarbon ring is an aromatic hydrocarbon group (an aryl group). Suitable specific examples of the aromatic hydrocarbon group include a phenyl group, a naphthalene-1-yl group, and naphthalene-2-yl group. A group in which one of the hydrogen atoms of an aromatic hydrocarbon ring is substituted with an alkylene group is an aralkyl group. Suitable specific examples of the aralkyl group include a benzyl group, a phenethyl group, a naphthalene-1-yl methyl group, a naphthalene-2-yl methyl group, a 2-(naphthalene-1-yl)ethyl group, and a 2-(naphthalene-2-yl)ethyl group.

When R^{a11} is an organic group including a phenolic hydroxy group, the organic group may consist only of an aromatic group or may be a combination of an aromatic group and an aliphatic group. The aromatic group may be an aromatic hydrocarbon group or an aromatic heterocyclic group. The aliphatic group may be a chain aliphatic group, a cyclic aliphatic group, or a combination of a chain aliphatic group and a cyclic aliphatic group. When the aliphatic group is a cyclic aliphatic group, the cyclic aliphatic group may form a condensed ring with an aromatic group.

When R^{a11} is an organic group including a phenolic hydroxy group, the organic group may have a substituent on an aromatic group or on an aliphatic group. Examples of the substituent include a carboxy group, a hydroxy group, an amino group, a sulfo group, a halogen atom, a halogenated alkyl group, an alkoxy group, an alkyloxycarbonyl group, a nitro group, and the like.

When R^{a11} is an organic group having a phenolic hydroxy group, the aliphatic group may include a bond including a hetero atom such as —O—, —C(═O)—O—, —C(═O)—, —O—C(═O)—O—, —C(═O)—NH—, —NH—, ═N—, —NH—C(═NH)—, —S—, —S(═O)₂—, —S(═O)₂—O—, and combinations of two or more selected from these. H in the heteroatom-containing bond may be substituted with an alkyl group such as a methyl group or an ethyl group, or an acyl group such as an acetyl group, a propionyl group or a benzoyl group.

For the constituent unit (a1), the constituent unit (a1-1) represented by the following formula (a1-1) is preferable.

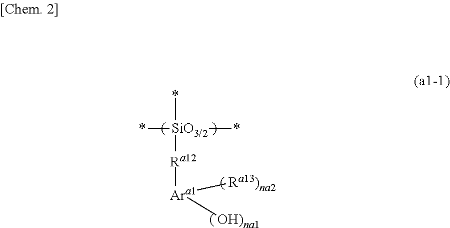

(In the formula (a1-1), Ar^{a1} represents an aromatic hydrocarbon group, R^{a12} represents a single bond, or a divalent linking group, R^{a13} represents a hydrocarbon group having 1 or more and 6 or less carbon atoms, or a halogen atom, na1 represents an integer of 1 or more and 3 or less, na2 represents an integer of 0 or more and 4 or less, and * represents a bonding.)

Ar^{a1} represents a (na1+na2+1)-valent aromatic hydrocarbon group. The aromatic hydrocarbon group for Ar^{a1} may be a monocyclic aromatic hydrocarbon group or a polycyclic aromatic hydrocarbon group. The polycyclic aromatic hydrocarbon group may be a group in which two or more aromatic rings are condensed to a monocyclic aromatic hydrocarbon group, or a group in which one or more aromatic hydrocarbon groups are bonded to a monocyclic aromatic hydrocarbon group, or a group in which two or more aromatic rings are condensed to a monocyclic aromatic hydrocarbon group via a single bond. The number of carbon atoms of the aromatic hydrocarbon group is preferably 6 or more and 30 or less, more preferably 6 or more and 20 or less, further preferably 6 or more and 15 or less, and particularly preferably 6 or more and 12 or less.

Examples of aromatic rings constituting the aromatic hydrocarbon group include a benzene ring, a naphthalene ring, a biphenyl ring, an anthracene ring, a phenanthrene ring, and the like. Among them, a benzene ring and a naphthalene ring are preferable, and a benzene ring is more preferable.

Examples of the divalent linking group as R^{a12} include divalent hydrocarbon groups which may have a substituent.

The hydrocarbon group as R^{a12} may be an aliphatic hydrocarbon group, or a combination of an aliphatic hydrocarbon group and an aromatic hydrocarbon group. Note here that R^{a12} is not an aromatic hydrocarbon group. It is because the aromatic hydrocarbon group as R^{a12} constitutes a part of the aromatic hydrocarbon group as Ar^{a1} if R^{a12} were an aromatic hydrocarbon group.

The aliphatic hydrocarbon group as R^{a12} may be a saturated aliphatic hydrocarbon group, or may be an unsaturated aliphatic hydrocarbon group. A saturated aliphatic hydrocarbon group is preferable.

The aliphatic hydrocarbon group as R^{a12} may be a chain aliphatic hydrocarbon group, or an alicyclic hydrocarbon group, or a combination of a chain aliphatic hydrocarbon group and an alicyclic hydrocarbon group. The chain aliphatic hydrocarbon group included in the aliphatic hydrocarbon group as R^{a12} may be linear or branched.

The number of carbon atoms of the linear aliphatic hydrocarbon group is preferably 1 or more and 10 or less, more preferably 1 or more and 6 or less, further preferably 1 or more and 4 or less, and the most preferably 1 or more and 3 or less.

The linear aliphatic hydrocarbon group is preferably a linear alkylene group. Specific examples include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], and the like.

The number of carbon atoms of the branched aliphatic hydrocarbon group is preferably 2 or more and 10 or less, more preferably 2 or more and 6 or less, and further preferably 2 or 3.

The branched aliphatic hydrocarbon group is preferably a alkylalkylene group including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃) CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; alkyltetramethylene groups such as —CH(CH₃)CH₂CH₂CH₂—, and —CH₂CH(CH₃)CH₂CH₂—, and the like. Preferable the alkyl groups in the alkylalkylene group include a linear alkyl group having a number of carbon atoms 1 or more and 5 or less.

The linear, or branched aliphatic hydrocarbon group may include a substituent. Examples of the substituent include a fluorine atom, a fluorinated alkyl group having 1 or more and 5 or less carbon atoms substituted with a fluorine atom, and the like.

In the linear or branched aliphatic hydrocarbon group, at least a part of the methylene group may be substituted with a divalent group other than the methylene group. Examples of the divalent groups include —O—, —S—, —C(═O)—, and the like.

The number of carbon atoms of the alicyclic hydrocarbon group is preferably 3 or more and 20 or less, and more preferably 3 or more and 12 or less.

The alicyclic hydrocarbon group may be a polycyclic group, or may be a monocyclic group. As the monocyclic aliphatic hydrocarbon group, a group obtained by removing two hydrogen atoms from a monocycloalkane is preferable. The number of carbon atoms of the monocycloalkane is preferably 3 or more and 6 or less. Specific examples of the monocycloalkane include cyclopentane, cyclohexane, and the like. The polycyclic aliphatic hydrocarbon group is preferably a group obtained by removing two hydrogen atoms from a polycycloalkane. The number of carbon atoms of the polycycloalkane is preferably 7 or more and 12 or less. Specific examples of the polycycloalkane include adamantane, norbornane, isobornane, tricyclodecane, tetracyclododecane, and the like.

The alicyclic hydrocarbon group may or may not have a substituent. Examples of the substituent include an alkyl group, an alkoxy group, a halogen atom, a halogenated alkyl group, and a hydroxy group.

The alkyl group as the above substituent is preferably an alkyl group having 1 or more and 5 or less carbon atoms, and more preferably a methyl group, an ethyl group, an n-propyl group, an n-butyl group, and a tert-butyl group.

The alkoxy group as the above substituent is preferably an alkoxy group having 1 or more and 5 or less carbon atoms, more preferably a methoxy group, an ethoxy group, an n-propyloxy group, an isopropyloxy group, an n-butyloxy group, and a tert-butyloxy group, and further preferably a methoxy group and an ethoxy group.

The halogen atom as the above substituent is preferably a fluorine atom.

Examples of the halogenated alkyl group as the above substituent include a group in which a part or all of the hydrogen atoms of the above alkyl group are substituted with the above halogen atom.

In the alicyclic hydrocarbon group, a part of the carbon atoms constituting the ring structure may be substituted with a group including a heteroatom. The group including the heteroatom is preferably —O—, —C(═O)—O—, —S—, —S(═O)₂—, and —S(═O)₂—O—.

R^{a12} is preferably a single bond, or a linear or branched aliphatic hydrocarbon group which may have a substituent, more preferably a single bond, or a linear or branched aliphatic hydrocarbon group, and further preferably a linear or branched aliphatic hydrocarbon group. The linear or branched aliphatic hydrocarbon group is preferably an alkylene group having 1 or more and 6 or less carbon atoms, more preferably an alkylene group having 1 or more and 5 or less carbon atoms, further preferably a methylene group, an ethylene group, a propane-1,3-diyl group, a propane-2,2-diyl group, and a propane-1,2-diyl group, particularly preferably a methylene group and an ethylene group, and most preferably a methylene group.

The hydrocarbon group as R^{a13} may be any of a linear hydrocarbon group, a branched hydrocarbon group, a cyclic hydrocarbon group, and a combination of two or more of these, and is preferably a linear hydrocarbon group and a branched hydrocarbon group. The hydrocarbon group as R^{a13} may be a saturated hydrocarbon group or an unsaturated hydrocarbon group, and preferably a saturated hydrocarbon group.

The number of carbon atoms of the hydrocarbon group as R^{a13} is preferably 1 or more and 5 or less. The hydrocarbon group as R^{a13} is preferably a methyl group, an ethyl group, an n-propyl group, and an isopropyl group, further preferably a methyl group and an ethyl group, and particularly preferably a methyl group.

It is favorable that na1 is 1.

It is favorable that na2 is an integer of 0 or more and 2 or less, more preferably 0 or 1, and further preferably 0.

Specific examples of the constituent unit (a1-1) are shown below.

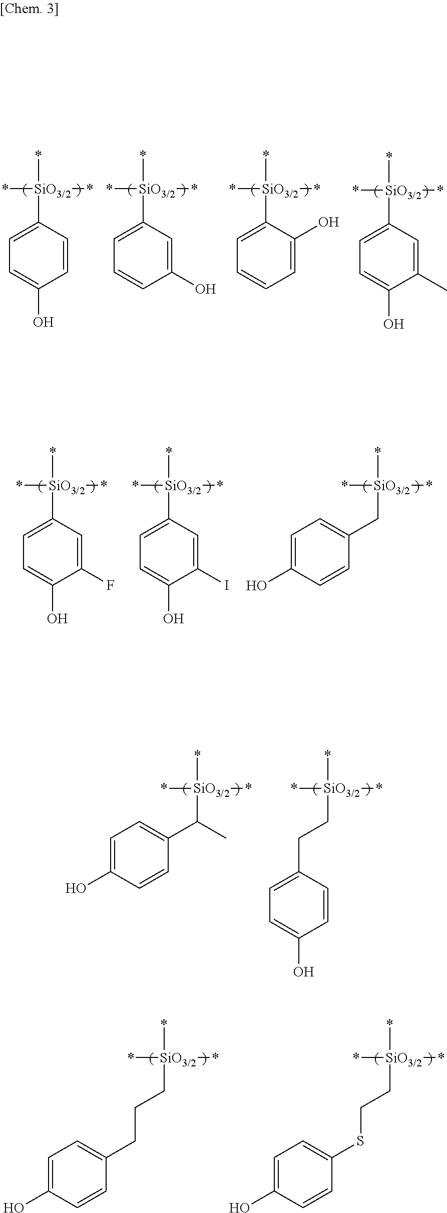

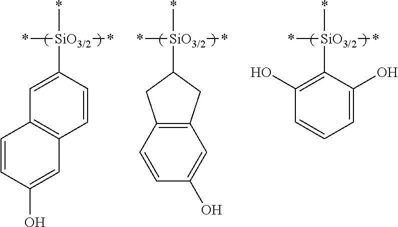

One kind of the constituent unit (a1-1) of the polysiloxane may be used, or two or more kinds thereof may be used. A proportion of the constituent unit (a1-1) in the polysiloxane is preferably 10 mol % or more, more preferably 20 mol % or more, and further preferably 30 mol % or more with respect to the total (100 mol %) of all constituent units constituting the polysiloxane. The above proportion is preferably 80 mol % or less, more preferably 75 mol % or less, and further preferably 70 mol % or less. When the proportion of the constituent unit (a1-1) is in the above-mentioned range, patterned resin films having excellent lithography properties of photosensitive composition and excellent etching resistance are easily formed.

[Constituent Unit (a2)]

Polysiloxane preferably includes a constituent unit (a2) represented by the following formula (a2).

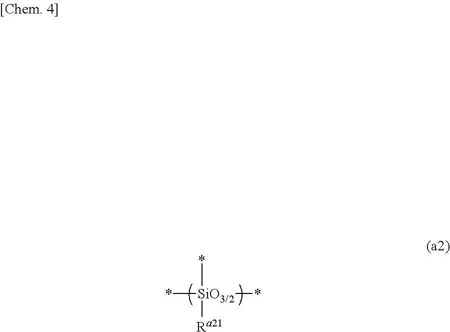

(In the formula (a2), R^{a21} is an organic group having an alkali-soluble group protected by an acid-dissociable group, and * represents a bonding.)

R^{a21} is preferably a group represented by the following formula (a2-1), or a group represented by the following formula (a2-2).

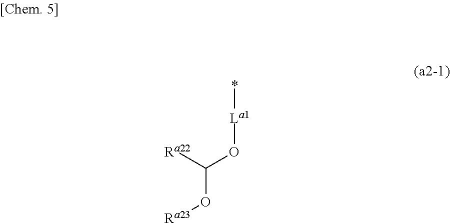

(In the formula (a2-1), L^{a1} is a single bond or a divalent organic group, R^{a22} is a hydrogen atom, or a hydrocarbon group which may have a substituent, R^{a23} is a hydrogen atom, or a hydrocarbon group which may have a substituent, R^{a22} and R^{a23} may be bonded to each other to form a ring, and * represents a bonding.)

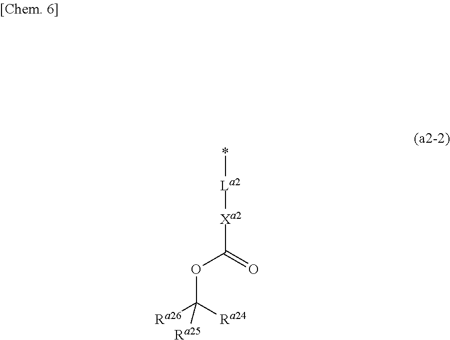

(In the formula (a2-2), L^{a2} is a single bond, or a divalent organic group, X^{a2} is a single bond or 0, R^{a24}, R^{a25}, and R^{a26} each independently represent a hydrocarbon group, two or more of R^{a24}, R^{a25}, and R^{a26} may be bonded to each other to form a ring, and * represents a bonding.)
(Group Represented by the Formula (a2-1))

The divalent organic group as L^{a1} includes a divalent hydrocarbon group which may include a substituent. The hydrocarbon group as L^{a1} may be an aliphatic hydrocarbon group, an aromatic hydrocarbon group, or a combination of an aliphatic hydrocarbon group and an aromatic hydrocarbon group.

The aliphatic hydrocarbon group as L^{a1} may be a saturated aliphatic hydrocarbon group or may be an unsaturated aliphatic hydrocarbon group, and is preferably a saturated aliphatic hydrocarbon group.

The aliphatic hydrocarbon group as L^{a1} may be a chain aliphatic hydrocarbon group, or an alicyclic hydrocarbon group, or a combination of a chain aliphatic hydrocarbon group and an alicyclic hydrocarbon group. The chain aliphatic hydrocarbon group included in the aliphatic hydrocarbon group as L^{a1} may be linear or branched.

The number of carbon atoms of the linear aliphatic hydrocarbon group is preferably 1 or more and 10 or less, more preferably 1 or more and 6 or less, further preferably 1 or more and 4 or less, and the most preferably 1 or more and 3 or less.

The linear aliphatic hydrocarbon group is preferably a linear alkylene group. Specific examples include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], and the like.

The number of carbon atoms of the branched aliphatic hydrocarbon group is preferably 2 or more and 10 or less, more preferably 2 or more and 6 or less, and further preferably 2 or 3.

The branched aliphatic hydrocarbon group is preferably a branched alkylene group. Specific examples include alkylalkylene group including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃) CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; alkyltetramethylene groups such as —CH(CH₃)CH₂CH₂CH₂—, and —CH₂CH(CH₃)CH₂CH₂—, and the like. Preferable the alkyl groups in the alkylalkylene group include a linear alkyl group having a number of carbon atoms 1 or more and 5 or less.

The linear, or branched aliphatic hydrocarbon group may include a substituent. Examples of the substituent include a fluorine atom, a fluorinated alkyl group having 1 or more and 5 or less carbon atoms substituted with a fluorine atom, and the like.

In the linear or branched aliphatic hydrocarbon group, at least a part of the methylene group may be substituted with a divalent group other than the methylene group. Examples of the divalent groups include —O—, —S—, —C(═O)—, and the like.

The aromatic hydrocarbon group as L^{a1} may be a monocyclic aromatic hydrocarbon group, or may be a polycyclic aromatic hydrocarbon group. The polycyclic aromatic hydrocarbon group may be a group in which two or more aromatic rings are condensed to a monocyclic aromatic hydrocarbon group, or a group in which one or more aromatic hydrocarbon groups are bonded to a monocyclic aromatic hydrocarbon group, or a group in which two or more aromatic rings are condensed to a monocyclic aromatic hydrocarbon group, via a single bond. The number of carbon atoms of the aromatic hydrocarbon group is preferably 6 or more and 30 or less, more preferably 6 or more and 20 or less, further preferably 6 or more and 15 or less, and particularly preferably 6 or more and 12 or less.

Examples of aromatic rings constituting the aromatic hydrocarbon group include a benzene ring, a naphthalene ring, a biphenyl ring, an anthracene ring, a phenanthrene ring, and the like. Among them, a benzene ring, a naphthalene ring, and a biphenyl ring are preferable, and a benzene ring is more preferable.

The aromatic hydrocarbon group may or may not have a substituent. Examples of the substituent include an alkyl group, an alkoxy group, a halogen atom, a halogenated alkyl group, and a hydroxy group.

L^{a1} is preferably a single bond or a group represented by the following formula (a2-1a).

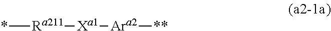

(In the formula (a2-1a), R^{a211} is a single bond, or an alkylene group, X^{a1} is a single bond, O, or S, Ar^{a2} is an aromatic hydrocarbon group which may include a substituent, * is a bonding to Si in the formula (a2), and ** is a bonding to O in the formula (a2-1).)

The number of carbon atoms of the alkylene group as R^{a211} is preferably 1 or more and 10 or less, more preferably 1 or more and 5 or less, and further preferably 1 or more and 3 or less.

The alkylene group as R^{a211} may be linear or branched, and preferably linear.

X^{a1} is preferably a single bond.

The aromatic hydrocarbon group as Ar^{a2} may be a monocyclic aromatic hydrocarbon group, or may be a polycyclic aromatic hydrocarbon group. The polycyclic aromatic hydrocarbon group may be a group in which two or more aromatic rings are condensed to a monocyclic aromatic hydrocarbon group, or may be a group in which one or more aromatic hydrocarbon groups are bonded to a monocyclic aromatic hydrocarbon group or a group in which two or more aromatic rings are condensed to a monocyclic aromatic hydrocarbon group, via a single bond. The number of carbon atoms of the aromatic hydrocarbon group is preferably 6 or more and 30 or less, more preferably 6 or more and 20 or less, further preferably 6 or more and 15 or less, and particularly preferably 6 or more and 12 or less.

Examples of aromatic rings constituting the aromatic hydrocarbon group include a benzene ring, a naphthalene ring, a biphenyl ring, an anthracene ring, a phenanthrene ring, and the like. Among them, a benzene ring, a naphthalene ring, and a biphenyl ring are preferable, and a benzene ring is more preferable.

The hydrocarbon group as R^{a22} is preferably an alkyl group. The number of carbon atoms of the alkyl group is preferably 1 or more and 10 or less, and preferably 1 or more and 5 or less. Examples of the alkyl group include a methyl group, an ethyl group, an n-propyl group, an isopropyl group, and the like.

R^{a22} is preferably a hydrogen atom, or an alkyl group having 1 or more and 5 or less carbon atoms, and more preferably a hydrogen atom, or a methyl group.

The hydrocarbon group as R^{a23} is preferably an alkyl group. The number of carbon atoms of the alkyl group is preferably 1 or more and 10 or less, more preferably 1 or more and 5 or less. Examples of the alkyl group include a methyl group, an ethyl group, an n-propyl group, and an isopropyl group, and the like.

As R^{a23}, an alkyl group having 1 or more and 5 or less carbon atoms is preferable, and a methyl group, or an ethyl group is more preferable.

Examples of the substituent which may be included by the hydrocarbon group for R^{a22} and R^{a23} include a halogen atom, a hydroxy group, and the like.

As the ring formed by bonding of R^{a22} and R^{a23}, rings with 4 members or more and 7 members or less are preferable, and rings with 4 members or more and 6 members or less are more preferable. Specific examples of the ring formed include, for example, a tetrahydropyran ring, a tetrahydrofuran ring, and the like.

Hereinafter, specific examples of the group represented by the formula (a2-1) are described.

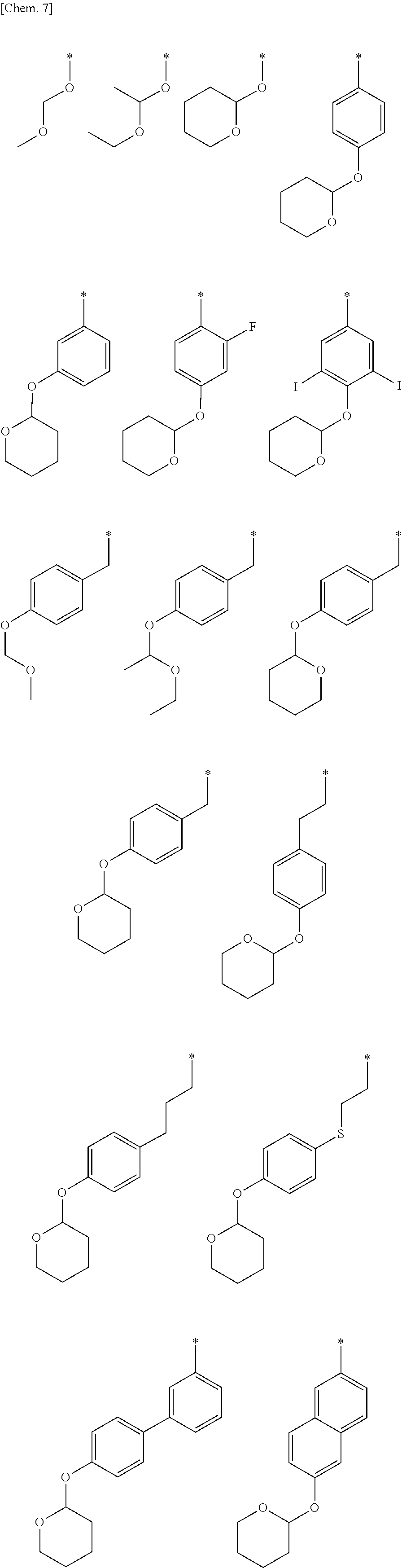

(Group Represented by the Formula (a2-2))

Examples of divalent organic group for L^{a2} include a divalent hydrocarbon group which may include a substituent.

The hydrocarbon group for L^{a2} may be an aliphatic hydrocarbon group, an aromatic hydrocarbon group, or a combination of an aliphatic hydrocarbon group and an aromatic hydrocarbon group.

The aliphatic hydrocarbon group as L^{a2} may be a saturated aliphatic hydrocarbon group or may be an unsaturated aliphatic hydrocarbon group, and is preferably a saturated aliphatic hydrocarbon group.

The aliphatic hydrocarbon group as L^{a2} may be a chain aliphatic hydrocarbon group, an alicyclic hydrocarbon group, or a combination of a chain aliphatic hydrocarbon group and an alicyclic hydrocarbon group. The chain aliphatic hydrocarbon group included in the aliphatic hydrocarbon group as L^{a2} may be linear or branched.

The number of carbon atoms of the linear aliphatic hydrocarbon group is preferably 1 or more and 10 or less, more preferably 1 or more and 6 or less, further preferably 1 or more and 4 or less, and the most preferably 1 or more and 3 or less. The linear aliphatic hydrocarbon group is preferably a linear alkylene group. Specific examples include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], and the like.

The number of carbon atoms of the branched aliphatic hydrocarbon group is preferably 2 or more and 10 or less, more preferably 2 or more and 6 or less, and further preferably 2 or 3.

The branched aliphatic hydrocarbon group is preferably a alkylalkylene group including alkylmethylene groups such as —CH(CH₃)—, —CH(CH₂CH₃)—, —C(CH₃)₂—, —C(CH₃) (CH₂CH₃)—, —C(CH₃)(CH₂CH₂CH₃)—, and —C(CH₂CH₃)₂—; alkylethylene groups such as —CH(CH₃)CH₂—, —CH(CH₃) CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; alkyltetramethylene groups such as —CH(CH₃)CH₂CH₂CH₂—, and —CH₂CH(CH₃)CH₂CH₂—, and the like. Preferable the alkyl groups in the alkylalkylene group include a linear alkyl group having a number of carbon atoms 1 or more and 5 or less.

The linear, or branched aliphatic hydrocarbon group may include a substituent. Examples of the substituent include a fluorine atom, a fluorinated alkyl group having 1 or more and 5 or less carbon atoms substituted with a fluorine atom, and the like.

In the linear or branched aliphatic hydrocarbon group, at least a part of the methylene group may be substituted with a divalent group other than the methylene group. Examples of the divalent groups include —O—, —S—, —C(═O)—, and the like.

The number of carbon atoms of the alicyclic hydrocarbon group as L^{a2} is preferably 3 or more and 20 or less, and more preferably 3 or more and 12 or less. The alicyclic hydrocarbon group may be a polycyclic group, or may be a monocyclic group. As the monocyclic aliphatic hydrocarbon group, a group obtained by removing two hydrogen atoms from a monocycloalkane is preferable. The number of carbon atoms of the monocycloalkane is preferably 3 or more and 6 or less. Specific examples of the monocycloalkane include cyclopentane, cyclohexane, and the like. The polycyclic aliphatic hydrocarbon group is preferably a group obtained by removing two hydrogen atoms from a polycycloalkane. The number of carbon atoms of the polycycloalkane is preferably 7 or more and 12 or less. Specific examples of the polycycloalkane include adamantane, norbornane, isobornane, tricyclodecane, tetracyclododecane, and the like.

The alicyclic hydrocarbon group may or may not have a substituent. Examples of the substituent include an alkyl group, an alkoxy group, a halogen atom, a halogenated alkyl group, and a hydroxy group.

The aromatic hydrocarbon group as L^{a2} may be a monocyclic aromatic hydrocarbon group, or may be a polycyclic aromatic hydrocarbon group. The polycyclic aromatic hydrocarbon group may be a group in which two or more aromatic rings are condensed to a monocyclic aromatic hydrocarbon group, or a group in which one or more aromatic hydrocarbon groups are bonded to a monocyclic aromatic hydrocarbon group, or a group in which two or more aromatic rings are condensed to a monocyclic aromatic hydrocarbon group, via a single bond. The number of carbon atoms of the aromatic hydrocarbon group is preferably 6 or more and 30 or less, more preferably 6 or more and 20 or less, further preferably 6 or more and 15 or less, and particularly preferably 6 or more and 12 or less.

Examples of aromatic rings constituting the aromatic hydrocarbon group include a benzene ring, a naphthalene ring, a biphenyl ring, an anthracene ring, a phenanthrene ring, and the like. Among them, a benzene ring, a naphthalene ring, and a biphenyl ring are preferable, and a benzene ring is more preferable.

The aromatic hydrocarbon group may or may not have a substituent. Examples of the substituent include an alkyl group, an alkoxy group, a halogen atom, a halogenated alkyl group, and a hydroxy group.

L^{a2} is preferably a single bond or a group represented by the following formula (a2-2a).

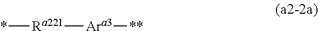

(In the formula (a2-1a), R^{a221} is a single bond, or an alkylene group, Ar^{a3} is an alicyclic hydrocarbon group which may have a substituent, or an aromatic hydrocarbon group which may have a substituent, * is a bonding to Si in the formula (a2), and * * is a bonding to X^{a2} in the formula (a2-2).)

The number of carbon atoms of the alkylene group as R^{a221} is preferably 1 or more and 10 or less, more preferably 1 or more and 5 or less, and further preferably 1 or more and 3 or less.

The alkylene group as R^{a211} may be linear or branched, and preferably linear.

The number of carbon atoms of the alicyclic hydrocarbon group as Ar^{a3} is preferably 3 or more and 20 or less, and more preferably 3 or more and 12 or less. The alicyclic hydrocarbon group may be a polycyclic group, or may be a monocyclic group. As the monocyclic aliphatic hydrocarbon group, a group obtained by removing two hydrogen atoms from a monocycloalkane is preferable. The number of carbon atoms of the monocycloalkane is preferably 3 or more and 6 or less. Specific examples of the monocycloalkane include cyclopentane, cyclohexane, and the like. The polycyclic aliphatic hydrocarbon group is preferably a group obtained by removing two hydrogen atoms from a polycycloalkane. The number of carbon atoms of the polycycloalkane is preferably 7 or more and 12 or less. Specific examples of the polycycloalkane include norbornane, isobornane, tricyclodecane, tetracyclododecane, and the like. Among these, adamantane, or norbornane is preferable, and norbornane is more preferable.

The aromatic hydrocarbon group as Ar^{a3} may be a monocyclic aromatic hydrocarbon group, or may be a polycyclic aromatic hydrocarbon group. The polycyclic aromatic hydrocarbon group may be a group in which two or more aromatic rings are condensed to a monocyclic aromatic hydrocarbon group, or a group in which one or more aromatic hydrocarbon groups are bonded to a monocyclic aromatic hydrocarbon group, or a group in which two or more aromatic rings are condensed to a monocyclic aromatic hydrocarbon group, via a single bond. The number of carbon atoms of the aromatic hydrocarbon group is preferably 6 or more and 30 or less, more preferably 6 or more and 20 or less, further preferably 6 or more and 15 or less, and particularly preferably 6 or more and 12 or less.

Examples of aromatic rings constituting the aromatic hydrocarbon group include a benzene ring, a naphthalene ring, a biphenyl ring, an anthracene ring, a phenanthrene ring, and the like. Among them, a benzene ring, a naphthalene ring, and a biphenyl ring are preferable, and a benzene ring is more preferable.

Examples of the hydrocarbon group as R^{a24}, R^{a25}, and R^{a26} include an alkyl group, an alkenyl group, an alicyclic hydrocarbon group, an aromatic hydrocarbon group, and the like.

The number of carbon atoms of the alkyl group as R^{a24}, R^{a25} and R^{a26} is preferably 1 or more and 10 or less, and more preferably 1 or more and 5 or less. As the alkyl group, a linear alkyl group is preferable, a methyl group, or an ethyl group is more preferable, and a methyl group is further preferable.

The number of carbon atoms of the alkenyl group as R^{a24}, R^{a25}, and R^{a26} is preferably 1 or more and 10 or less, and more preferably 1 or more and 5 or less. As the alkenyl group, a linear alkenyl group is preferable, a vinyl group, or a propenyl group is more preferable, and a vinyl group is further preferable.

The number of carbon atoms of the alicyclic hydrocarbon group as R^{a24}, R^{a25}, and R^{a26} is preferably 3 or more and 20 or less, and more preferably 3 or more and 12 or less. The alicyclic hydrocarbon group may be a polycyclic group, or may be a monocyclic group. As the monocyclic aliphatic hydrocarbon group, a group obtained by removing two hydrogen atoms from a monocycloalkane is preferable. The number of carbon atoms of the monocycloalkane is preferably 3 or more and 6 or less. Specific examples of the monocycloalkane include cyclopentane, cyclohexane, and the like. The polycyclic aliphatic hydrocarbon group is preferably a group obtained by removing two hydrogen atoms from a polycycloalkane. The number of carbon atoms of the polycycloalkane is preferably 7 or more and 12 or less. Specific examples of the polycycloalkane include norbornane, isobornane, tricyclodecane, tetracyclododecane, and the like.

The aromatic hydrocarbon group as R^{a24}, R^{a25}, and R^{a26} may be a monocyclic aromatic hydrocarbon group, or may be a polycyclic aromatic hydrocarbon group. The polycyclic aromatic hydrocarbon group may be a group in which two or more aromatic rings are condensed to a monocyclic aromatic hydrocarbon group, or a group in which one or more aromatic hydrocarbon groups are bonded to a monocyclic aromatic hydrocarbon group, or a group in which two or more aromatic rings are condensed to a monocyclic aromatic hydrocarbon group, via a single bond. The number of carbon atoms of the aromatic hydrocarbon group is preferably 6 or more and 30 or less, more preferably 6 or more and 20 or less, further preferably 6 or more and 15 or less, and particularly preferably 6 or more and 12 or less.

Examples of aromatic rings constituting the aromatic hydrocarbon group include a benzene ring, a naphthalene ring, a biphenyl ring, an anthracene ring, a phenanthrene ring, and the like. Among them, a benzene ring, a naphthalene ring, and a biphenyl ring are preferable, and a benzene ring is more preferable.

When R^{a24}, R^{a25}, and R^{a26} are not bonded to each other to forma ring, these groups are preferably an alkyl group having 1 or more and 5 or less carbon atoms, more preferably a methyl group, or an ethyl group, and further preferably a methyl group.

Two or more of R^{a24}, R^{a25}, and R^{a26} may be bonded to each other to form a ring. For example, R^{a24}, and R^{a25} may be bonded to each other to form an alicyclic hydrocarbon group having 5 or more and 20 or less carbon atoms together with the carbon atoms to which they are bonded. The alicyclic hydrocarbon group may be a polycyclic group, or a monocyclic group. As the monocyclic aliphatic hydrocarbon group, a group obtained by removing two hydrogen atoms from a monocycloalkane is preferable. The number of carbon atoms of the monocycloalkane is preferably 3 or more and 6 or less. Specific examples of the monocycloalkane include cyclopentane, cyclohexane, and the like. The polycyclic aliphatic hydrocarbon group is preferably a group obtained by removing two hydrogen atoms from a polycycloalkane. The number of carbon atoms of the polycycloalkane is preferably 7 or more and 12 or less. Specific examples of the polycycloalkane include norbornane, isobornane, tricyclodecane, tetracyclododecane, and the like. Among these, a group obtained by removing one hydrogen atom from cyclohexane or cyclopentane is preferable.

Hereinafter, specific examples of the group represented by the formula (a2-2) are shown.

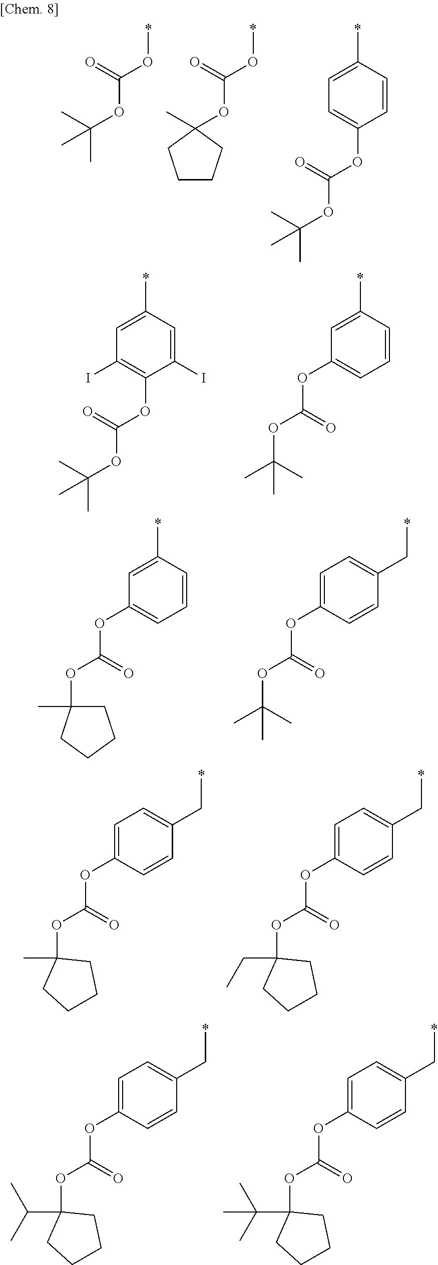

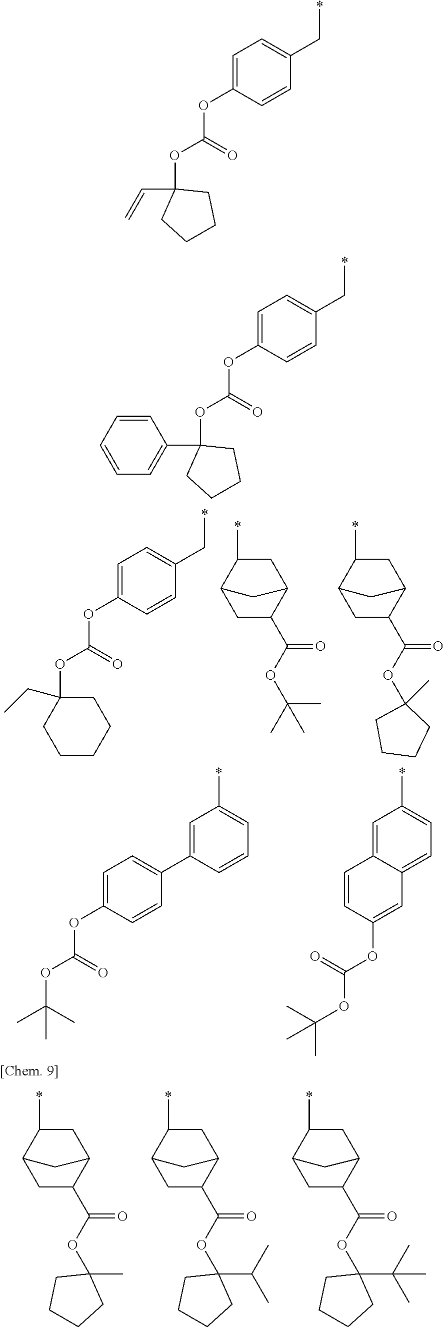

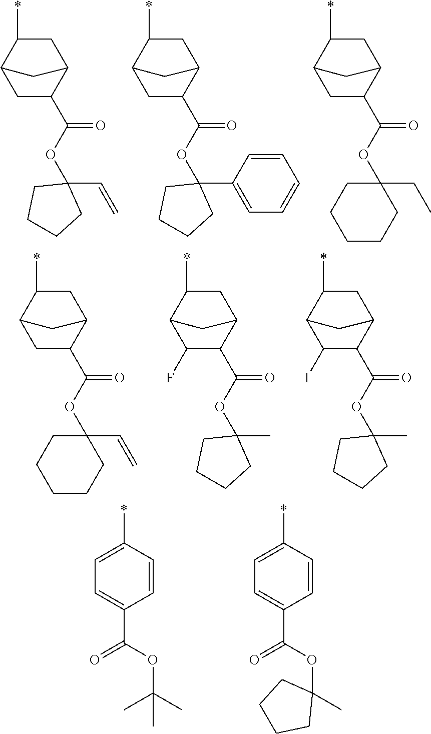

One kind of the constituent unit (a2) of the polysiloxane may be used, or two or more kinds thereof may be used.

A proportion of the constituent unit (a2) in the polysiloxane is preferably 5 mol % or more, more preferably 10 mols or more, and further preferably 15 mol % or more, with respect to the total (100 mol %) of all constituent units constituting the polysiloxane. The above proportion is preferably 60 mol % or less, more preferably 50 mol % or less, and further preferably 40 mol % or less. When the proportion of the constituent unit (a2) is in the above-mentioned range, patterned resin films having good lithography properties of photosensitive composition and excellent etching resistance can be formed.

### [Other Constituent Units]

Polysiloxane may include other constituent units in addition to the constituent unit (a1), and the constituent unit (a2).

Examples of the other constituent unit include constituent unit (a3) represented by the formula (a3-1) or the formula (a3-2), constituent unit (a4) represented by the formula (a4-1) or the formula (a4-2), and constituent unit (a5) represented by the formula (a5), and the like.

(Constituent Unit (a3))

The constituent unit (a3) is a constituent unit represented by the following formula (a3-1) or the following formula (a3-2).

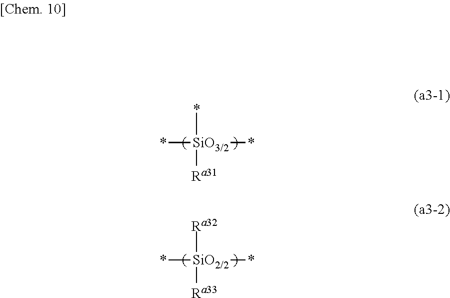

(In the formula, R^{a31} to R^{a33} each independently represent a hydrogen atom, or an aliphatic hydrocarbon group which may have a substituent and having 1 or more and 10 or less carbon atoms, and * represents a bonding.)

When the constituent unit (a3) is included, properties of the cured film formed by using a photosensitive composition can be easily controlled.

In the formula (a3-1) and the formula (a3-2), the aliphatic hydrocarbon group for R^{a31} to R^{a33} may be a saturated aliphatic hydrocarbon group or may be an unsaturated aliphatic hydrocarbon group. The structure of the aliphatic hydrocarbon group may be any of linear, branched, cyclic, or a combination of these structures.

The aliphatic hydrocarbon group as R^{a31} to R^{a33} may have a substituent. Examples of the substituent include a hydroxy group, an alkoxy group having 1 or more and 5 or less carbon atoms, a mercapto group, and an amino group, and the like.

As R^{a31} to R^{a33}, a hydrogen atom, an alkyl group, and an alkenyl group are preferable.

The number of carbon atoms of the alkyl group for R^{a31} to R^{a33} is preferably 1 or more and 5 or less, and more preferably 1 or more and 3 or less.

Examples of the alkyl groups for R^{a31} to R^{a33} include a methyl group, an ethyl group, an n-propyl group, an n-butyl group, an n-pentyl group, an n-hexyl group, an n-octyl group, an n-decyl group, an isopropyl group, an isobutyl group, a sec-butyl group, a tert-butyl group, a 2-ethylhexyl group, and the like. Among them, a methyl group, an ethyl group, an n-propyl group, an n-butyl group, an n-pentyl group, an isopropyl group, an isobutyl group, a sec-butyl group, and a tert-butyl is preferable, a methyl group, an ethyl group, an n-propyl group, and an isopropyl group are more preferable, a methyl group, and an ethyl group are further preferred, and a methyl group is particularly preferred.

As the alkenyl group for R^{a31} to R^{a33}, the number of carbon atoms is preferably 2 or more and 5 or less, and more preferably 2, or 3.

As the alkenyl group for R^{a31} to R^{a33}, a vinyl group, and an allyl group are preferable.

One kind of the constituent unit (a3) of the polysiloxane may be used, or two or more kinds thereof may be used.

When the polysiloxane includes the constituent unit (a3) in addition to the constituent unit (a1), and the constituent unit (a2), a proportion of the constituent unit (a3) is preferably, for example, 10 mol % or more and 60 mol % or less, more preferably 20 mol % or more and 55 mol % or less, and further preferably 30 mol % or more and 50 mol % or less with respect to the total (100 mol %) of all the constituent units constituting the polysiloxane.

When the proportion of the constituent unit (a3) is equal to or more than the lower limit of the above-mentioned preferable range, a patterned resin film with particularly excellent etching resistance is easily formed. Furthermore, when the above-mentioned proportion is equal to or less than the upper limit of the above-mentioned preferable range, a photosensitive composition with excellent lithography properties is obtained.

(Constituent Unit (a4))

The constituent unit (a4) is a constituent unit represented by the following formula (a4-1) or the following formula (a4-2). The constituent unit (a4) is useful for improving lithography properties. With introduction of the constituent unit (a4), the dissolution rate is easily controlled.

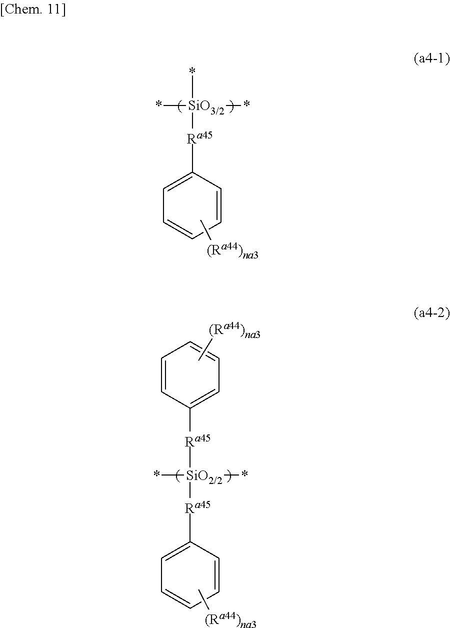

(In the formula (a4-1), and the formula (a4-2), R^{a44} represents a hydrocarbon group having 1 or more and 6 or less carbon atoms, an alkoxy group having 1 or more and 6 or less carbon atoms, and R^{a45} represents a single bond or a divalent linking group. na3 represents an integer of 0 or more and 5 or less, and * represents a bonding.)

The hydrocarbon group for R^{a44} may be linear or branched. Furthermore, the hydrocarbon group for R^{a44} may be a saturated hydrocarbon group, or an unsaturated hydrocarbon group, and is preferably a saturated hydrocarbon group.

The number of carbon atoms in the hydrocarbon group for R^{a44} is preferably 1 or more and 5 or less, and more preferably 1 or more and 3 or less. The hydrocarbon group for R^{a44} is preferably an alkyl group. Examples of the alkyl group include a methyl group, an ethyl group, an n-propyl group, an isopropyl group, an n-butyl group, an isobutyl group, a tert-butyl group, an n-pentyl group, an isopentyl group, a neopentyl group, and the like. Among them, a methyl group, an ethyl group, an n-propyl group, and an isopropyl group are preferable, a methyl group and an ethyl group are more preferable, and a methyl group is further preferable.

The number of carbon atoms of the alkoxy group for R^{a44} is preferably 1 or more and 5 or less, and more preferably 1 or more and 3 or less. Examples of alkoxy groups include a methoxy group, an ethoxy group, an n-propyloxy group, an isopropyloxy group, an n-butyloxy group, an isobutyloxy group, a tert-butyloxy group, an n-pentyloxy group, an isopentyloxy group, a neopentyloxy group, and the like. Among these, a methoxy group, an ethoxy group, an n-propyloxy group, and an isopropyloxy group are preferable, a methoxy group and an ethoxy group are more preferable, and a methoxy group is further preferable. na3 is preferably an integer of 0 or more and 3 or less, more preferably 0 or 1, and further preferably 0.

The divalent linking group for R^{a45} is the same as the divalent linking group for R^{a12} in the formula (a1-1). Preferable divalent linking groups include —Si(CH₃)₂—, —SiH(CH₃)—, —Si(C₆H₅)(CH₃)—, Si(C₆H₅)₂—, —SiH(C₆H₅)—, and the like.

One kind of the constituent unit (a4) of the polysiloxane may be used, or two or more kinds thereof may be used.

When the polysiloxane includes the constituent unit (a4) in addition to the constituent unit (a1) and the constituent unit (a2), a proportion of the constituent unit (a4) in the polysiloxane is preferably 10 mol % or more and 60 mol % or less, more preferably 20 mol % or more and 55 mol % or less, and further preferably 30 mol % or more and 50 mol % or less with respect to the total (100 mol %) of all the constituent units constituting the polysiloxane.

(Constituent Unit (a5))

The constituent unit (a5) is a constituent unit represented by the following formula (a5).

The constituent unit (a5) is useful for improving lithography properties. When the constituent unit (a5) is introduced, the dissolution rate is easily controlled.

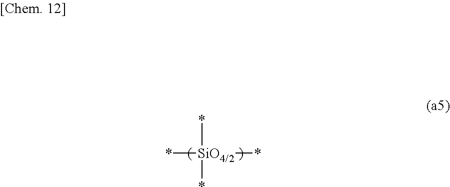

(In the formula (a5), * represents a bonding.)

When the polysiloxane includes the constituent unit (a5) in addition to the constituent unit (a1) and the constituent unit (a2), a proportion of the constituent unit (a5) in the polysiloxane is preferably 10 mol % or more and 60 mol % or less, more preferably 20 mol % or more and 55 mol % or less, and further preferably 30 mol % or more and 50 mol % or less with respect to the total (100 mol %) of all the constituent units constituting the polysiloxane.

Hereinafter, specific examples of the other constituent units are described.

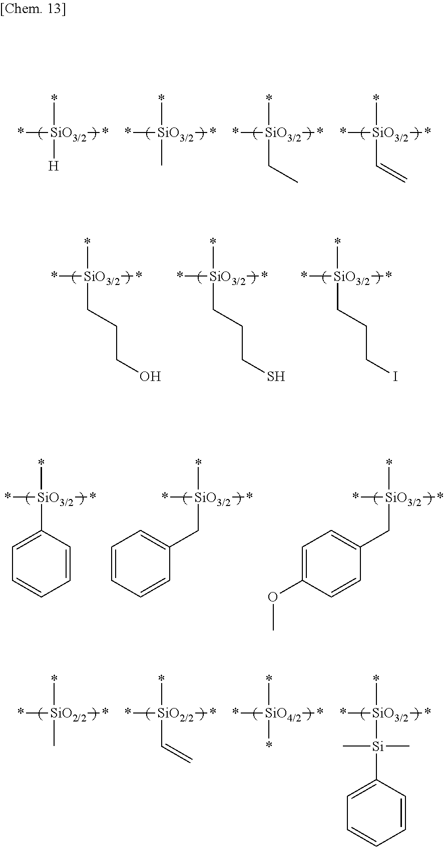

Among polysiloxanes, silsesquioxane including a constituent unit represented by the formula (a1) and a constituent unit represented by the formula (a2); silsesquioxane including a constituent unit represented by the formula (a1), a constituent unit represented by the formula (a2), and a constituent unit represented by the formula (a5) are preferable.

The mass average molecular weight (Mw) (polystyrene equivalent value determined by gel permeation chromatography (GPC)) of the silicon-containing polymer (A) such as polysiloxane is not particularly limited, and is, for example, 1000 or more, preferably 1000 or more and 10000 or less, more preferably 1300 or more and 7500 or less, and further preferably 1500 or more and 5000 or less.

When the Mw of the silicon-containing polymer (A) is equal to or less than the upper limit value of the above preferable range, solubility of the silicon-containing polymer (A) in an organic solvent is improved. On the other hand, when the Mw of the silicon-containing polymer (A) is equal to or more than the lower limit value of the above preferable range, a photosensitive composition with excellent lithography properties is easily obtained, and a resin film patterned in a good shape is easily formed.

Note here that a value of mass average molecular weight (Mw)/number average molecular weight (Mn) in the silicon-containing polymer (A), that is, dispersity is preferably, for example, 1 to 3, further 1.0 to 2.0, and particularly, about 1.05 to 1.50. Such a silicon-containing polymer (A) can further improve the lithography properties of the photosensitive composition.

A proportion of a mass of the silicon-containing polymer (A) to a mass of a solid content of the photosensitive composition is preferably 10% by mass or more, more preferably 20% by mass or more, further preferably 30% by mass or more and 75% by mass or less, particularly preferably 40% by mass or more and 70% by mass or less, and the most preferably 50% by mass or more and 70% by mass or less. When the proportion of mass of the silicon-containing polymer (A) is in the above-mentioned preferable range, etching resistance of a film formed using the photosensitive composition is improved.

Note here that the term “solid contents of the photosensitive composition” refers to components constituting the photosensitive composition excluding the organic solvent (S).

### <Photoacid Generating Agent (B)>

A photoacid generating agent (B) includes a photoacid generating agent (B1) including a sulfonium cation including an iodine atom. This increases usefulness particularly as a photosensitive composition for EUV.

### [Photoacid Generating Agent (B1) Including Sulfonium Cation Including Iodine Atom]

A photoacid generating agent (B1) is sulfonium salt including a sulfonium cation including an iodine atom as a cation part.

### (Cation Part)

As the sulfonium cation including an iodine atom, a sulfonium cation represented by the following formula (b1-1) is preferable.

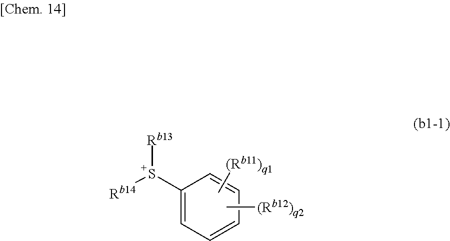

(In the formula (b1-1), Roll represents an iodine atom, or —R^{b111}—X^{b1}, R^{b111} represents a divalent linking group not including an aromatic group, X^{b1} represents an aromatic group substituted with an iodine atom, R^{b12} represents, a fluorine atom, a hydroxy group, a hydrocarbon group which may have a substituent, or an alkoxy group which may have a substituent, R^{b13} and R^{b14} each independently represent a hydrocarbon group which may have a substituent, R^{b13} and R^{b14} may be bonded to each other to form a ring, q1 represents an integer of 1 or more and 4 or less, q2 represents an integer of 0 or more and 3 or less, and a sum of q1 and q2 is 1 or more and 4 or less.)

When q1 is an integer of 2 or more, a plurality of Rolls may be the same as each other or may be different from each other. Furthermore, when q2 is an integer of 2 or more, a plurality of R^{b12}s may be the same as each other or may be different from each other.

The divalent linking group not including an aromatic group for R^{b111} represents a divalent aliphatic hydrocarbon group or a group represented by the following formula (b1-1a).

-L^{b1}-R^{b112}-L^{b2}-* (b1-1a)

(In the formula (b1-1a), L^{b1} represents an ester bond, an amide bond, or an ether bond; L^{b2} represents a single bond, an ester bond, an amide bond, or an ether bond, R^{b112} represents a single bond or an alkylene group, and * represents a bonding bonded to X^{b1}.)

The aliphatic hydrocarbon group for R^{b111} may be a saturated aliphatic hydrocarbon group or may be an unsaturated aliphatic hydrocarbon group.

The aliphatic hydrocarbon group for R^{b111} may be a linear aliphatic hydrocarbon group, a branched aliphatic hydrocarbon group, an alicyclic hydrocarbon group, combinations of two kinds or more selected from these, and the like.

The number of carbon atoms of the linear aliphatic hydrocarbon group is preferably 1 or more and 10 or less, more preferably 1 or more and 6 or less, further preferably 1 or more and 4 or less, and the most preferably 1 or more and 3 or less.

The linear aliphatic hydrocarbon group is preferably a linear alkylene group. Specific examples include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], and the like.

The number of carbon atoms of the branched aliphatic hydrocarbon group is preferably 2 or more and 10 or less, more preferably 2 or more and 6 or less, and further preferably 2 or 3.

The branched aliphatic hydrocarbon group is preferably a branched alkylene group. Specific examples include alkylalkylene group including alkylmethylene groups such as —CH(CH₃)—, —CH(CH₂CH₃)—, —C(CH₃)₂—, —C(CH₃) (CH₂CH₃)—, —C(CH₃) (CH₂CH₂CH₃)—, and —C(CH₂CH₃)₂—; alkylethylene groups such as —CH(CH₃)CH₂—, —CH(CH₃) CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; alkyltetramethylene groups such as —CH(CH₃)CH₂CH₂CH₂—, —CH₂CH(CH₃)CH₂CH₂—, and the like. Preferable the alkyl groups in the alkylalkylene group include a linear alkyl group having a number of carbon atoms 1 or more and 5 or less.

The number of carbon atoms of the alicyclic hydrocarbon group is preferably 3 or more and 20 or less, and more preferably 3 or more and 12 or less.

The alicyclic hydrocarbon group may be a polycyclic group, or may be a monocyclic group. As the monocyclic aliphatic hydrocarbon group, a group obtained by removing two hydrogen atoms from a monocycloalkane is preferable. The number of carbon atoms of the monocycloalkane is preferably 3 or more and 6 or less. Specific examples of the monocycloalkane include cyclopentane, cyclohexane, and the like. The polycyclic aliphatic hydrocarbon group is preferably a group obtained by removing two hydrogen atoms from a polycycloalkane. The number of carbon atoms of the polycycloalkane is preferably 7 or more and 12 or less. Specific examples of the polycycloalkane include adamantane, norbornane, isobornane, tricyclodecane, tetracyclododecane, and the like.

The number of carbon atoms of the alkylene group for R^{b112} is preferably 1 or more and 5 or less, and more preferably 1 or more and 3 or less.

The alkylene group for R^{b112} may be linear or may be branched, and is preferably linear.

Examples of the alkylene group as R^{b112} include a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], and the like.

As the aromatic group for X^{b1}, an aromatic hydrocarbon group is preferable.

Specific examples of the aromatic hydrocarbon ring constituting the aromatic hydrocarbon group include a benzene ring, a fluorene ring, a naphthalene ring, an anthracene ring, a phenanthrene ring, a biphenyl ring, and the like.

Examples of the aromatic hydrocarbon group include a group obtained by removing one hydrogen atom from the aromatic hydrocarbon ring (an aryl group), and the like. Suitable specific examples of the aromatic hydrocarbon group include a phenyl group, a naphthalene-1-yl group, and naphthalene-2-yl group.

The number of iodine atoms for substituting the aromatic group for X^{b1} is preferably 1 or more and 5 or less, and more preferably 1 or more and 3 or less.

R^{b11} is preferably an iodine atom.

The hydrocarbon group for R^{b12} is preferably an alkyl group. The number of carbon atoms of the alkyl group is preferably 1 or more and 10 or less, and more preferably 1 or more and 5 or less. Examples of alkyl groups include a methyl group, an ethyl group, an n-propyl group, an n-butyl group, an n-pentyl group, an isopropyl group, an isobutyl group, a sec-butyl group, a tert-butyl group, and the like.

The number of carbon atoms of the alkoxy group for R^{b12} is preferably 1 or more and 10 or less, and more preferably 1 or more and 5 or less. Examples of the alkoxy groups for R^{b12} include a methoxy group, an ethoxy group, an n-propyloxy group, an isopropyloxy group, an n-butyloxy group, an isobutyloxy group, a sec-butyloxy group, a tert-butyloxy group, and the like.

Examples of the substituent which may be included by the hydrocarbon group and alkoxy group for R^{b12} include a fluorine atom, and the like.

R^{b12} is preferably a hydroxy group.

It is favorable that q1 is 1 or more and 3 or less, and more preferably 1.

It is favorable that q2 is 0 or 1, and more preferably 0.

Examples of the hydrocarbon group as R^{b13} and R^{b14} which may have a substituent include an aryl group which may have a substituent, an alkyl group which may have a substituent, an alkenyl group which may have a substituent, or the like.

As the aryl group as R^{b13} and R^{b14}, an unsubstituted aryl group having carbon atoms 6 or more and 20 or less carbon atoms is preferable, and a phenyl group and a naphthyl group are more preferable.

The number of carbon atoms of the alkyl group for R^{b13} and R^{b14} is preferably 1 or more and 30 or less.

The number of carbon atoms of the alkenyl group for R^{b13} and R^{b14} is preferably 2 or more and 10 or less.

Examples of the substituent which may be included in the hydrocarbon group for R^{b13}, and R^{b14} include an alkyl group, a halogen atom, a halogenated alkyl group, a carbonyl group, a cyano group, an amino group, and an aryl group, and groups respectively represented by the following formulae (ca-r-1) to (ca-r-7).

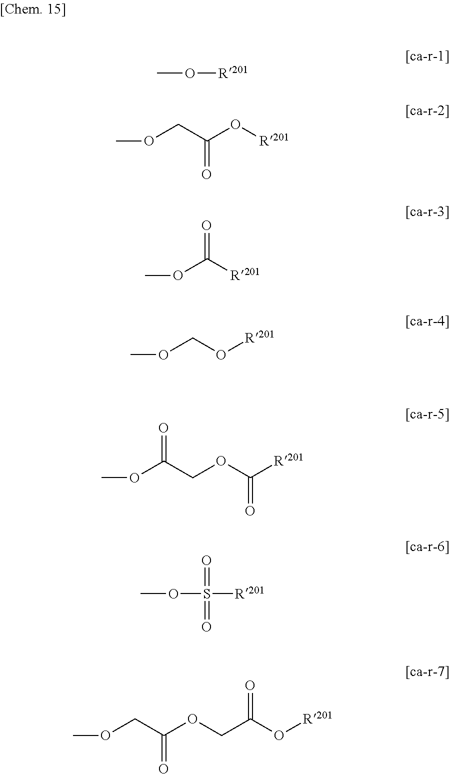

(In the formula, R′²⁰¹ independently represents a hydrogen atom, a cyclic group which may have a substituent, an alkyl group which may have a substituent, or an alkenyl group which may have a substituent.)

A cyclic group which may have a substituent:

A cyclic group which may have a substituent is preferably a cyclic-shaped hydrocarbon group, or a heterocyclic group. The cyclic-shaped hydrocarbon group may be an aromatic hydrocarbon group, or an alicyclic hydrocarbon group. The aliphatic hydrocarbon group and the alicyclic heterocyclic group may include 1 or more unsaturated bonds, and are preferably a saturated aliphatic hydrocarbon group, and a saturated alicyclic heterocyclic group.

The number of carbon atoms of the aromatic hydrocarbon group for R′²⁰¹ is preferably 6 or more and 30 or less, more preferably 6 or more and 20 or less, further preferably 6 or more and 15 or less, and particularly preferably 6 or more and 10 or less. However, the number of carbon atoms does not include the number of carbon atoms in a substituent.

Specific examples of the aromatic hydrocarbon ring constituting the aromatic hydrocarbon group for R′²⁰¹ include a benzene ring, a fluorene ring, a naphthalene ring, an anthracene ring, a phenanthrene ring, a biphenyl ring, and the like.

Examples of the aromatic hydrocarbon group for R′²⁰¹ include a group (an aryl group and the like) obtained by removing one hydrogen atom from the aromatic hydrocarbon ring, and the like. Suitable specific examples of the aromatic hydrocarbon group include a phenyl group, a naphthalene-1-yl group, a naphthalene-2-yl group, and the like.

The number of carbon atoms in the alicyclic hydrocarbon group for R′²⁰¹ is preferably 3 or more and 20 or less, and more preferably 3 or more and 12 or less.

The alicyclic hydrocarbon group may be a polycyclic group or a monocyclic group. The monocyclic alicyclic hydrocarbon group is preferably a group obtained by removing one or more hydrogen atoms from a monocycloalkane. The monocycloalkane is preferably a monocycloalkane having 3 or more and 6 or less carbon atoms. Specific examples of the monocycloalkane include cyclopentane, cyclohexane, and the like. The polycyclic alicyclic hydrocarbon group is preferably a group obtained by removing one or more hydrogen atoms from a polycycloalkane. The polycycloalkane is preferably a polycycloalkane having 7 or more and 30 or less carbon atoms. A polycycloalkane having a crosslinked ring polycyclic skeleton, such as adamantane, norbornane, isobornane, tricyclodecane, and tetracyclododecane; and a polycycloalkane having a condensed ring polycyclic skeleton, such as a cyclic group having a steroid skeleton are more preferable as the polycycloalkane.

The alicyclic hydrocarbon group for R′²⁰¹ is preferably a group obtained by removing one or more hydrogen atoms from a monocycloalkane or a polycycloalkane, more preferably a group obtained by removing one hydrogen atom from a polycycloalkane, particularly preferably an adamantyl group or a norbornyl group, and most preferably an adamantyl group.

The cyclic group for R′²⁰¹ may be a heterocyclic group. The heterocyclic group may be an aliphatic heterocyclic group, or may be an aromatic heterocyclic group. Specific examples of the heterocyclic group include a lactone-containing cyclic group, —SO₂-containing cyclic group, and a heterocyclic group represented by any one of the following formulae (r-hr-1) to (r-hr-16). In the formula, * represents a bonding.

The term “lactone-containing cyclic group” is a cyclic group containing a ring (lactone ring) including —O—C(═O)— in the ring skeleton thereof. A group consisting only of a lactone ring is a monocyclic group. A group including the other ring structure together with the lactone ring is a polycyclic group.

The lactone-containing cyclic group may be a monocyclic group or may be a polycyclic group. The term “—SO₂-containing cyclic group” refers to a cyclic group containing a ring including —SO₂-in the ring skeleton thereof, and specifically, refers to a cyclic group in which a sulfur atom(S) in the —SO₂-forms a part of the ring skeleton of the cyclic group. A group consisting only of a ring including —SO₂— is a monocyclic group. A group including a ring including —SO₂— and other ring structures is a polycyclic group. The —SO₂-containing cyclic group may be a monocyclic group or a polycyclic group. The —SO₂-containing cyclic group is particularly preferred to be a cyclic group including —O—SO₂— in its ring skeleton, that is, a cyclic group containing a sultone ring in which —O—S— in —O—SO₂-forms a part of the ring skeleton.

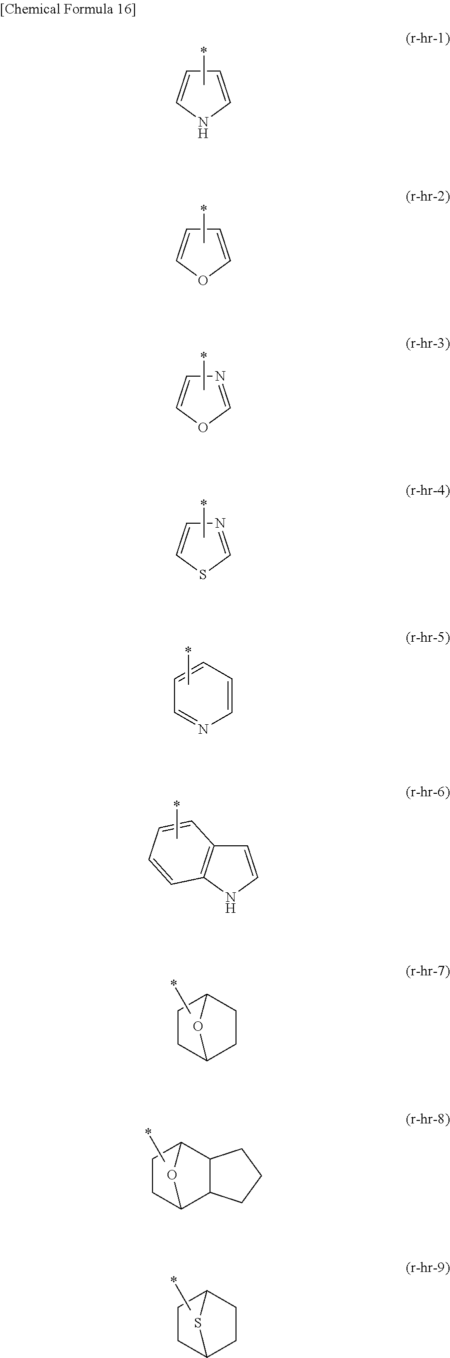

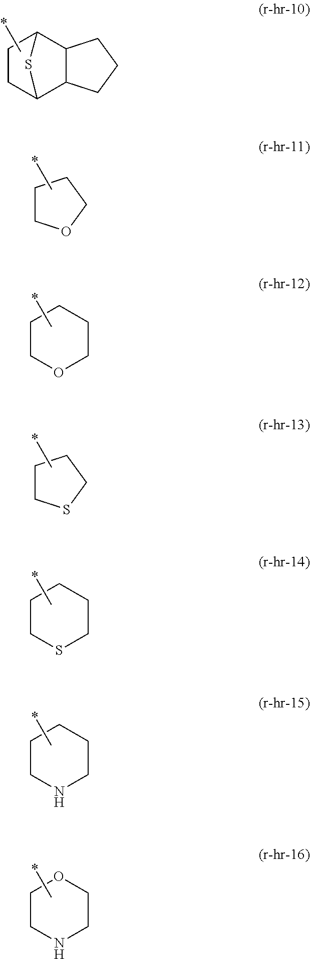

Examples of the substituent which may be included by the cyclic group as R′²⁰¹ include an alkyl group, an alkoxy group, a halogen atom, a halogenated alkyl group, a hydroxy group, an oxo group (═O), a nitro group, and the like.

The alkyl group as the substituent is preferably an alkyl group having 1 or more and 5 or less carbon atoms, and more preferably a methyl group, an ethyl group, an n-propyl group, an n-butyl group, and a tert-butyl group.

The alkoxy group as the substituent is preferably an alkoxy group having 1 or more and 5 or less carbon atoms, more preferably a methoxy group, an ethoxy group, an n-propyloxy group, an iso-propyloxy group, an n-butyloxy group, and a tert-butyloxy group, and further preferably a methoxy group and an ethoxy group.

Examples of the halogen atom as the substituent include a fluorine atom, a chlorine atom, a bromine atom, an iodine atom, and the like. Among these, a fluorine atom is preferable.

Examples of halogenated alkyl group as the substituent include an alkyl group having 1 or more and 5 or less carbon atoms in which a part or all of hydrogen atoms are substituted with the above-mentioned halogen atom.

Alkyl group which may have a substituent:

An alkyl group as R′²⁰¹ may be a linear alkyl group, or a branched alkyl group.

The number of carbon atoms of the linear alkyl group is preferably 1 or more and 20 or less, more preferably 1 or more and 15 or less, and further preferably 1 or more and 10 or less. Specific examples of the linear alkyl group include a methyl group, an ethyl group, an n-propyl group, an n-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, an n-nonadecyl group, and an icosyl group.

The number of carbon atoms of the branched alkyl group is preferably 3 or more and 20 or less, more preferably 3 or more and 15 or less, and further preferably 3 or more and 10 or less. Specific examples of the branched alkyl group include a 1-methylethyl group (isopropyl group), a 1-methylpropyl group (sec-butyl group), a 2-methylpropyl group (isobutyl group), a 1-methylbutyl group (sec-pentyl group), a 2-methylbutyl group, a 3-methylbutyl group (isopentyl group), a 1-ethylbutyl group, a 2-ethylbutyl group, a 1-methylpentyl group, a 2-methylpentyl group, and a 3-methylpentyl group, a 4-methylpentyl group, and the like.

Alkenyl group which may have a substituent:

The alkenyl group as R′²⁰¹ may be a linear alkenyl group or a branched alkenyl group.

The number of carbon atoms in the alkenyl group is preferably 2 or more and 10 or less, more preferably 2 or more and 5 or less, further preferably 2 or more and 4 or less, and particularly preferably 3. Examples of the linear alkenyl groups include a vinyl group, a 2-propenyl group (an allyl group), a 1-propenyl group, 3-butenyl group, a 2-butenyl group, a 1-butenyl group, and the like. Examples of the branched alkenyl groups include a 1-methylvinyl group, a 1-methyl-2-propenyl group, a 2-methyl-2-propenyl group, and the like.

The alkenyl group is preferably the linear alkenyl group, more preferably a vinyl group, a 2-propenyl group, and a 1-propenyl group, and further preferably a vinyl group.

Examples of the substituent which may be included in the alkyl group and the alkenyl group as R′²⁰¹ include an alkoxy group, a halogen atom, a halogenated alkyl group, a hydroxy group, an oxo group (═O), a nitro group, an amino group, the cyclic group as the above-mentioned R′²⁰¹, and the like.

Examples of the cyclic group which may have a substituent, an alkyl group which may have a substituent, and an alkenyl group which may have a substituent for R′²⁰¹ also include tertiary alkyl ester-type acid dissociable group in addition to the groups described above.

R′²⁰¹ is preferably a cyclic group which may have a substituent. Specific preferable examples thereof include a phenyl group, a naphthyl group, or a group obtained by removing one or more hydrogen atoms from a polycycloalkane, a lactone-containing cyclic group, a —SO₂-containing cyclic group, and the like.

R^{b13} and R^{b14} may be bonded to each other to form a ring. For example, a ring may be formed together with a sulfur atom in the formula by bonding each other, or a condensed ring may be formed together with a sulfur atom and a benzene ring in the formula.

When R^{b13} and R^{b14} form a condensed ring together with a sulfur atom and a benzene ring in the formula, R^{b13} and R^{b14} may be bonded via a heteroatom such as a sulfur atom, an oxygen atom, and a nitrogen atom, or a functional group such as a carbonyl group, —SO—, —SO₂—, —SO₃—, —COO—, —CONH—, or —N(R_{N})—(R_{N} represents an alkyl group having 1 or more and 5 or less carbon atoms).

As the ring formed by bonding of R^{b13} and R^{b14}, rings with 3 members or more and 10 members or less are preferable, and rings with 5 members or more and 7 members or less are more preferable. Specific examples of the formed ring include a thiophene ring, a thiazole ring, a benzothiophene ring, a thianthrene ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

In the formula (b1-1), it is preferable that R^{b13} and R^{b14} each independently are a phenyl group which may have a substituent or a naphthyl group which may have a substituent, or that R^{b13} and R^{b14} are bonded to each other to form a ring together with the sulfur atom in the formula.

Specific examples of the sulfonium cation represented by the formula (b1-1) are shown below.

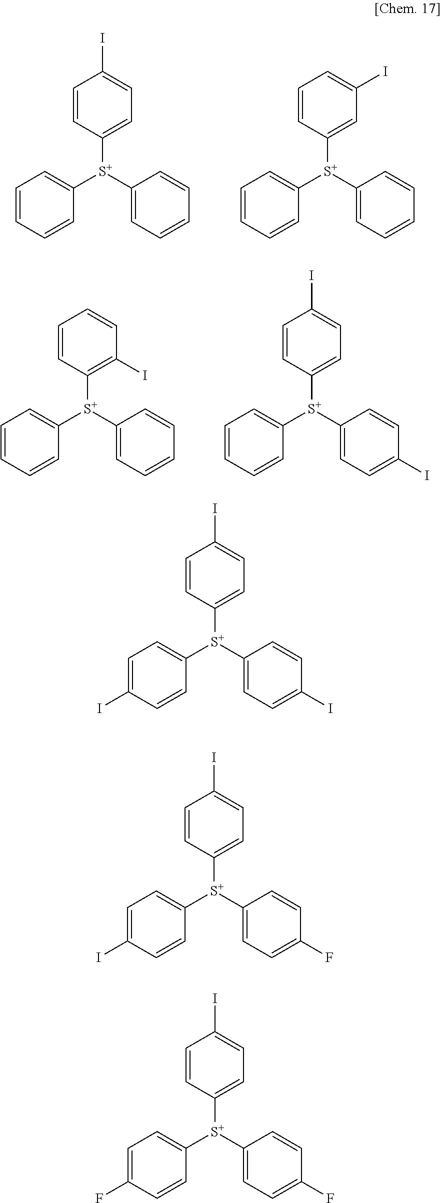

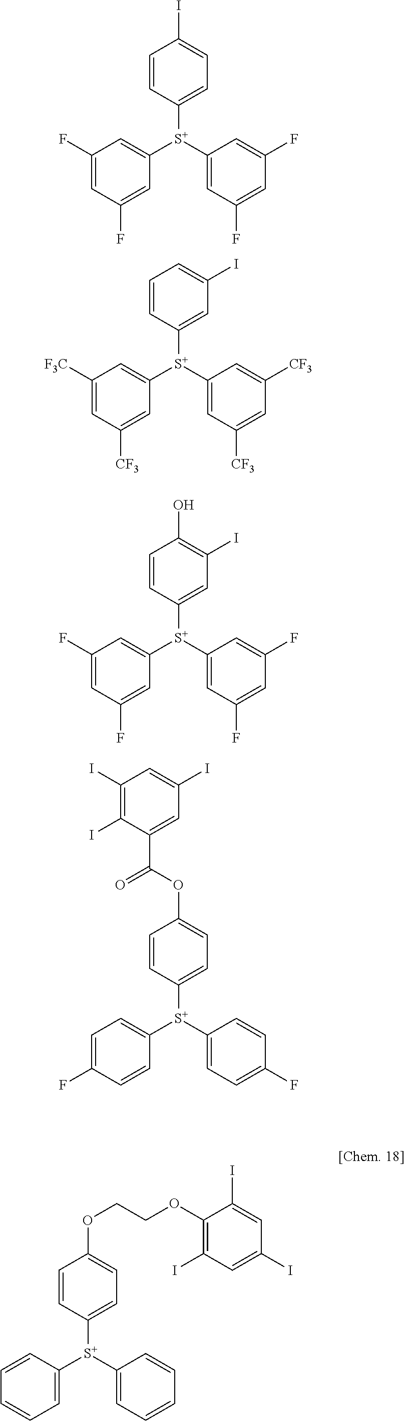 [SMILES: Fc1cc(F)cc([S+](c2ccc(I)cc2)c2cc(F)cc(F)c2)c1 ; FC(F)(F)c1cc([S+](c2cccc(I)c2)c2cc(C(F)(F)F)cc(C(F)(F)F)c2)cc(C(F)(F)F)c1 ; Oc1ccc([S+](c2cc(F)cc(F)c2)c2cc(F)cc(F)c2)cc1I ; O=C(Oc1ccc([S+](c2ccc(F)cc2)c2ccc(F)cc2)cc1)c1cc(I)cc(I)c1I ; Ic1cc(I)c(OCCOc2ccc([S+](c3ccccc3)c3ccccc3)cc2)c(I)c1]

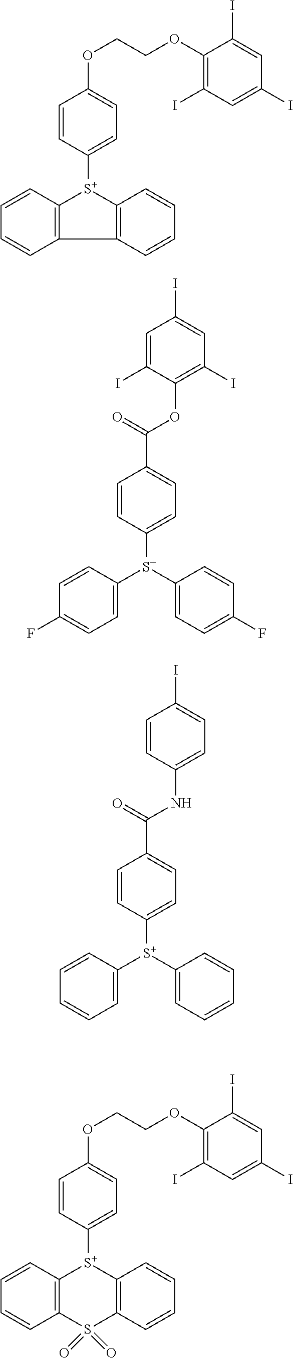 [SMILES: Ic1cc(I)c(OCCOc2ccc(-[s+]3c4ccccc4c4ccccc43)cc2)c(I)c1 ; O=C(Oc1c(I)cc(I)cc1I)c1ccc([S+](c2ccc(F)cc2)c2ccc(F)cc2)cc1 ; O=C(Nc1ccc(I)cc1)c1ccc([S+](c2ccccc2)c2ccccc2)cc1 ; O=S1(=O)c2ccccc2[S+](c2ccc(OCCOc3c(I)cc(I)cc3I)cc2)c2ccccc21]

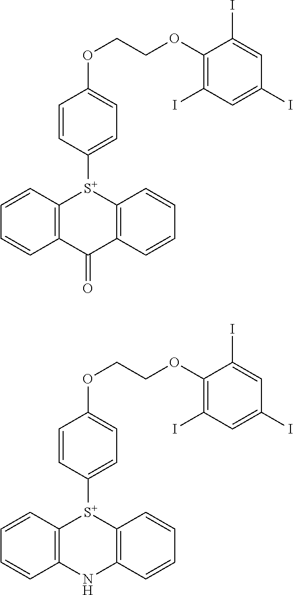 [SMILES: O=c1c2ccccc2[s+](-c2ccc(OCCOc3c(I)cc(I)cc3I)cc2)c2ccccc12 ; Ic1cc(I)c(OCCOc2ccc([S+]3c4ccccc4Nc4ccccc43)cc2)c(I)c1]

The sulfonium cation represented by the formula (b1-1) is preferably a sulfonium cation represented by the formula (b1-1a).

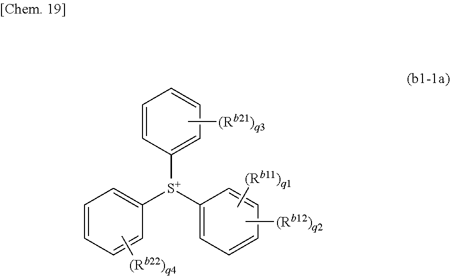

(In the formula (b1-1a), R^{b21} and R^{b22} each independently represent an iodine atom, a fluorine atom, a hydroxy group, a hydrocarbon group which may have a substituent, or an alkoxy group which may have a substituent, q3 and q4 each independently represent an integer of 0 or more and 5 or less, R^{b11}, R^{b12}, q1, and q2 are the same groups as those of R^{b11}, R^{b12}, q1, and q2 in the formula (b1-1).)

When q3 is an integer of 2 or more, a plurality of R^{b21}s may be the same as or may be different from each other. Furthermore, when q4 is an integer of 2 or more, a plurality of R^{b22}s may be the same as or may be different from each other.

Examples of the hydrocarbon group for R^{b21} and R^{b22} which may have a substituent include the same groups as the hydrocarbon groups for R^{b12} which may have a substituent. The hydrocarbon group for R^{b21} and R^{b22} which may have a substituent is preferably an alkyl group which may have a fluorine atom (a fluorinated alkyl group).

The alkoxy group for R^{b21} and R^{b22} which may have a substituent include the same groups as the alkoxy group for R^{b12} which may have a substituent.

R^{b21} and R^{b22} are preferably an iodine atom, a fluorine atom, a hydroxy group, and a hydrocarbon group which may have a substituent, and more preferably an iodine atom, a fluorine atom, a hydroxy group, and a fluorinated alkyl group.

It is favorable that q3 and q4 are an integer of 0 or more and 3 or less, and more preferably 1 or 2.

### (Anion Moiety)

An anion moiety of the photoacid generating agent (B1) is not particularly limited, and can be appropriately selected from anions known as anion moieties of the photoacid generating agent used in the photosensitive composition.

Examples of the anion moiety include anions represented by the following formula (b1-2).

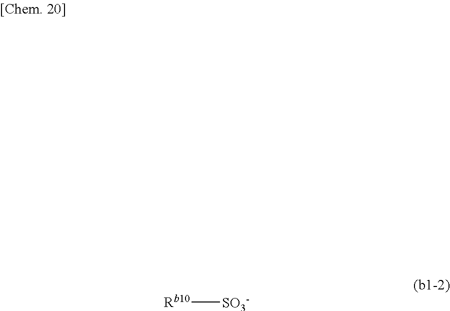

(In the formula (b1-2), R^{b10} is an organic group having 1 or more and 40 or less carbon atoms.)

Examples of the organic group for R^{b10} include a hydrocarbon group which may have a substituent, a divalent linking group including an oxygen atom, and a combination thereof.

The anion represented by the formula (b1-2) is preferably an anion represented by the following formula (b1-3).

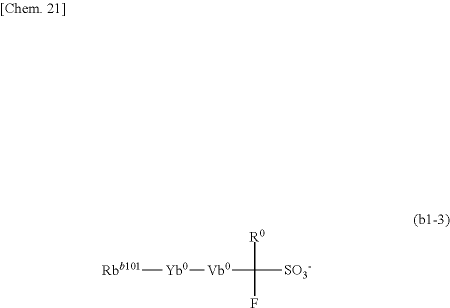

(In the formula (b1-3), R^{b101} represents a cyclic group which may have a substituent, an alkyl group which may have a substituent, or an alkenyl group which may have a substituent, Yb⁰ represents a divalent linking group, or a single bond, Vb⁰ represents a single bond, an alkylene group, or a fluorinated alkylene group, R⁰ represents a hydrogen atom, a fluorinated alkyl group having 1 or more and 5 or less carbon atoms, or a fluorine atom.)

Cyclic group which may have a substituent as R^{b101}:

The cyclic group may be a cyclic hydrocarbon group or a cyclic heterocyclic group. The cyclic group may be an alicyclic hydrocarbon group, an aromatic hydrocarbon group, an aliphatic heterocyclic group, an aromatic heterocyclic group, and a cyclic group in which two or more rings selected from these rings are condensed. Aliphatic hydrocarbon group means a hydrocarbon group without aromatic properties. Furthermore, the aliphatic hydrocarbon group may be saturated or unsaturated, and is generally preferably saturated.

The number of carbon atoms of the cyclic group for R^{b101} is preferably 3 or more and 30 or less, more preferably 5 or more and 30 or less, further preferably 5 or more and 20 or less, and particularly preferably 6 or more and 18 or less. The number of carbon atoms of the above-mentioned cyclic group does not include the number of carbon atoms of the substituent.

Examples of the aromatic rings constituting the aromatic hydrocarbon group include a benzene ring, a fluorene ring, a naphthalene ring, an anthracene ring, a phenanthrene ring, a biphenyl ring, and the like. Examples of the aromatic hydrocarbon group include a group obtained by removing one hydrogen atom from the above aromatic ring (aryl group) Specific examples of the aromatic hydrocarbon groups include a phenyl group, a naphthalene-1-yl group, and a naphthalene-2-yl group.

The number of carbon atoms of the alicyclic hydrocarbon group for R^{b101} is preferably 3 or more and 30 or less, more preferably 3 or more and 20 or less, and further preferably 3 or more and 12 or less.

The above-mentioned alicyclic hydrocarbon group may be a polycyclic group, or a monocyclic group. As the monocyclic alicyclic hydrocarbon group, a group in which one or more hydrogen atoms are removed from monocycloalkane is preferable. The monocycloalkane is preferably a monocycloalkane having 3 or more and 6 or less carbon atoms. Specific examples of the monocycloalkane include cyclopentane and cyclohexane. The polycyclic alicyclic hydrocarbon group is preferably a group obtained by removing one or more hydrogen atoms from a polycycloalkane. The polycycloalkane is preferably a polycycloalkane having 7 or more and 30 or less carbon atoms. As the polycycloalkane, a polycycloalkane having a crosslinked ring polycyclic skeleton such as adamantane, norbornane, isobornane, tricyclodecane, and tetracyclododecane; a polycycloalkane having a condensed ring polycyclic skeleton such as a cyclic group having a steroid skeleton are more preferable.

The alicyclic hydrocarbon group for R^{b101} is preferably monocycloalkane or a group obtained by removing one or more hydrogen atoms from polycycloalkane, more preferably a group obtained by removing one hydrogen atom from polycycloalkane, further preferably an adamantyl group and a norbornyl group, and particularly preferably an adamantyl group.

The cyclic group for R^{b101} may be a heterocyclic group. The heterocyclic group may be an aromatic heterocyclic group, or may be an aliphatic heterocyclic group. Specific examples include a lactone-containing cyclic group, —SO₂-containing cyclic group, and heterocyclic groups respectively represented by the above chemical formulae (r-hr-1) to (r-hr-16).

Examples of the substituent which may be included by the cyclic group for R^{b101} include an alkyl group, an alkoxy group, a halogen atom, a halogenated alkyl group, a hydroxy group, an oxo group (═O), a nitro group, a cyclic group which may have a substituent, and the like.

The alkyl group as the substituent is preferably an alkyl group having 1 or more and 5 or less carbon atoms, and more preferably a methyl group, an ethyl group, an n-propyl group, an n-butyl group, and a tert-butyl group.

The alkoxy group as the substituent is preferably an alkoxy group having 1 or more and 5 or less carbon atoms, more preferably a methoxy group, an ethoxy group, an n-propyloxy group, an iso-propyloxy group, an n-butyloxy group, and a tert-butyloxy group, and further preferably a methoxy group and an ethoxy group.

Examples of the halogen atom as the substituent include a fluorine atom, a chlorine atom, a bromine atom, an iodine atom, and the like, and a fluorine atom is preferable.

Examples of the halogenated alkyl group as the substituent include an alkyl group having 1 or more and 5 or less carbon atoms in which a part or all of hydrogen atoms are substituted with the above-mentioned halogen atom. As the alkyl group having 1 or more and 5 or less carbon atoms, groups listed as the specific examples of the alkoxy group as the substituent are preferable.

Examples of the cyclic group which may have a substituent, as the substituent, include the same groups as the cyclic groups for R^{b101} which may have a substituent.

The cyclic group for R^{b101} may be a condensed cyclic group including a condensed ring in which an aliphatic hydrocarbon ring and an aromatic hydrocarbon ring are condensed. Examples of the above condensed ring include a ring in which one or more aromatic rings are condensed to a polycycloalkane having a crosslinked ring polycyclic skeleton. Specific examples of the crosslinked cyclic polycycloalkane include bicycloalkanes such as bicyclo[2.2.1]heptane (norbornane) and bicyclo[2.2.2]octane. As the condensed ring type group, a group including a condensed ring in which two or three aromatic rings are condensed to bicycloalkane is preferable, and a group including a condensed ring in which two or three aromatic rings are condensed to bicyclo[2.2.2]octane is more preferable.

Specific examples of the condensed cyclic group for R^{b101} include groups represented by the following formulae (r-br-1) to (r-br-2).

In the formula, * represents a bonding bonded to Yb⁰ in the formula (b1-3).

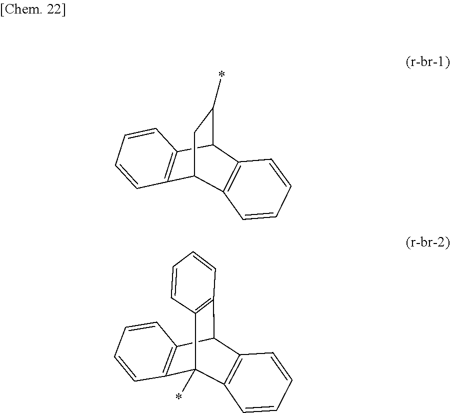 [SMILES: *C1CC2c3ccccc3C1c1ccccc12 ; *C12c3ccccc3C(c3ccccc31)c1ccccc12]

Examples of the substituent which may be included in the condensed cyclic group for R^{b101} include an alkyl group, an alkoxy group, a halogen atom, a halogenated alkyl group, a hydroxy group, an oxo group (═O), a nitro group, an aromatic hydrocarbon group, an alicyclic hydrocarbon group, and the like.

Examples of the alkyl group, the alkoxy group, the halogen atom, and the halogenated alkyl group as the substituent of the above-mentioned condensed cyclic group include the same groups as those described as the substituent of the cyclic group for the above R¹⁰¹.

Alkyl group for R^{b101} which may have a substituent:

Alkyl group for R^{b101} may be a linear alkyl group or a branched alkyl group. The number of carbon atoms of the linear alkyl group is preferably 1 or more and 20 or less, more preferably 1 or more and 15 or less, and further preferably 1 or more and 10 or less. Specific examples of the linear alkyl group include a methyl group, an ethyl group, an n-propyl group, an n-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, n-nonadecyl group, and an n-icosyl group.

The number of carbon atoms of the branched alkyl group is preferably 3 or more and 20 or less, more preferably 3 or more and 15 or less, and further preferably 3 or more and 10 or less. Specific examples of the branched alkyl group include a 1-methylethyl group (isopropyl group), a 1-methylpropyl group (sec-butyl group), a 2-methylpropyl group (isobutyl group), a 1-methylbutyl group (sec-pentyl group), a 2-methylbutyl group, a 3-methylbutyl group (isopentyl group), a 1-ethylbutyl group, a 2-ethylbutyl group, a 1-methylpentyl group, a 2-methylpentyl group, a 3-methylpentyl group, a 4-methylpentyl group, and the like.

Alkenyl group for R^{b101} which may have a substituent:

Alkenyl group for R^{b101} may be a linear alkenyl group or a branched alkenyl group. The number of carbon atoms in the alkenyl group is preferably 2 or more and 10 or less, more preferably 2 or more and 5 or less, still more preferably 2 or more and 4 or less, and particularly preferably 3. Examples of the linear alkenyl groups include a vinyl group, a 2-propenyl group (an allyl group), a 1-propenyl group, a 3-butenyl group, a 2-butenyl group, a 1-butenyl group, and the like.

Examples of the branched alkenyl groups include a 1-methylvinyl group, a 1-methyl-2-propenyl group, a 2-methyl-2-propenyl group, and the like. The chain alkenyl group is preferably the linear alkenyl group, more preferably a vinyl group, and a 2-propenyl group, and further preferably a vinyl group.

Examples of the substituent which may be included in the alkyl group or the alkenyl group for R^{b101} include an alkoxy group, a halogen atom, a halogenated alkyl group, a hydroxy group, an oxo group (═O), a nitro group, an amino group, and the cyclic group for R^{b101} mentioned above and the like.

R^{b101} is preferably a cyclic group which may have a substituent, and more preferably a cyclic hydrocarbon group which may have a substituent. Specific preferable examples of cyclic groups include a phenyl group, a naphthalene-1-yl group, a naphthalene-2-yl group, a group in which one hydrogen atom is removed from polycycloalkane, a lactone-containing cyclic group, a —SO₂-containing cyclic group, and a condensed cyclic group including a condensed ring in which an aliphatic hydrocarbon ring and an aromatic ring are condensed.

Yb⁰ represents a divalent linking group, or a single bond. As the divalent linking group for Yb⁰ , a divalent linking group including an oxygen atom is preferable. The divalent linking group including an oxygen atom may contain an atom other than the oxygen atom. Examples of the atoms other than an oxygen atom include a carbon atom, a hydrogen atom, a sulfur atom, a nitrogen atom, and the like.

Examples of the divalent linking group including an oxygen atom include: a non-hydrocarbon-based oxygen atom-containing linking group such as an oxygen atom (ether bond:—O—), an ester bond (—C(═O)—O—), an oxycarbonyl group (—O—C(═O)—), an amide bond (—C(═O)—NH—), a carbonyl group (—C(═O)—), and a carbonate bond (—O—C(═O)—O—); a combination of the non-hydrocarbon-based oxygen atom-containing linking group with an alkylene group, and the like. A sulfonyl group (—SO₂—) may be further linked to this combination.

Examples of such a divalent linking group including an oxygen atom include linking groups represented by the following formulae (y-a1-1) to (y-a1-7).

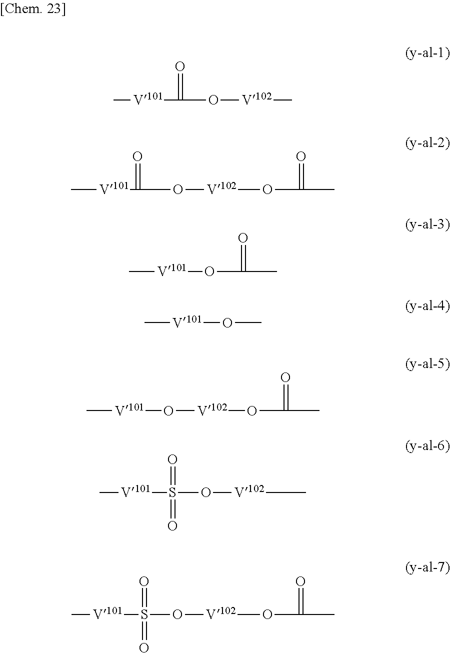

(In the formulae, V′¹⁰¹ represents a single bond, or an alkylene group having 1 or more and 5 or less carbon atoms, and V′¹⁰² represents a divalent saturated hydrocarbon group having 1 or more and 30 or less carbon atoms.)

The divalent saturated hydrocarbon group for V′¹⁰² is preferably an alkylene group having 1 or more and 30 or less carbon atoms, more preferably an alkylene group having 1 or more and 10 or less carbon atoms, and further preferably an alkylene group having 1 or more and 5 or less carbon atoms.

The alkylene group for V′¹⁰¹ and V′¹⁰² may be a linear alkylene group or a branched alkylene group, and is preferably a linear alkylene group.

Specific examples of the alkylene group for V′¹⁰¹ and V′¹⁰² include a methylene group [—CH₂—]; alkylmethylene groups such as —CH(CH₃)—, —CH(CH₂CH₃)—, —C(CH₃)₂—, —C(CH₃) (CH₂CH₃)—, —C(CH₃) (CH₂CH₂CH₃)—, and —C(CH₂CH₃)₂—; an ethylene group [—CH₂CH₂—]; an alkylethylene group such as —CH(CH₃)CH₂—, —CH(CH₃) CH(CH₃)—, —C(CH₃)₂CH₂—, and —CH(CH₂CH₃)CH₂—; a trimethylene group (n-propylene group) [—CH₂CH₂CH₂—]; an alkyltrimethylene group such as —CH(CH₃)CH₂CH₂—, and —CH₂CH(CH₃)CH₂—; a tetramethylene group [—CH₂CH₂CH₂CH₂—]; an alkyltetramethylene group such as —CH(CH₃)CH₂CH₂CH₂—, and —CH₂CH(CH₃)CH₂CH₂—; a pentamethylene group [—CH₂CH₂CH₂CH₂CH₂—], and the like.

A part of the methylene group in the alkylene group in V′¹⁰¹ or V′¹⁰² may be substituted with a divalent aliphatic cyclic group having 5 or more and 10 or less carbon atoms.

The aliphatic cyclic group is preferably a group in which further one hydrogen atom is removed from an alicyclic hydrocarbon group (a monocyclic aliphatic hydrocarbon group, a polycyclic aliphatic hydrocarbon group), and more preferably a cyclohexylene group, a 1,5-adamantylene group, and a 2,6-adamantylene group.

Yb⁰ is preferably a divalent linking group including an ester bond and a divalent linking group including an ether bond, and more preferably linking groups respectively represented by the above-mentioned formulae (y-a1-1) to (y-a1-5).

Vb⁰ represents a single bond, an alkylene group, or a fluorinated alkylene group. The number of carbon atoms of the alkylene group and the fluorinated alkylene group for Vb⁰ is preferably 1 or more and 4 or less. Examples of the fluorinated alkylene group for Vb⁰ include groups in which part or all of hydrogen atoms of the alkylene group for Vb⁰ are substituted with fluorine atoms. Vb⁰ is preferably a linear fluorinated alkylene group having 1 or more and 4 or less carbon atoms or a single bond.

R⁰ represents a hydrogen atom, a fluorinated alkyl group having 1 or more and 5 or less carbon atoms, or a fluorine atom. R⁰ is preferably a hydrogen atom, a perfluoroalkyl group having 1 or more and 5 or less carbon atoms, and a fluorine atom, and more preferably a fluorine atom.

An anion represented by the formula (b1-3) is preferably an anion represented by the following formula (b1-4).

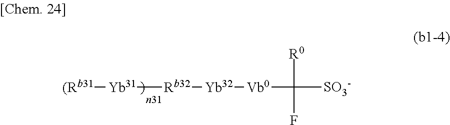

(In the formula (b1-4), R^{b31} represents a cyclic group which may have a substituent, Yb³¹ represents a divalent linking group, R^{b32} represents a cyclic group which may have a substituent, Yb³² represents a divalent linking group, n31 represents 0 or 1, Vb⁰ and R⁰ is the same group as those of Vb⁰ and R⁰ in the formula (b1-3).)

Examples of the cyclic group for R^{b31} which may have a substituent include the same groups as the cyclic group for R^{b101} which may have a substituent. The cyclic group for R^{b31} which may have a substituent is preferably a phenyl group which may have a substituent, and a condensed cyclic group including a condensed ring obtained by condensing an aliphatic hydrocarbon ring which may have a substituent and an aromatic ring. The substituent is preferably a halogen atom, and more preferably an iodine atom.

Examples of the cyclic group for R^{b32} which may have a substituent include the same groups as the cyclic group for R^{b101} which may have a substituent. The cyclic group for R^{b32} which may have a substituent is preferably a phenyl group which may have a substituent, and a condensed cyclic group including a condensed ring obtained by condensing an aliphatic hydrocarbon ring which may have a substituent and an aromatic ring. The substituent is preferably a halogen atom, and more preferably an iodine atom.

Examples of the divalent linking group for Yb³¹ include the same groups as the divalent linking group for Yb⁰. The divalent linking group for Y^{b31} is preferably a divalent linking group including an ester bond, and a divalent linking group including an ether bond, and more preferably an ester bond.

Examples of the divalent linking group for Yb³² include the same groups as the divalent linking group for Yb⁰. The divalent linking group for Yb³² is preferably a divalent linking group including an ester bond, and a divalent linking group including an ether bond, and more preferably an ester bond.

It is preferable that n31 is 1.

Specific examples of the anion moiety of the photoacid generating agent (B1) are shown below.

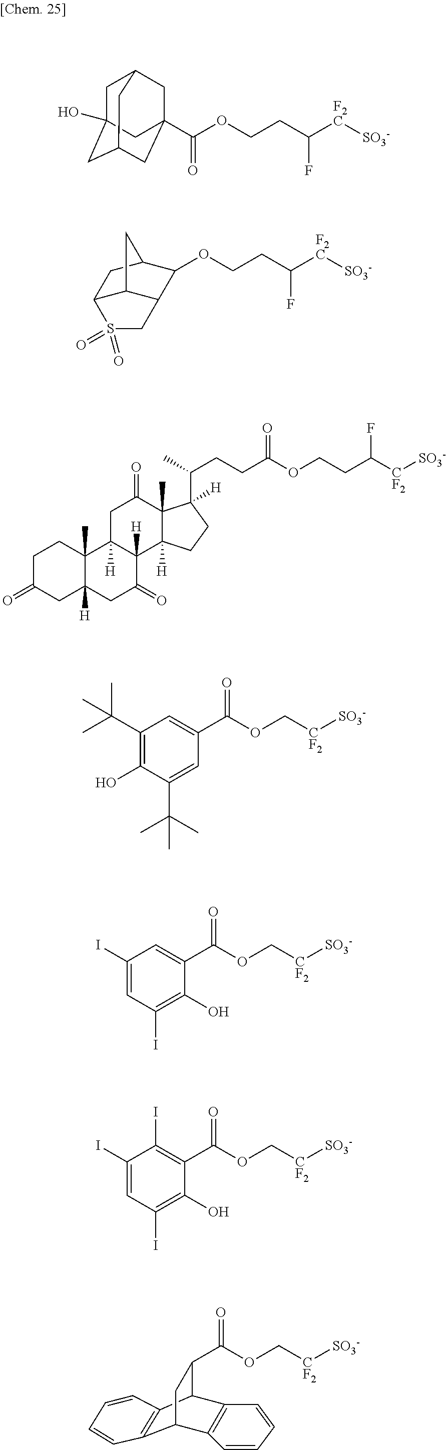

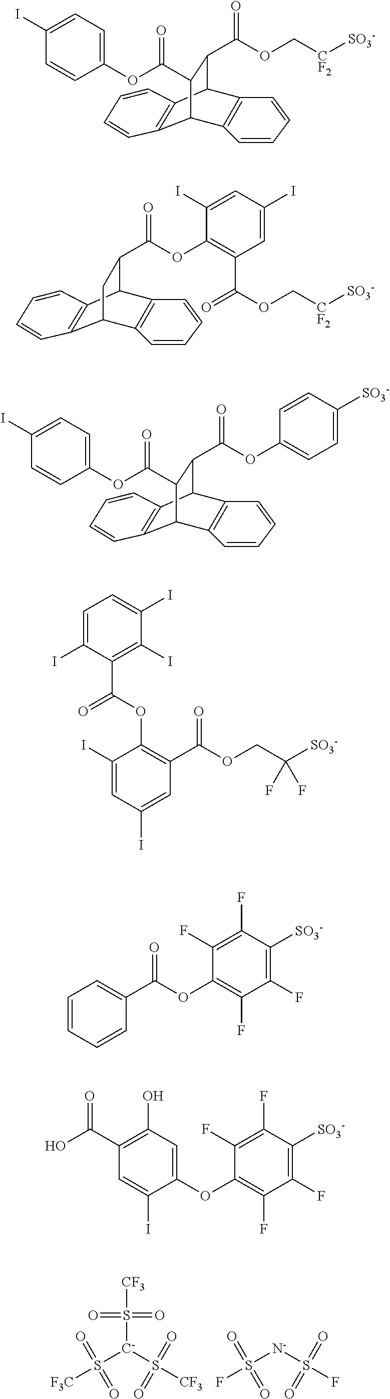

The content of the photoacid generating agent (B1) is preferably 5 parts by mass or more and 80 parts by mass or less, more preferably 10 parts by mass or more and 60 parts by mass or less, and further preferably 15 parts by mass or more and 50 parts by mass or less with respect to 100 parts by mass of the silicon-containing polymer (A). When the content of the photoacid generating agent (B1) is in the above preferable range, effect of the present invention can be easily obtained.

### [Other Photoacid Generating Agent]

The photoacid generating agent (B) may include a photoacid generating agent other than the photoacid generating agent (B1).

Other photoacid generating agent is not particularly limited, and any photoacid generating agents that have been proposed for the photosensitive composition can be used.

Examples of such photoacid generating agents include an onium salt-based acid generating agent such as an iodonium salt or a sulfonium salt, and an oximesulfonate-based acid generating agent; diazomethane-based acid generating agent such as bisalkyl or bisarylsulfonyl diazomethanes, poly(bissulfonyl)diazomethanes; various photoacid generating agents such as nitrobenzylsulfonate-based acid generating agents, iminosulfonate-based acid generating agents, disulfone-based acid generating agents, and the like.

The proportion of mass of the photoacid generating agent (B1) with respect to 100% by mass of the mass of the photoacid generating agent (B) is preferably 50% by mass or more, more preferably 70% by mass or more, further preferably 90% by mass or more, particularly preferably 95% by mass or more, and may be 100% by mass.

The content of the photoacid generating agent (B) is preferably 5 parts by mass or more and 80 parts by mass or less, more preferably 10 parts by mass or more and 60 parts by mass or less, and further preferably 15 parts by mass or more and 50 parts by mass or less with respect to 100 parts by mass of the silicon-containing polymer (A). When the content of the photoacid generating agent (B) is in the above preferable range, a desired effect can be easily obtained.

### <Crosslinking Agent (C)>

Examples of the crosslinking agents (C) include melamine-based crosslinking agents, urea-based crosslinking agents, alkylene urea-based crosslinking agents, glycoluril-based crosslinking agents, phenol-based crosslinking agents, and epoxy-based crosslinking agents. In the following description, the term “lower” means that the number of carbon atoms is 1 or more and 5 or less.

Examples of the melamine-based crosslinking agents include compounds obtained by substituting a part or all of hydrogen atoms in an amino group of melamine with a hydroxymethyl group, and compounds obtained by substituting a part or all of hydrogen atoms in an amino group of melamine with a lower alkoxymethyl group, and the like. Specifically, hexamethoxymethylmelamine, hexaethoxymethylmelamine, hexapropoxymethylmelamine, hexabutoxybutylmelamine, and the like, are preferable, and, hexamethoxymethylmelamine is more preferable.

Examples of the urea-based crosslinking agents include compounds obtained by substituting a part or all of hydrogen atoms in an amino group of urea with a hydroxymethyl group, and compounds obtained by substituting a part or all of hydrogen atoms in an amino group of urea with a lower alkoxymethyl group, and the like. Specifically, bismethoxymethyl urea, bisethoxymethyl urea, bispropoxymethyl urea, and bisbutoxymethyl urea, and the like, are preferable, and bismethoxymethyl urea is more preferable.

Examples of the alkylene urea-based crosslinking agents include compounds represented by the following formula (CA-1).

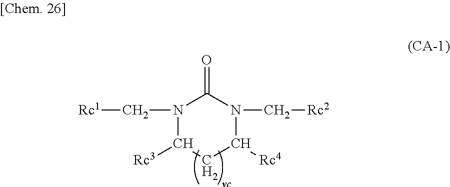

(In the formula (CA-1), Rc¹ and Rc² each independently represent a hydroxy group or a lower alkoxy group. Rc³ and Rc⁴ each independently represent a hydrogen atom, a hydroxy group, or a lower alkoxy group. vc represents an integer of 0 or more and 2 or less.)

When Rc¹ and Rc² are lower alkoxy groups, the lower alkoxy groups are preferably alkoxy groups having 1 or more and 4 or less carbon atoms. The lower alkoxy groups may be a linear alkoxy group or a branched alkoxy group. Rc¹ and Rc² may be the same as or different from each other, and are more preferably the same as each other.

When Rc³ and Rc⁴ are lower alkoxy groups, the lower alkoxy groups are preferably alkoxy groups having 1 or more and 4 or less carbon atoms. The lower alkoxy groups may be a linear alkoxy group or a branched alkoxy group. Rc³ and Rc⁴ may be the same as or different from each other, and are more preferably the same as each other.

It is preferable that vc is 00 or 1.

The alkylene urea-based crosslinking agent is particularly preferably a compound in which vc is 0 (ethylene urea-based crosslinking agent) and/or a compound in which vc is 1 (propylene urea-based crosslinking agent).

Specific examples of the alkylene urea-based crosslinking agents include ethylene urea-based crosslinking agents such as monohydroxymethylated ethylene urea, dihydroxymethylated ethylene urea, monomethoxymethylated ethylene urea, dimethoxymethylated ethylene urea, monoethoxymethylated ethylene urea, diethoxymethylated ethylene urea, monopropoxymethylated ethylene urea, dipropoxymethylated ethylene urea, monobutoxymethylated ethylene urea, and dibutoxymethylated ethylene urea; propylene urea-based crosslinking agent such as monohydroxymethylated propylene urea, dihydroxymethylated propylene urea, monomethoxymethylated propylene urea, dimethoxymethylated propylene urea, monoethoxymethylated propylene urea, diethoxymethylated propylene urea, monopropoxymethylated propylene urea, dipropoxymethylated propylene urea, monodibutoxymethylated propylene urea and dibutoxymethylated propylene urea; 1,3-di(methoxymethyl)4,5-dihydroxy-2-imidazolidinone, 1,3-di(methoxymethyl)-4,5-dimethoxy-2-imidazolidinone, and the like.

Examples of the glycoluril-based crosslinking agents include glycoluril derivatives obtained by substituting the N-position with one or both of a hydroxyalkyl group and an alkoxyalkyl group having 1 or more and 4 or less carbon atoms. The glycoluril derivative can be obtained by subjecting glycoluril and formalin to a condensation reaction, or by subjecting this product to a reaction with a lower alcohol.

Specific examples of the glycoluril-based crosslinking agent include hydroxymethylated glycoluril such as monohydroxymethylated glycoluril, dihydroxymethylated glycoluril, trihydroxymethylated glycoluril, and tetrahydroxymethylated glycoluril; methoxymethylated glycoluril such as monomethoxymethylated glycoluril, dimethoxymethylated glycoluril, trimethoxymethylated glycoluril, and tetramethoxymethylated glycoluril; ethoxymethylated glycoluril such as monoethoxymethylated glycoluril, diethoxymethylated glycoluril, triethoxymethylated glycoluril, and tetraethoxymethylated glycoluril; propoxymethylated glycoluril such as monopropoxymethylated glycoluril, dipropoxymethylated glycoluril, tripropoxymethylated glycoluril, and tetrapropoxymethylated glycoluril; butoxymethylated glycoluril such as monobutoxymethylated glycoluril, dibutoxymethylated glycoluril, tributoxymethylated glycoluril, tetrabutoxymethylated glycoluril, and the like.

The phenol-based crosslinking agent is not particularly limited as long as it is a compound having a plurality of phenol nucleus structures in the same molecule, and the compound in which a position adjacent to the binding position of a phenol-based hydroxy group on the aromatic ring is substituted with a methylol group and/or an alkoxyalkyl group. The crosslinking reactivity is improved when a plurality of phenol nucleus structures is included.

The number of phenol nucleus structures is preferably 2 or more and 5 or less, more preferably 2 or more and 4 or less, and further preferably 2 or 3.

The epoxy-based crosslinking agent is not particularly limited as long as it is a crosslinking agent having an epoxy group, and can be freely selected and used from well-known epoxy-based crosslinking agents. Crosslinking agents having 2 or more epoxy groups are preferable from the viewpoint that the crosslinking reactivity is improved.

The number of epoxy groups in one molecule of the epoxy-based crosslinking agent is preferably 2 or more, more preferably 2 or more and 4 or less, and most preferably 2.

As the crosslinking agent (C), a crosslinking agent (C1) having a methylol group and/or an alkoxyalkyl group is preferable, and among them, a crosslinking agent selected from the group consisting of a glycoluril-based crosslinking agent and a phenol-based crosslinking agent is more preferable. As such crosslinking agent, suitable examples include a compound represented by formula (c1-1).

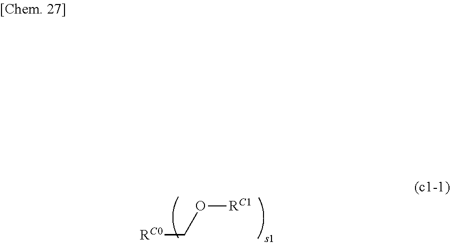

(In the formula (c1-1), s1 represents an integer of 1 or more and 10 or less. R^{C0} represents a glycoluril structure, or a polynuclear phenol structure. R^{C1} represents an alkyl group having 1 or more and 5 or less carbon atoms, or a hydrogen atom.)

As described above, Os1 represents an integer of 1 or more and 10 or less, preferably an integer of 2 or more and 10 or less, and more preferably an integer of 4 or more and 9 or less.

A glycoluril structure in R^{C0} is a structure represented by the following formula (R^{C0}-1).

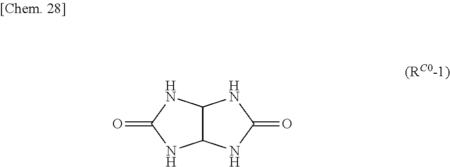

The polynuclear phenol structure for R^{C0} is a structure including two or more structures selected from the group consisting of a phenol structure and a naphthol structure.

Suitable specific examples of the crosslinking agent (C) include the following compounds.

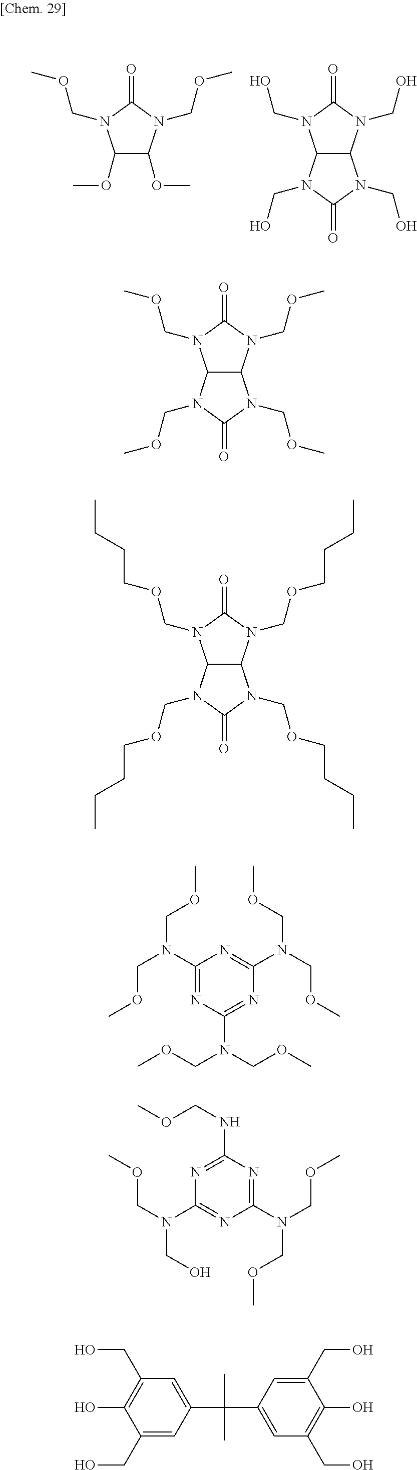

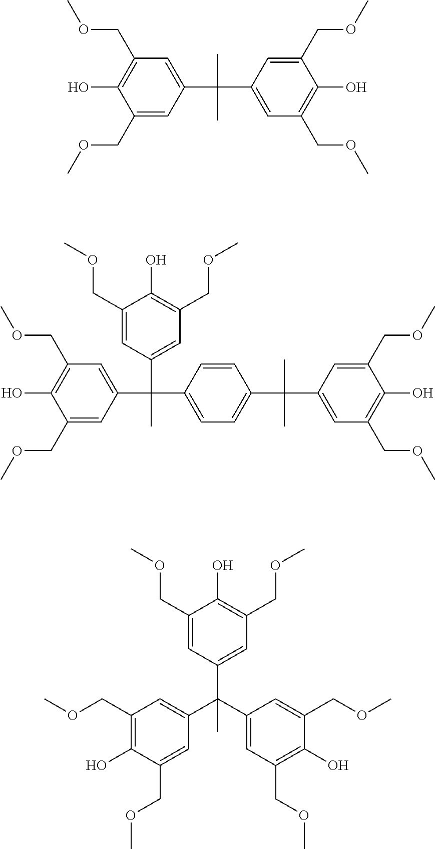

One kind of the crosslinking agent (C) may be used alone, or two or more kinds thereof may be used in combination.

The content of the crosslinking agent (C) is preferably 1 part by mass or more and 50 parts by mass or less, more preferably 3 parts by mass or more and 40 parts by mass or less, further preferably 5 parts by mass or more and 30 parts by mass or less, and particularly preferably 5 parts by mass or more and 25 parts by mass or less with respect to 100 parts by mass of the silicon-containing polymer (A).

When the amount used of the crosslinking agent (C) is equal to or more than the lower limit value of the above preferable range, formation of crosslinks sufficiently proceeds and dissolution contrast is easily obtained, and an excellent cured film with improved resolution performance and lithography properties of the photosensitive composition and with little swelling is easily formed.

When the amount used of the crosslinking agent (C) is equal to or less than the upper limit value of the above preferable range, the storage stability of the photosensitive composition is good, and the deterioration of the sensitivity over time is easily suppressed.

### <Base Component (D) for Controlling Diffusion of Acid Generated Upon Exposure>

A photosensitive composition preferably contains a base component (D) for controlling diffusion of an acid generated upon exposure.

The base component (D) acts as a quencher (acid diffusion control agent) which traps an acid generated in the photosensitive composition upon exposure.

Examples of the base component (D) include a photodegradable base (D1) that is to be decomposed upon exposure and loses acid diffusion controllability, and a nitrogen-containing organic compound (D2) which does not fall under the category of the photodegradable base (D1). As the base component (D), the photodegradable base (D1) is preferable from the viewpoint of increasing the sensitivity, reducing the roughness, and suppressing the occurrence of coating defects.

When the photosensitive composition containing the photodegradable base (D1) is used, upon formation of a patterned cured film, contrast between an exposed part of the coating film made of the photosensitive composition and an unexposed part can be further improved.

The photodegradable base (D1) is not particularly limited as long as it is a base that is decomposable upon exposure and is preferably a compound represented by the following formula (d1-1) (hereinafter, also referred to as a “component (d1-1)”).

The component (d1-1) is decomposed and loses the acid diffusion controllability (basicity) at exposed parts of the coating film made of the photosensitive composition, and therefore, does not act as a quencher, while the component acts as a quencher at unexposed parts of the coating film.

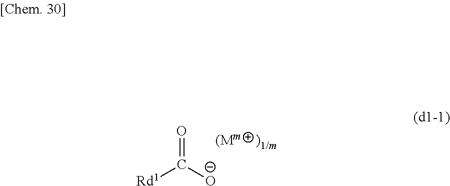

(In the formula, Rd¹ represents a monovalent organic group. m represents an integer of 1 or more, and M^{m+} each independently represents m-valent organic cation.)
{Component (d1-1)}

### Anion Moiety

In the formula (d1-1), Rd¹ represents a monovalent organic group. The monovalent organic group is not particularly limited as long as the component (d1-1) acts well as a quencher. As the monovalent organic group, a cyclic group which may have a substituent, an alkyl group which may have a substituent, and an alkenyl group which may have a substituent are preferable. Examples of these groups respectively include the same group as the R′^{201.}

As Rd¹, an aromatic hydrocarbon group which may have a substituent, an aliphatic cyclic group which may have a substituent, and an alkyl group which may have a substituent are preferable, and an aromatic hydrocarbon group which may have a substituent is more preferable.

Examples of substituents which may be included by these groups include a hydroxy group, an oxo group (═O), an alkyl group, an aryl group, a fluorine atom, a bromine atom, an iodine atom, a fluorinated alkyl group, and a lactone-containing cyclic group.

As the monovalent organic group for Rd¹, a group in which a divalent group including an ether bond or an ester bond is bonded to a cyclic group which may have a substituent, an alkyl group which may have a substituent, and an alkenyl group which may have a substituent are also preferable. As the divalent group including an ether bond or an ester bond, linking groups respectively represented by the formulae (y-a1-1) to (y-a1-5) are preferable.

In this case, suitable examples of the cyclic groups bonded to the above-mentioned linking group include a phenyl group, a naphthyl group, a polycyclic structure including a bicyclooctane skeleton (a polycyclic structure including a bicyclooctane skeleton and a ring structure other than this structure). These cyclic groups may include the above-mentioned substituent.

As the cyclic group to be bonded to the above-mentioned linking group, a group in which one or more hydrogen atoms are removed from polycycloalkanes such as adamantane, norbornane, isobornane, bicyclodecane, tricyclododecane, tetracyclododecane is also preferable.

As the alkyl group to be bonded to the above-mentioned linking group, an alkyl group having 1 or more and 10 or less carbon atoms is preferable. Specific examples thereof include linear alkyl groups such as a methyl group, an ethyl group, an n-propyl group, an n-butyl group, an n-pentyl group, an n-hexyl group, an n-heptyl group, an n-octyl group, an n-nonyl group, and an n-decyl group; branched alkyl groups such as a 1-methylethyl group (isopropyl group), a 1-methylpropyl group (sec-butyl group), a 2-methylpropyl group (isobutyl group), a 1-methylbutyl group (sec-pentyl group), a 2-methylbutyl group, a 3-methylbutyl group (isopentyl group), a 1-ethylbutyl group, a 2-ethylbutyl group, a 1-methylpentyl group, a 2-methylpentyl group, a 3-methylpentyl group, and a 4-methylpentyl group.

When the above-mentioned alkyl group is a fluorinated alkyl group having a fluorine atom or a fluorinated alkyl group as a substituent, the number of carbon atoms of the fluorinated alkyl group is preferably 1 or more and 11 or less, more preferably 1 or more and 8 or less, and further preferably 1 or more and 4 or less. The fluorinated alkyl group may contain an atom other than the fluorine atom.

Preferable specific examples of the anion moiety of the component (d1-1) are shown below.

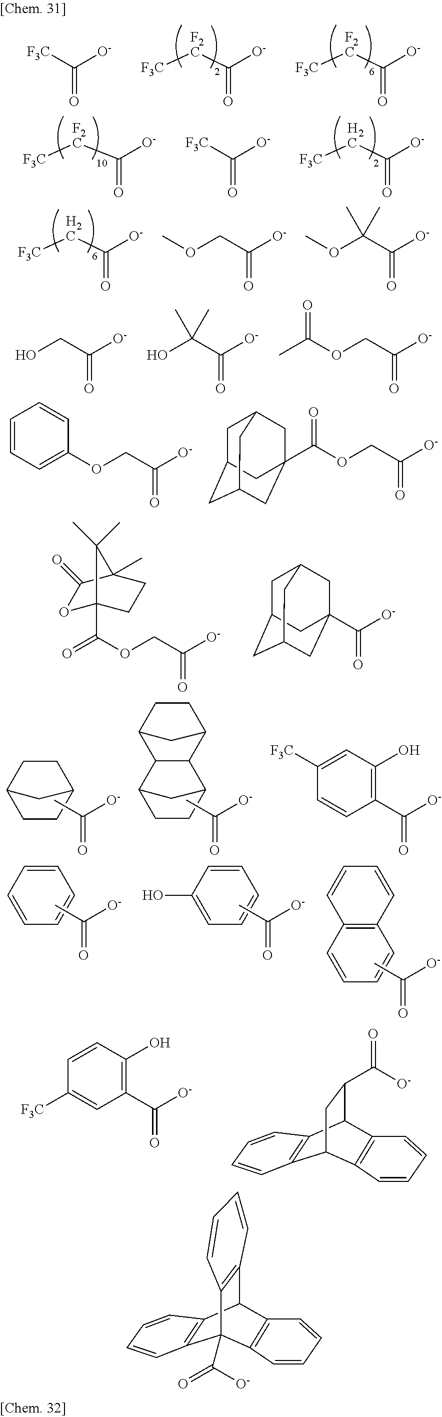

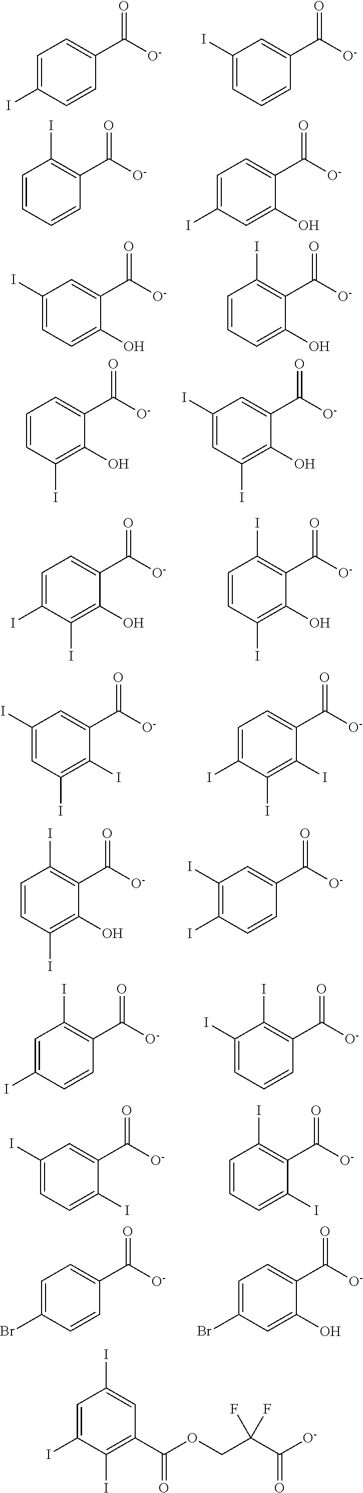

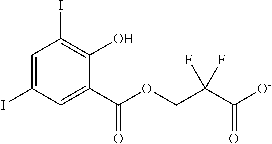 [SMILES: O=C(OCC(F)(F)C(=O)[O-])c1cc(I)cc(I)c1O]

### Cation Moiety

In the formula (d1-1), M^{m+} represents m-valent organic cation.

Examples of the organic cation represented by M^{m+} suitably include the cations same as the sulfonium cation represented by the formula (b1-1).

Furthermore, as the organic cation represented by M^{m+}, cations represented by the following formula (d1-1a) are also preferable.

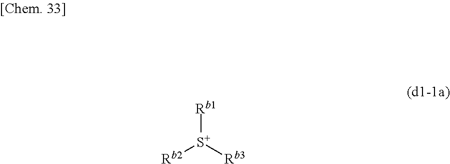

(In the formula (d1-1a), R^{b1} represents an aryl group including a fluorine atom, or an aryl group including a fluorinated alkyl group. R^{b2} and R^{b3} each independently represents an aryl group which may have a substituent, an alkyl group which may have a substituent, or an alkenyl group which may have a substituent. Two of R^{b1} to R^{b3} may be bonded to each other to form a ring together with a sulfur atom in the formula.)

In the formula (d1-1a), R^{b1} represents an aryl group including a fluorine atom, or an aryl group including a fluorinated alkyl group.

The number of carbon atoms of the aryl group for R^{b1} is preferably 5 or more and 30 or less, more preferably 5 or more and 20 or less, further preferably 6 or more and 15 or less, and particularly preferably 6 or more and 10 or less. However, the number of carbon atoms of the aryl group does not include the number of carbon atoms of the substituent.

Specific examples of the aryl groups for R^{b1} are preferably a phenyl group, a naphthyl group, an anthryl group, a phenanthryl group, and a biphenyl group, more preferably a phenyl group and a naphthyl group, and further preferably a phenyl group.

Specific examples of the fluorinated alkyl group of the aryl group for R^{b1} include a group in which a part or all of hydrogen atoms of the alkyl group having 1 or more and 12 or less carbon atoms are substituted with a fluorine atom. The fluorinated alkyl group may be a linear fluorinated alkyl group or a branched fluorinated alkyl group.

Specific examples of the linear fluorinated alkyl groups having carbon atoms 1 or more and 12 or less include groups in which a part or all of the hydrogen atoms of a methyl group, an ethyl group, an n-propyl group, an n-butyl group, an n-pentyl group, an n-hexyl group, an n-heptyl group, an n-octyl group, an n-nonyl group, an n-decyl group, an n-undecyl group, or an n-dodecyl group are substituted with a fluorine atom. Specific examples of the branched fluorinated alkyl group having 1 or more and 12 or less include groups in which part or all of the hydrogen atoms of a 1-methylethyl group (isopropyl group), a 1,1-dimethylethyl group (tert-butyl group), a 1-methylpropyl group (sec-butyl group), a 2-methylpropyl group (isobutyl group), a 1-methylbutyl group (sec-pentyl group), a 2-methylbutyl group, a 3-methylbutyl group (isopentyl group), a 1-ethylbutyl group, a 2-ethylbutyl group, a 1-methylpentyl group, a 2-methylpentyl group, a 3-methylpentyl group, and a 4-methylpentyl group are substituted with fluorine atoms.

The fluorinated alkyl group included in the aryl group for R^{b1} is preferably a group obtained by substituting a part or all of the hydrogen atoms having 1 or more and 5 or less carbon atoms with a fluorine atom, more preferably groups obtained by substituting a part or all of the hydrogen atoms in the alkyl group having 1 or more and 3 or less carbon atoms with a fluorine atom, and further preferably a trifluoromethyl group.

The aryl group for R^{b1} may have a substituent other than a fluorine atom or a fluorinated alkyl group. Examples of the substituent include an alkyl group, a halogen atom other than a fluorine atom, a halogenated alkyl group other than a fluorinated alkyl group, an oxo group (═O), a cyano group, an amino group, a group respectively represented by the above formulae (ca-r-1) to (ca-r-7), a monovalent group represented by —SO₂—R^{b0}, and the like. R^{b0} is a linear alkyl group which may have a substituent, a branched alkyl group which may have a substituent, an alicyclic hydrocarbon group which may have a substituent, or an aromatic hydrocarbon group which may have a substituent.

Examples of the linear alkyl group and branched alkyl group for R^{b0} include a methyl group, an ethyl group, an n-propyl group, an isopropyl group, an n-butyl group, an isobutyl group, a tert-butyl group, an n-pentyl group, an isopentyl group, a neopentyl group, and the like, and a methyl group and an ethyl group are preferable, and a methyl group is more preferable.

Examples of the substituent, which may be included by linear alkyl group and branched alkyl group as R^{b0}, include a halogen atom, a halogenated alkyl group having 1 or more and 5 or less carbon atoms, an alkoxy group having 1 or more and 5 or less carbon atoms, a hydroxy group, an oxo group (═O), a carboxy group, and the like.

The number of carbon atoms of the alicyclic hydrocarbon group for R^{b0} is preferably 3 or more and 20 or less, and more preferably 3 or more and 12 or less. The alicyclic hydrocarbon group may be a polycyclic group, or a monocyclic group. Preferable example of the monocyclic alicyclic hydrocarbon group, a group obtained by removing one or more hydrogen atoms from monocycloalkane. As the monocycloalkane, monocycloalkane having 3 or more and 6 or less carbon atoms is preferable. Specific examples of the monocycloalkane include cyclobutane, cyclopentane, cyclohexane, and the like. The polycyclic alicyclic hydrocarbon group is preferably a group obtained by removing one or more hydrogen atoms from a polycycloalkane.

The polycycloalkane is preferably a polycycloalkane having 7 or more and 12 or less carbon atoms. Specific examples of the polycycloalkane include adamantane, norbornane, isobornane, tricyclodecane, tetracyclododecane, and the like.

Examples of the aromatic hydrocarbon group as R^{b0} include a group obtained by removing one hydrogen atom from an aromatic hydrocarbon ring such as a benzene ring, a naphthalene ring, an anthracene ring, a phenanthrene ring, a biphenyl ring, and a fluorene ring.

Examples of the substituent which may be included by the alicyclic hydrocarbon group or the aromatic hydrocarbon group for R^{b0} include —R^{P1}, —R^{P2}—O—R^{P1}, —R^{P2}—CO—R^{P1}, —R^{P2}—CO—OR^{P1}, —R^{P2}—O—CO—R^{P1}, —R^{P2}—OH, —R^{P2}—CN, —R^{P2}—COOH, and the like.

Herein, R^{P1} represents a monovalent chain saturated hydrocarbon group having 1 or more and 10 or less carbon atoms, a monovalent aliphatic cyclic saturated hydrocarbon group having 3 or more and 20 or less carbon atoms, or a monovalent aromatic hydrocarbon group having 6 or more and 30 or less carbon atoms. Furthermore, R^{P2} is a single bond, a divalent chain saturated hydrocarbon group having 1 or more and 10 or less carbon atoms, a divalent aliphatic cyclic saturated hydrocarbon group having 3 or more and 20 or less carbon atoms, or a divalent aromatic hydrocarbon group having 6 or more and 30 or less carbon atoms. However, a part or all of hydrogen atoms in the chain saturated hydrocarbon group, the aliphatic cyclic saturated hydrocarbon group, and the aromatic hydrocarbon group for R^{P1} and R^{P2} may be substituted with a fluorine atom. The above aliphatic cyclic hydrocarbon group may have one or more of one kind of the above substituent alone or may have one or more of each of the plurality of kinds of the above substituents.

Examples of the monovalent chain saturated hydrocarbon group (alkyl group) having 1 or more and 10 or less carbon atoms include a methyl group, an ethyl group, an n-propyl group, an n-butyl group, an n-pentyl group, an n-hexyl group, an n-heptyl group, an n-octyl group, an n-decyl group, and the like.

Examples of the monovalent aliphatic cyclic saturated hydrocarbon group having 3 or more and 20 or less carbon atoms include monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and a cyclododecyl group; polycyclic aliphatic saturated hydrocarbon groups such as a bicyclo[2.2.2]octanyl group, a tricyclo[5.2.1.02, 6]decanyl group, a tricyclo[3.3.1.13, 7]decanyl group, a tetracyclo[6.2.1.13, 6.02, 7]dodecanyl group, and an adamantyl group.

Examples of the monovalent aromatic hydrocarbon group having 6 or more and 30 or less carbon atoms include a group obtained by removing one hydrogen atom from an aromatic hydrocarbon ring such as a benzene ring, a biphenyl ring, a fluorene ring, a naphthalene ring, an anthracene ring, and a phenanthrene ring.

R^{b2} and R^{b3} each independently an aryl group which may have a substituent, an alkyl group which may have a substituent, or an alkenyl group which may have a substituent. The aryl group for R^{b2} and R^{b3} are the same groups as the aryl group for R^{b1}.

The aryl group for R^{b2} and R^{b3} is preferably a phenyl group, a naphthyl group, an anthryl group, a phenanthryl group, and a biphenyl group, more preferably a phenyl group and a naphthyl group, and further preferably a phenyl group.

The alkyl group for R^{b2} and R^{b3} is preferably an alkyl group having 1 or more and 30 or less carbon atoms.

The alkenyl group in R^{b2} and R^{b3} is preferably an alkenyl group having 2 or more and 10 or less carbon atoms.

Examples of the substituents which may be included by R^{b2} and R^{b3} include an alkyl group, a halogen atom, a halogenated alkyl group, an oxo group (═O), a cyano group, an amino group, an aryl group, and groups respectively represented by the above formulae (ca-r-1) to (ca-r-7), and the like.

R^{b2} and R^{b3} are preferably an aryl group which may have a substituent. When the aryl group includes a substituent, the substituent is preferably a fluorine atom, an iodine atom, a fluorinated alkyl group, and a monovalent group represented by the above-SO₂—R^{b0}, and more preferably a fluorine atom, an iodine atom, a fluorinated alkyl group, and a methanesulfonyl group (mesyl group). As R^{b2} and R^{b3}, an unsubstituted aryl group, and an aryl group having a fluorine atom, an aryl group having a fluorinated alkyl group, and an aryl group having a methanesulfonyl group (mesyl group) are particularly preferable.

Two of R^{b1} to R^{b3} may be bonded to each other to form a ring together with a sulfur atom in the formula. When two of R^{b1} to R^{b3} are bonded to each other to form a ring together with a sulfur atom in the formula, two of R^{b1} to R^{b3} may be bonded to each other, a heteroatom such as a sulfur atom, an oxygen atom, and a nitrogen atom, or a bond such as —SO—, —SO₂—, —SO₃—, —C(═O)—, —COO—, —CONH— or —N(R_{N})— (R is an alkyl group having 1 or more and 5 or less carbon atoms). As a ring to be formed, one ring including a sulfur atom in the ring skeleton of the formula is preferably a ring with 3 or more to 10 or less members, and particularly preferably a ring with 5 or more and 7 or less members, including the sulfur atom. Specific examples of the formed ring include a thiophene ring, a thiazole ring, a benzothiophene ring, a dibenzothiophene ring, a 9H-thioxanthene ring, a thianthrene ring, a phenoxathiin ring, a tetrahydrothiophenium ring, a tetrahydrothiopyranium ring, and the like.

When R^{b1}, and R^{b2} or R^{b3} are bonded to each other to form a ring together with a sulfur atom in the formula, it is enough that the ring structure to be formed may include a fluorine atom or a fluorinated alkyl group, and a hydrogen atom of a structure derived in the aryl group (for example, the benzene ring structure) may not be substituted with a fluorine atom or a fluorinated alkyl group.

Preferable specific examples of cations represented by the formula (d1-1a) are shown below.

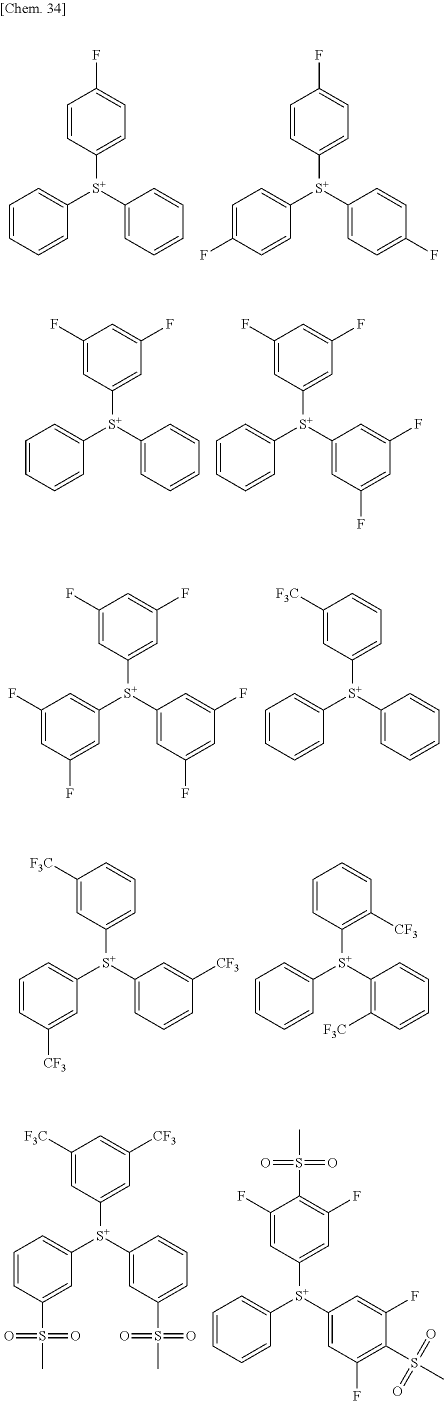

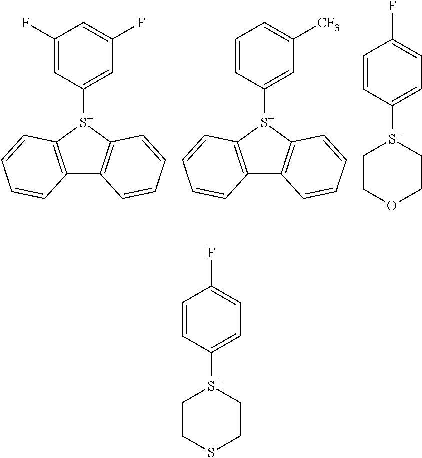 [SMILES: Fc1cc(F)cc(-[s+]2c3ccccc3c3ccccc32)c1 ; FC(F)(F)c1cccc(-[s+]2c3ccccc3c3ccccc32)c1 ; Fc1ccc([S+]2CCOCC2)cc1 ; Fc1ccc([S+]2CCSCC2)cc1]

When the photosensitive composition contains a photodegradable base (D1), in the photosensitive composition, the content of the photodegradable base (D1) is preferably 10 parts by mass or more, more preferably 15 parts by mass or more and 70 parts by mass or less, and further preferably 20 parts by mass or more and 60 parts by mass or less with respect to 100 parts by mass of the silicon-containing polymer (A).

When the content of the photodegradable base (D1) is equal to or more than the lower limit value of the above preferable range, the photosensitive composition has particularly excellent lithography properties, and a patterned cured film having a good shape is easily formed. When the content of the photodegradable base (D1) is equal to or less than the upper limit value of the above preferable range, the excellent sensitivity of the photosensitive composition and excellent throughput is achieved.

The content of the component (d1-1) with respect to the entire base component (D) is preferably 50% by mass or more, more preferably 70% by mass or more, and further preferably 90% by mass or more, and may be 100% by mass.

### —Component (D2)

The component (D) may contain the nitrogen-containing organic compound component (component (D2)) which does not fall under the category of the photodegradable base (D1).

The nitrogen-containing organic compound component (D2) is not particularly limited as long as it acts as an acid diffusion control agent and does not fall under the category of the photodegradable base (D1), and may be arbitrarily selected from the known nitrogen-containing organic compounds. As the nitrogen-containing organic compound component (D2), aliphatic amine is preferable, and secondary aliphatic amine and tertiary aliphatic amine are more preferable.

The aliphatic amines are an amine having one or more aliphatic groups. The number of carbon atoms of the aliphatic group include in the aliphatic amine is preferably 1 or more and 12 or less.

Examples of the aliphatic amines include alkylamine in which at least one hydrogen atom of ammonia NH₃ is substituted with an alkyl group having 12 or less carbon atoms, alkanolamine in which at least one hydrogen atom of ammonia NH₃ is substituted with a hydroxyalkyl group having 1 or more and 12 or less carbon atoms, and cyclic amine.

Specific examples of alkylamines and alkanolamines include: monoalkylamines such as n-hexylamine, n-heptylamine, n-octylamine, n-nonylamine, and n-decylamine; dialkylamines such as diethylamine, di-n-propylamine, di-n-heptylamine, and di-n-octylamine; trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, and tri-n-dodecylamine; alkanolamines such as diethanolamine, triethanolamine, diisopropanolamine, triisopropanolamine, di-n-octanolamine, and tri-n-octanolamine. Among them, trialkylamines having 5 or more and 10 or less carbon atoms are more preferable, and tri-n-pentylamine or tri-n-octylamine are more preferable.

Examples of the cyclic amine include heterocyclic compounds containing a nitrogen atom as a heteroatom. The heterocyclic compound may be a monocyclic compound (aliphatic monocyclic amine) or a polycyclic compound (aliphatic polycyclic amine).

Specific examples of the aliphatic monocyclic amine include piperidine, piperazine and the like.

The aliphatic polycyclic amine is preferably an amine having 6 or more and 10 or less carbon atoms. Specific examples thereof include 1,5-diazabicyclo[4.3.0]-5-nonene, 1,8-diazabicyclo[5.4.0]-7-undecene, hexamethylenetetramine, 1,4-diazabicyclo[2.2.2]octane, and the like.

Examples of other aliphatic amines include dicyclohexylamine, tris(2-methoxymethoxyethyl)amine, tris {2-(2-methoxyethoxy)ethyl}amine, tris {2-(2-methoxyethoxymethoxy)ethyl}amine, tris {2-(1-methoxyethoxy)ethyl}amine, tris {2-(1-ethoxyethoxy)ethyl}amine, tris {2-(1-ethoxypropoxy)ethyl}amine, tris[2-{2-(2-hydroxyethoxy) ethoxy}ethyl]amine, triethanolamine triacetate, and the like, and triethanolamine triacetate is preferable.

For the nitrogen-containing organic compound component (D2), amines having an aromatic group may be used.

Examples of amines having an aromatic group include 4-dimethylaminopyridine, pyrrole, indole, pyrazole, imidazole, imidazole derivatives, tribenzylamine, 2,6-diisopropylaniline, N-tert-butoxycarbonylpyrrolidine, 2,6-di-tert-butylpyridine, and the like.

One kind of the nitrogen-containing organic compound component (D2) may be used alone, or two or more kinds thereof may be used in combination.

When the photosensitive composition contains the nitrogen-containing organic compound (D2), the content of the nitrogen-containing organic compound component (D2) is used generally within a range of 0.01 parts by mass or more and 5 parts by mass or less with respect to 100 parts by mass of the silicon-containing polymer (A). Within the above range, the pattern shape of the patterned cured film is good, and post exposure stability of the photosensitive composition is improved.

<At Least One Compound (E) Selected from a Group Consisting of Organic Carboxylic Acids, Phosphorus Oxoacids, and Derivatives Thereof>

The photosensitive composition may contain, at least one compound (E) selected from the group consisting of organic carboxylic acids, phosphorus oxoacids, and derivative thereof as optional components for the purpose of preventing deterioration in sensitivity, formation of patterned cured film having good pattern shape, and improving post exposure stability.

As the organic carboxylic acids, acetic acid, malonic acid, citric acid, malic acid, succinic acid, benzoic acid, salicylic acid and the like are preferable.

As the phosphorus oxoacids, phosphoric acid, phosphonic acid, and phosphinic acid, and the like are preferable, and phosphonic acid is more preferable.

Examples of the derivative of the phosphorus oxoacid include an ester compound in which the hydrogen atom of the oxo acid is substituted with a hydrocarbon group. Examples of the hydrocarbon group include an alkyl group having 1 or more and 5 or less carbon atoms, an aryl group having 6 or more and 15 less carbon atoms, and the like.

Examples of the derivative of phosphoric acid include phosphoric acid esters such as di-n-butyl phosphoric acid ester, diphenyl phosphoric acid ester, and the like. Examples of the phosphonic acid derivative include phosphonic acid esters such as phosphonic acid dimethyl ester, phosphonic acid-di-n-butyl ester, phenylphosphonic acid, phosphonic acid diphenyl ester, and phosphonic acid dibenzyl ester, and the like.

Examples of the derivative of the phosphinic acid include phosphinic acid ester, phenylphosphinic acid, and the like.

One kind of the component (E) may be used alone, or two or more kinds thereof may be used in combination.

When the photosensitive composition contains the compound (E), the content of the compound (E) is generally used in the range of 0.01 parts by mass or more and 10 parts by mass or less with respect to 100 parts by mass of the silicon-containing polymer (A).

### <Fluorine Additive (F)>

The photosensitive composition may contain a fluorine additive component (F) as a hydrophobic resin. The fluorine additive (F) is used for imparting water repellency to a cured film formed using the photosensitive composition. When the fluorine additive (F) is used as a resin other than the silicon-containing polymer (A) for photosensitive composition, lithography properties is improved.

As the component (F), for example, a fluorine-containing polymer compound described in Japanese Unexamined Patent Application, Publication No. 2010-002870, Japanese Unexamined Patent Application, Publication No. 2010-032994, Japanese Unexamined Patent Application, Publication No. 2010-277043, Japanese Unexamined Patent Application, Publication No. 2011-13569, or Japanese Unexamined Patent Application, Publication No. 2011-128226 can be used.

More specific examples of the fluorine additive (F) include polymers having a constituent unit (f1) represented by the following formula (f1-1). The polymer is preferably a polymer (homopolymer) consisting of only a constituent unit (f1) represented by the following formula (f1-1); a copolymer of a constituent unit including an acid-degradable group having polarity increased by the action of an acid and the constituent unit (f1); a copolymer of a constituent unit including an acid-degradable group having polarity increased by the action of an acid, the constituent unit (f1), and a constituent unit derived from acrylic acid or methacrylic acid. Herein, the constituent units being to be copolymerized with the constituent unit (f1) and including an acid-degradable group having polarity increased by the action of an acid are preferably a constituent unit derived from 1-ethyl-1-cyclooctyl(meth)acrylate or a constituent unit derived from 1-methyl-1-adamantyl(meth)acrylate.

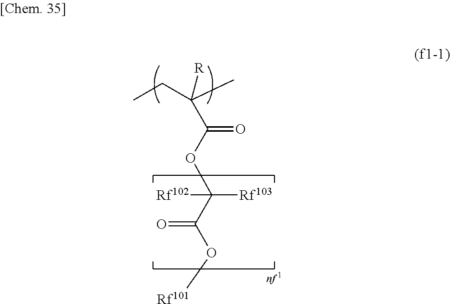

(In the formula (f1-1), R represents a hydrogen atom or an alkyl group having 1 or more and 5 or less carbon atoms, Rf¹⁰² and Rf¹⁰³ each independently represent a hydrogen atom, a halogen atom, an alkyl group having 1 or more and 5 or less carbon atoms, or a halogenated alkyl group having 1 or more and 5 or less carbon atoms, and Rf¹⁰² and Rf¹⁰³ may be the same as or different from each other. nf¹ represents an integer of 0 or more and 5 or less, and Rf¹⁰¹ represents an organic group containing a fluorine atom.)

Examples of R bonded to the carbon atom at the x-position include a hydrogen atom, or an alkyl group having 1 or more and 5 or less carbon atoms. R is preferably a hydrogen atom or a methyl group.

The halogen atom for Rf¹⁰² and Rf¹⁰³ is preferably a fluorine atom. The alkyl group having 1 or more and 5 or less carbon atoms for Rf¹⁰² and Rf¹⁰³ is preferably a methyl group or an ethyl group. Specific examples of the halogenated alkyl group having 1 or more and 5 or less carbon atoms for Rf¹⁰² and Rf¹⁰³ include groups obtained by substituting a part or all of hydrogen atoms in an alkyl group having 1 or more and 5 or less carbon atoms with a halogen atom. The halogen atom is preferably a fluorine atom. Rf¹⁰² and Rf¹⁰³ are preferably a hydrogen atom, a fluorine atom, and an alkyl group having 1 or more and 5 or less carbon atoms, more preferably a hydrogen atom, a fluorine atom, a methyl group, and an ethyl group.

As described above, nf¹ represents an integer of 0 or more and 5 or less, and is preferably an integer of 0 or more and 3 or less, and more preferably 1 or 2.

Rf¹⁰¹ represents an organic group including a fluorine atom. The organic group including a fluorine atom is preferably a hydrocarbon group including a fluorine atom.

The structure of the hydrocarbon group including a fluorine atom may be linear, branched, cyclic, and a combination of these structures. The number of carbon atoms of the hydrocarbon group including a fluorine atom is preferably 1 or more and 20 or less, more preferably 1 or more and 15 or less, and further preferably 1 or more and 10 or less.

In the hydrocarbon group including a fluorine atom, preferably 25% or more of hydrogen atoms in the hydrocarbon group are fluorinated, more preferably 50% or more of the hydrogen atoms are fluorinated, and particularly preferably 60% or more of the hydrogen atoms are fluorinated.

Rf¹⁰¹ is more preferably a fluorinated hydrocarbon group having 1 or more and 6 or less carbon atoms, and further preferably a trifluoromethyl group, —CH₂—CF₃, —CH₂—CF₂—CF₃, —CH(CF₃)₂, —CH₂—CH₂—CF₃, and —CH₂—CH₂—CF₂—CF₂—CF₂—CF₃.

The weight average molecular weight (Mw) (polystyrene equivalent value determined by gel permeation chromatography) of the fluorine additive (F) is preferably 1000 or more and 50000 or less, more preferably 5000 or more and 40000 or less, and further preferably 10000 or more and 30000 or less.

The dispersity (Mw/Mn) of the fluorine additive (F) is preferably 1.0 or more and 5.0 or less, more preferably 1.0 or more and 3.0 or less, and further preferably 1.0 or more and 2.5 or less.

One kind of the fluorine additive (F) may be used alone, or two or more kinds thereof may be used in combination.

When the photosensitive composition contains the fluorine additive component (F), the content of the fluorine additive (F) is generally 0.5 parts by mass or more and 10 parts by mass or less with respect to 100 parts by mass of the silicon-containing polymer (A).

### <Organic Solvent(S)>

The photosensitive composition may include an organic solvent(S). The photosensitive composition preferably includes an organic solvent(S) for the purpose of adjusting coating properties.

The organic solvent(S) may be organic solvent capable of dissolving the respective components used to give a uniform solution, and one or more kinds of any organic solvent can be appropriately selected from those which have been conventionally known as solvents for chemically amplified photosensitive composition.

Examples of the organic solvent(S) include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether, for example, monomethylether, monoethylether, monopropylether or monobutylether, or monophenylether of any of these polyhydric alcohols or the compounds having an ester bond [among these, propylene glycol monomethyl ether acetate (PGMEA) and propylene glycol monomethyl ether (PGME) are preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene; dimethylsulfoxide (DMSO), and the like.

One type of the organic solvent(S) may be used alone, or two or more types thereof may be used as a mixed solvent. Among the above organic solvent(S), PGMEA, PGME, γ-butyrolactone, EL, and cyclohexanone are preferable.

As the organic solvent(S), a mixed solvent obtained by mixing PGMEA and a polar solvent is also preferable. The blending ratio (mass ratio) may be appropriately determined in consideration of the compatibility of PGMEA with the polar solvent, and the like, but is preferably within the range of 1:9 to 9:1, more preferably within the range of 2:8 to 8:2.

More specifically, when EL or cyclohexanone is blended as the polar solvent, the mass ratio of PGMEA to EL or cyclohexanone is preferably 1:9 to 9:1, and more preferably 2:8 to 8:2. Furthermore, when PGME is added as the polar solvent, the mass ratio of PGMEA:PGME is preferably 1:9 to 9:1, more preferably 2:8 to 8:2.

In addition, a mixed solvent of PGMEA, PGME, and cyclohexanone is preferable. Furthermore, as the organic solvent(S), a mixed solvent of at least one kind selected from PGMEA and EL and γ-butyrolactone is also preferable. In this case, in the mixing proportion, the mass ratio of the former to the latter is preferably 70:30 to 95:5.

The amount of the organic solvent(S) to be used is not particularly limited, and is appropriately set in accordance with the thickness of the coating film within a range in which the solid concentration of the photosensitive composition can be applied to the substrate or the like.

The solid content concentration of the photosensitive composition is preferably in the range of 0.1% by mass or more and 10% by mass or less, and more preferably 0.2% by mass or more and 5% by mass or less.

### <Other Components>

In addition to the components described above, the photosensitive composition may appropriately contain other components such as an additional resin, a dissolution inhibitor, a plasticizer, a stabilizer, a colorant, a halation inhibitor, a dye, and the like.

For example, in the photosensitive composition, in addition to the above silicon-containing polymer (A), a silicon-free resin such as a hydroxystyrene resin or a novolak resin may be used as an additional resin.

### <<Method for Producing Patterned Cured Film>>

A method for producing a patterned cured film includes forming a coating film made of a photosensitive composition on a support (hereinafter, also referred to as a “coating film formation step”), exposing the coating film in a position-selective manner (hereinafter, also referred to as an “exposure step”), and developing the exposed coating film to form a patterned cured film (hereinafter, also referred to as a “development step”).

### <Coating Film Formation Step>

First, a photosensitive composition described above is applied to a support using a spinner or the like to form a coating film.

The support is not particularly limited, and a conventionally known support can be used, and examples of the support include a substrate for an electronic component and a support on which a predetermined wiring pattern is formed. More specific examples of the support include a silicon wafer, a substrate made of metal such as copper, chromium, iron, and aluminum, a glass substrate, and the like. For a material of the wiring pattern, for example, metal such as copper, aluminum, nickel, and gold may be used.

The support may be a support in which an inorganic and/or organic film is provided on the above-described substrate. Examples of the inorganic film include an inorganic anti-reflective film (inorganic BARC). Examples of the organic film include organic films such as an organic anti-reflective film (organic BARC) and a lower organic film in a multilayer resist method.

After the photosensitive composition is applied, a film made of photosensitive composition is subjected to a bake (post apply bake (PAB)) treatment. Conditions of the bake treatment is not particularly limited as long as patterned cured film with a desired shape and properties can be formed. Preferable bake conditions include, for example, under a temperature condition of 80° C. or higher and 150° C. or lower for 40 seconds or longer and 120 seconds or shorter, and preferably 60 seconds or longer and 90 seconds or shorter.

### <Exposure Step>

Next, using an exposure apparatus such as an electron beam drawing apparatus or an EUV (extreme ultraviolet) exposure apparatus, the coating film is subjected to position-selective exposure through a mask on which a predetermined pattern is formed (mask pattern) or through drawing by direct irradiation with an electron beam without using a mask pattern.

The wavelength to be used for exposure is not particularly limited. The exposure can be carried out using a radiation such as a ArF excimer laser, a KrF excimer laser, a F₂ excimer laser, EUV (extreme ultraviolet), VUV (vacuum ultraviolet), an EB (electron beam), an X-ray, and a soft X-ray.

Among the above methods for producing a patterned cured film, the method of exposing the above coating film with EUV (extreme ultraviolet) or EB (electron beam) is particularly useful.

Also, in the methods using EUV, it is still preferable to use radiation of so-called BEUV having a wavelength of 13.5 nm or less, for example, within a range of 3 to 11 nm, 5 to 11 nm, 5 to 8 nm, or 6.5 to 6.8 nm, particularly a wavelength of 6.7 nm. This is because the shorter wavelength can provide good resolution (features less than 13.5 nm nodes), deep depth of focus (DOF), and high throughput compared with 13.5 nm radiation, which is common in EUV lithography. When the photosensitive resin composition of the present invention is exposed to BEUV radiation, the photosensitive resin composition preferably uses a compound including at least one element among Ta, W, Re, Os, Ir, Ni, Cu, Sn, S, Ga, Ge, Gd, Hf, Tm, Zn, Nd, Pm, Sm, Eu, Tb, Dy, Ho, Er, Yb, Lu, Pt or Au.

The exposure method of the coating film may be a general exposure (dry exposure) carried out in air or an inert gas such as nitrogen, or may be liquid immersion lithography.

After the above exposure, if necessary, exposed coating film is subjected to a bake (post exposure bake (PEB)) treatment. Preferable bake condition is, for example, heating under a temperature condition of 80° C. or higher and 150° C. or lower for 40 seconds or longer and 120 seconds or shorter, and preferably 60 seconds or longer and 90 seconds or shorter.

### <Development Step>

Next, the coating film is developed after the position-selective exposure. With development, a patterned hard film is obtained. Development is typically carried out by an alkaline developing process or a solvent development process.

When developing is carried out by an alkaline developing process, an alkaline developing solution is used. Examples of the alkaline developing solution include a tetramethylammonium hydroxide (TMAH) aqueous solution having a concentration of 0.1% by mass or more and 10% by mass or less.

When developing is carried out by a solvent development process, a developing solution containing an organic solvent (an organic developing solution) is used.

The organic solvent contained in the organic developing solution used for the developing treatment in the solvent development process can be appropriately selected from known organic solvents as long as it is an organic solvent capable of dissolving the component (A) (the component (A) prior to exposure). Specific examples thereof include polar solvents such as a ketone-based solvent, an ester-based solvent, an alcohol-based solvent, a nitrile-based solvent, an amide-based solvent, and an ether-based solvent, and a hydrocarbon-based solvent, and halogenated hydrocarbon-based solvent, and the like.

The ketone-based solvent is an organic solvent including C—C(═O)—C in the structure thereof. The ester-based solvent is an organic solvent including C—C(═O)—O—C in the structure thereof. The alcohol-based solvent is an organic solvent including an alcoholic hydroxy group in the structure thereof.

The term “alcoholic hydroxy group” refers to a hydroxy group bonded to a carbon atom in an aliphatic hydrocarbon group. The nitrile-based solvent is an organic solvent including a nitrile group in the structure thereof. The amide-based solvent is an organic solvent including a carboxylic acid amide group in the structure thereof. The ether-based solvent is an organic solvent including C—O—C in the structure thereof.

The organic solvent includes also an organic solvent including a plurality of kinds of functional groups characterizing each of the above solvents in the structure thereof, and in that case, the organic solvent falls under the category of any type of solvent including the functional group contained in the organic solvent. For example, diethylene glycol monomethyl ether falls under the category of both an alcohol-based solvent and an ether-based solvent in the above classification.

The hydrocarbon-based solvent is a solvent including hydrocarbon. The halogenated hydrocarbon-based solvent is a solvent including only a halogen atom as a substituent. The halogen atom is preferably a fluorine atom.

The organic solvent contained in the organic developing solution is preferably a polar solvent, and preferably a ketone-based solvent, an ester-based solvent, an alcohol-based solvent, and the like.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, methyl amyl ketone (2-heptanone), and the like. Among these, methyl amyl ketone (2-heptanone) is preferable.

Examples of the ester-based solvent include methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, propyl-3-methoxypropionate, γ-butyrolactone, and the like. Among them, butyl acetate is preferable as the ester-based solvent.

Examples of the alcohol-based solvent include methanol, ethanol, propanol, butanol, pentanol, hexanol, heptanol, octanol, nonanol, decanol, 4-methyl-2-pentanol, ethylene glycol, ethylene glycol monomethyl ether, ethylene glycol monoethyl ether, ethylene glycol monopropyl ether, propylene glycol, propylene glycol monomethyl ether, propylene glycol monoethyl ether, diethylene glycol, diethylene glycol monomethyl ether, and the like.

A known additive can be blended in the organic developing solution as necessary. Examples of the additive include a surfactant. The surfactant is not particularly limited, and, for example, an ionic or nonionic fluorine-based and/or silicon-based surfactant and the like can be used.

The development can be carried out by a known developing method. Suitable examples of the developing method include a method of immersing a support in a developing solution for a certain period of time (dip method), a method of casting up a developing solution on a surface of a support by surface tension and standing still for a certain period of time (puddle method), a method of spraying a developing solution on a surface of a support (spray method), a method of continuously applying a developing solution onto a support rotating at a constant speed while scanning a developing solution application nozzle at a constant speed (dynamic dispense method), and the like.

After development, the patterned cured film is preferably subjected to rinse treatment. In the case of the alkaline development process, rinsing with pure water is preferable. In the case of a solvent development process, rinsing with rinse solution containing an organic solvent is preferable.

The rinse treatment can be carried out by a known rinse method. Examples of the rinsing method include a method of continuously applying a rinse solution to a support while rotating the support at a constant rate (rotational coating method), a method of immersing a support in a rinse solution for a certain period of time (dip method), a method of spraying a rinse solution onto a surface of a support (spray method), and the like.

In the case of a solvent development process, after the development or after the development and rinse treatment, the developing solution or the rinse solution attached to the patterned cured film may be removed by treatment using a supercritical fluid.

In general, after the development or the rinse treatment, a patterned cured film is dried. The patterned cured film may be subjected to bake treatment (post bake) after the above development if necessary.

As mentioned above, the present inventors provide the following (1) to (11).

(1) A photosensitive composition including a silicon-containing polymer (A) containing a phenolic hydroxy group, and an alkali-soluble group protected by an acid-dissociable group, and a photoacid generating agent (B), the photoacid generating agent (B) including a photoacid generating agent (B1) including a sulfonium cation including an iodine atom.
(2) The photosensitive composition described in (1), wherein the sulfonium cation is a sulfonium cation represented by the following formula (b1-1).

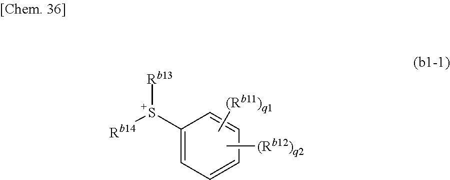

(In the formula (b1-1), R^{b11} represents an iodine atom, or —R^{b111}—X^{b1}, R^{b111} represents a divalent linking group not including an aromatic group, X^{b1} represents an aromatic group substituted with an iodine atom, R^{b12} represents a fluorine atom, a hydroxy group, a hydrocarbon group which may have a substituent, or an alkoxy group which may have a substituent, R^{b13}, and R^{b14} each independently represent a hydrocarbon group which may have a substituent, R^{b13}, and R^{b14} optionally being bonded to each other to form a ring, q1 represents an integer of 1 or more and 4 or less, q2 represents an integer of 0 or more and 3 or less, and 1≤q1+q2≤4 is satisfied.)
(3) The photosensitive composition described in (2), wherein a divalent linking group not including an aromatic group for the R^{b111} represents a divalent aliphatic hydrocarbon group or a group represented by the following formula (b1-1a):

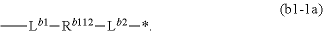

(In the formula (b1-1a), L^{b1} represents an ester bond, an amide bond, or an ether bond; L^{b2} represents a single bond, an ester bond, an amide bond, or an ether bond, R^{b112} represents a single bond or an alkylene group, and * represents a bonding bonded to X^{b1}.)
(4) The photosensitive composition described in any one of (1) to (3), wherein the silicon-containing polymer (A) includes a constituent unit represented by the following formula (a1), and a constituent unit represented by the following formula (a2).

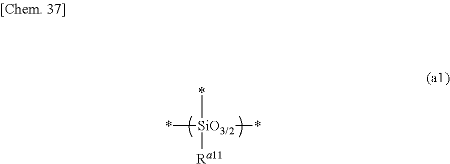

(In the formula (a1), R^{a11} represents an organic group having a phenolic hydroxy group, and * represents a bonding.)

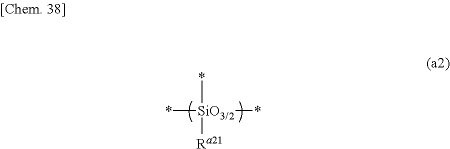

(in the formula (a2), R^{a21} represents an organic group having an alkali-soluble group protected by an acid-dissociable group, and * represents a bonding.)
(5) The photosensitive composition described in (4), wherein the R^{a21} represents a group represented by the following formula (a2-1), or a group represented by the following formula (a2-2).

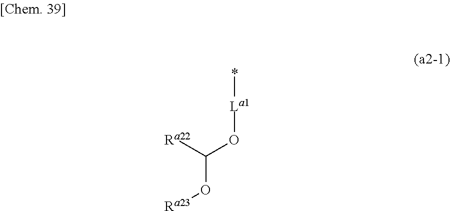

(In the formula (a2-1), L^{a1} represents a single bond, or a divalent organic group, R^{a22} represents a hydrogen atom, or a hydrocarbon group which may have a substituent, R^{a23} represents a hydrogen atom, or a hydrocarbon group which may have a substituent, R^{a22} and R^{a23} are optionally bonded to each other to form a ring, and * represents a bonding.)

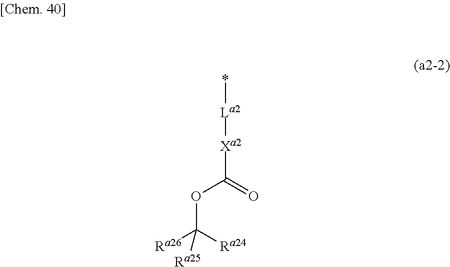

(In the formula (a2-2), L^{a2} represents a single bond or a divalent organic group, X^{a2} represents a single bond or O, R^{a24}, R^{a25}, and R^{a26} each independently represent a hydrocarbon group, two or more of R^{a24}, R^{a25}, and R^{a26} which may be bonded to each other to form a ring, and * represents a bonding.)
(6) The photosensitive composition described in any one of (1) to (5), further containing a base component (D) for controlling diffusion of an acid generated upon exposure.
(7) The photosensitive composition according to any one of (1) to (6), wherein a proportion of a mass of the silicon-containing polymer (A) to a mass of a solid content of the photosensitive composition is 10% by mass or more.
(8) The photosensitive composition described in any one of (1) to (7), further containing a crosslinking agent (C).
(9) The photosensitive composition described in any one of (1) to (8), wherein the photosensitive resin composition is a positive type.
(10) A method for producing a patterned cured film, the method including:
forming a coating film made of the photosensitive composition described in any one of (1) to (9) on a support;
exposing the coating film in a position-selective manner; and
developing the exposed coating film to form a patterned cured film.
   (11) The method for producing a patterned cured film described in (10), wherein the coating film is exposed to EUV (extreme ultraviolet).

### EXAMPLES

The present invention will be described in more detail based on Examples, but the present invention is not limited to these Examples.

### <<Preparation of Photosensitive Composition>>

The components shown in Table 1 were mixed and dissolved to prepare a photosensitive composition in each example.

TABLE 1

| | | Component | Component | Component | Component | Component | Component |
|---|---|---|---|---|---|---|---|
| | | (A) | (B) | (C) | (D) | (E) | (S) |
| Example | 1 | (A)-1 [100] | (B)-1 [30] | — | (D)-1 [32] | (E)-1 | (S)-1 |
| | 2 | (A)-2 [100] | (B)-1 [30] | — | (D)-1 [32] | [3] | [12000] |
| | 3 | (A)-3 [100] | (B)-1 [30] | — | (D)-1 [32] | | (S)-2 |
| | 4 | (A)-4 [100] | (B)-1 [30] | — | (D)-1 [32] | | [3000] |
| | 5 | (A)-1 [100] | (B)-2 [33] | — | (D)-1 [32] | | (S)-3 |
| | 6 | (A)-1 [100] | (B)-3 [41] | — | (D)-1 [32] | | [5000] |
| | 7 | (A)-1 [100] | (B)-4 [44] | — | (D)-1 [32] | | |
| | 8 | (A)-1 [100] | (B)-1 [30] | — | (D)-2 [44] | | |
| | 9 | (A)-1 [100] | (B)-2 [33] | — | (D)-2 [49] | | |
| | 10 | (A)-1 [100] | (B)-1 [19] | — | (D)-1 [24] | | |
| | 11 | (A)-2 [100] | (B)-2 [33] | — | (D)-2 [49] | | |
| | 12 | (A)-5[100] | (B)-1[30] | — | (D)-1[32] | | |
| | 13 | (A)-4[100] | (B)-1[30] | — | (D)-1[32] | | |
| | 14 | (A)-4[100] | (B)-1[30] | (C)-1[15] | (D)-1[32] | | |
| | 15 | (A)-4[100] | (B)-1[30] | (C)-2[17] | (D)-1[32] | | |
| Comparative | 1 | (A)-1 [100] | (B)-5 [32] | — | (D)-1 [36] | | |
| Example | 2 | (A)-6 [100] | (B)-1 [30] | — | (D)-1 [32] | | |
| | 3 | (A)-6 [100] | (B)-1 [30] | — | (D)-2 [48] | | |

In Table 1, each abbreviation has the following meaning. The numerical value in [ ] is a blending amount (part(s) by mass).

(A)-1: a polymer represented by the following formula (weight average molecular weight (Mw) in terms of polystyrene equivalent value measured by GPC: 3,900, molecular weight dispersity (Mw/Mn): 1.3, silicon atom content rate: 20.0% by mass)

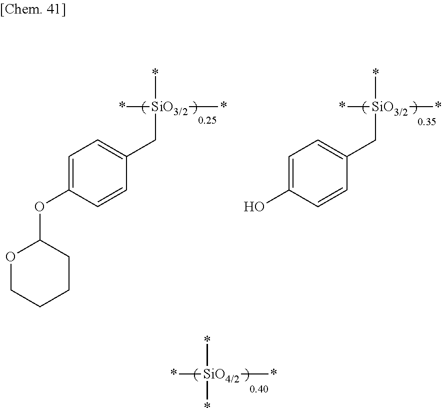

(A)-2: a polymer represented by the following formula (weight average molecular weight (Mw) in terms of polystyrene equivalent value measured by GPC: 2,500, molecular weight dispersity (Mw/Mn): 1.3, silicon atom content rate: 14.9% by mass)

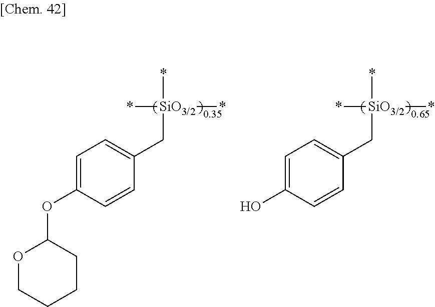

(A)-3: a polymer represented by the following formula (weight average molecular weight (Mw) in terms of polystyrene equivalent value measured by GPC: 4,800, molecular weight dispersity (Mw/Mn): 1.4, silicon atom content rate: 19.4% by mass)

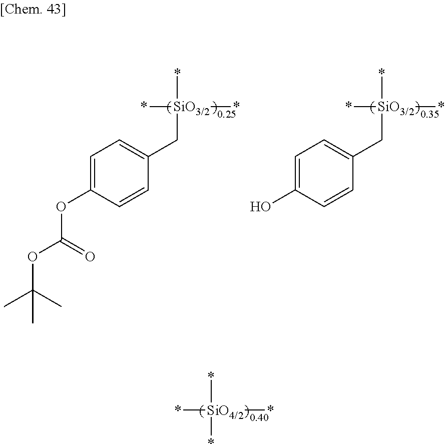

(A)-4: a polymer represented by the following formula (weight average molecular weight (Mw) in terms of polystyrene equivalent value measured by GPC: 4,000, molecular weight dispersity (Mw/Mn): 1.3, silicon atom content rate: 20.5% by mass)

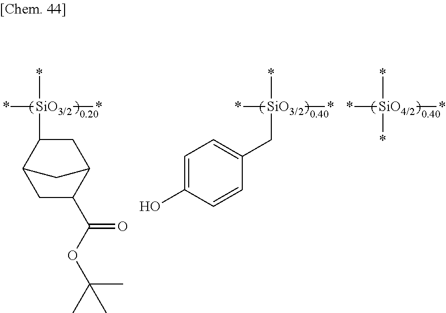

(A)-5: a polymer represented by the following formula (weight average molecular weight (Mw) in terms of polystyrene equivalent value measured by GPC: 2300, molecular weight dispersity (Mw/Mn): 1.1, silicon atom content rate: 13% by mass)

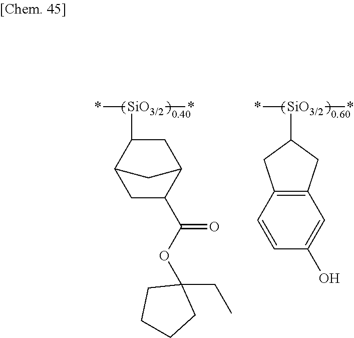

(A)-6: a polymer represented by the following formula (weight average molecular weight (Mw) in terms of polystyrene equivalent value measured by GPC: 4,100, molecular weight dispersity (Mw/Mn): 1.4, silicon atom content rate: 0% by mass)

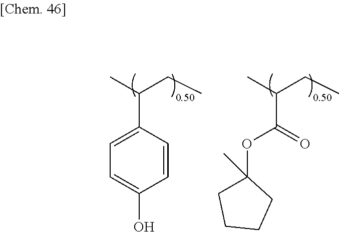

(B)-1: a compound represented by the following formula.

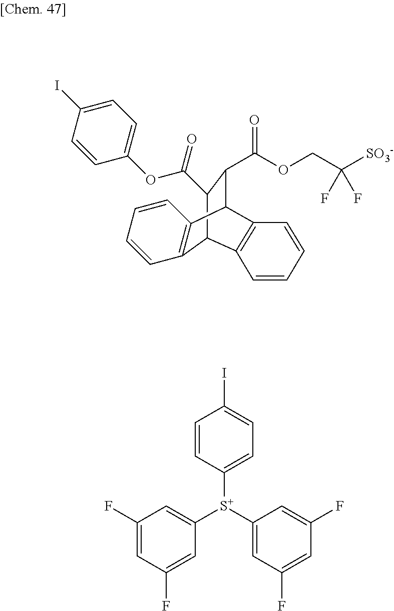

(B)-2: a compound represented by the following formula.

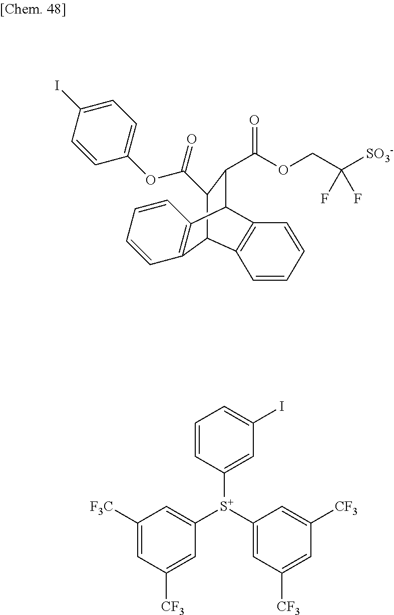

(B)-3: a compound represented by the following formula.

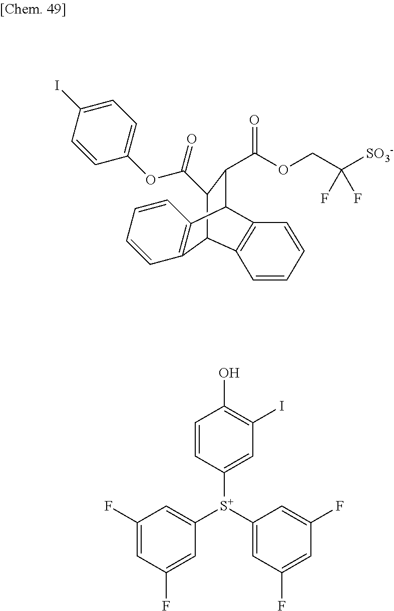

(B)-4: a compound represented by the following formula.

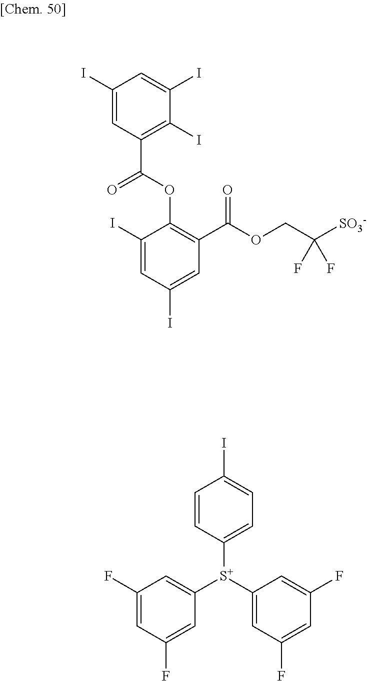

(B)-5: a compound represented by the following formula.

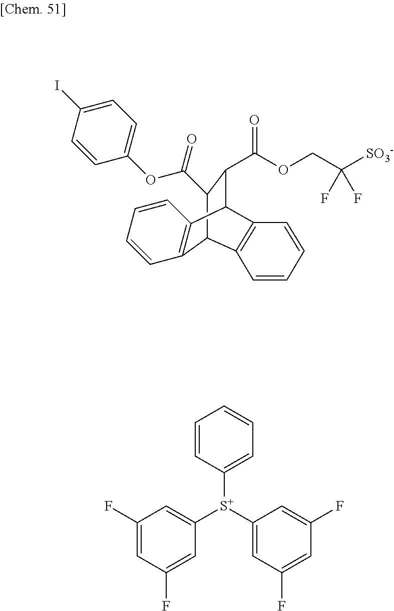

(C)-1: a compound represented by the following formula.

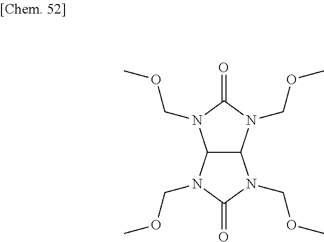

(C)-2: a compound represented by the following formula.

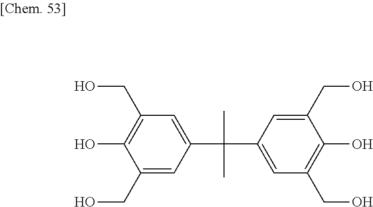 [SMILES: CC(C)(c1cc(CO)c(O)c(CO)c1)c1cc(CO)c(O)c(CO)c1]

(D)-1: a compound represented by the following formula.

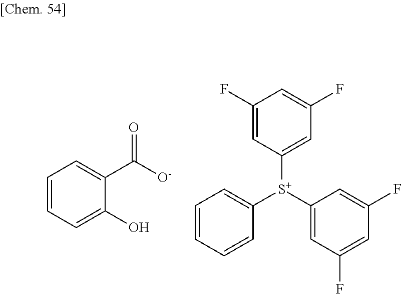 [SMILES: O=C([O-])c1ccccc1O ; Fc1cc(F)cc([S+](c2ccccc2)c2cc(F)cc(F)c2)c1]

(D)-2: a compound represented by the following formula.

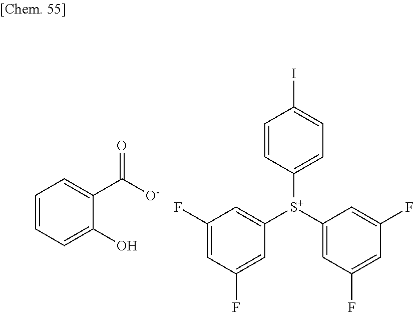 [SMILES: O=C([O-])c1ccccc1O ; Fc1cc(F)cc([S+](c2ccc(I)cc2)c2cc(F)cc(F)c2)c1]

(E)-1: a compound represented by the following formula.

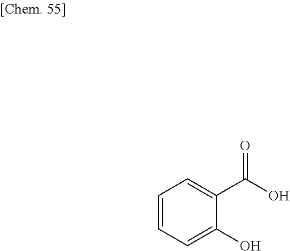

(S)-1: propylene glycol monomethyl ether
(S)-2: propylene glycol monomethyl ether acetate(S)
(S)-3: cyclohexanone

### <Synthesis of Compound (B)-1 to Compound (B)-4, and Compound (D)-2>

### (Synthesis of Sulfonium Salt (Y-1))

A mixture solution was obtained by mixing 70.2 g of sulfonium salt (X-1) (CAS. 3028611-48-2), 53.7 g of benzyldimethylstearylammonium chloride, 351 g of 4-methyltetrahydropyran, and 842 g of pure water, and the mixture solution was stirred at room temperature for 30 minutes, and then an aqueous layer was collected using a separatory funnel. Thereafter, a step of collecting the aqueous layer using a separatory funnel after adding 351 g of pure water to the remaining organic layer, and stirring the mixtures for 30 minutes was repeated three times. All the collected aqueous layer was mixed. A step of collecting the aqueous layer using a separatory funnel after adding 632 g of 4-methyltetrahydropyran to the aqueous layer and stirring for 30 minutes was repeated four times to obtain a 2.8% aqueous solution of sulfonium salt (Y-1).

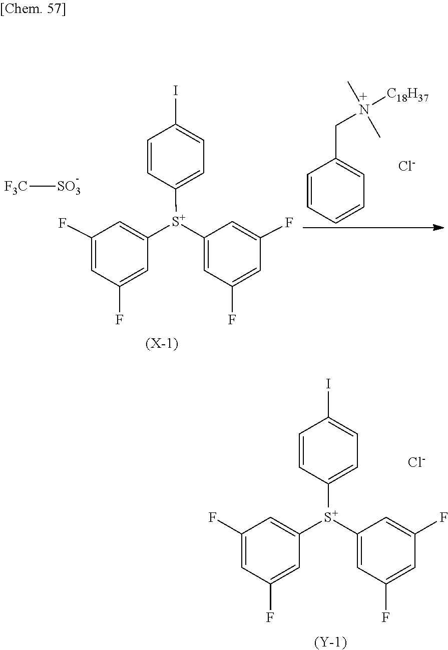

### (Synthesis of Sulfonium Salt (Y-2))

A mixture solution was obtained by mixing 93.2 g of (X-2) (CAS. 3028611-54-0), 53.7 g of benzyldimethylstearylammonium chloride, 351 g of 4-methyltetrahydropyran, and 842 g of pure water, and the mixture solution was stirred at room temperature for 30 minutes, and then an aqueous layer was collected using a separatory funnel. Thereafter, a step of collecting the aqueous layer using a separatory funnel after adding 351 g of pure water to the remaining organic layer and stirring for 30 minutes was repeated three times. All collected aqueous layers were mixed. A step of collecting the aqueous layer using a separatory funnel after adding 632 g of 4-methyltetrahydropyran to the aqueous layers and stirring for 30 minutes was repeated four times to obtain a 3.0% aqueous solution of sulfonium salt (Y-2).

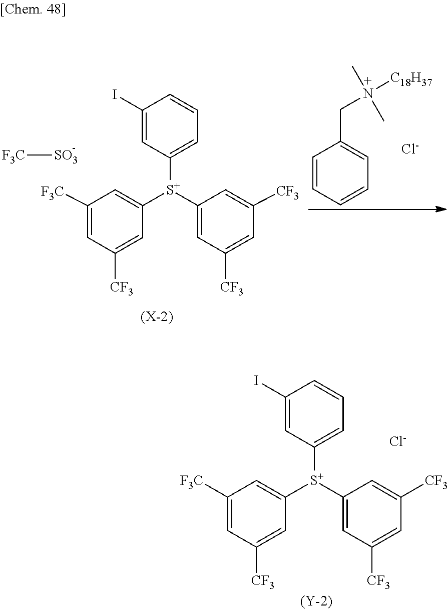

### (Synthesis of Sulfonium Salt (Y-3))

A mixture solution was obtained by mixing 72.0 g of (X-3) (CAS. 3028611-58-4), 53.7 g of benzyldimethylstearylammonium chloride, 351 g of 4-methyltetrahydropyran, and 842 g of pure water, and the mixture solution was stirred at room temperature for 30 minutes, and then an aqueous layer was collected using a separatory funnel. Thereafter, a step of collecting the aqueous layer using a separatory funnel after adding 351 g of pure water to the remaining organic layer and stirring for 30 minutes was repeated three times. All collected aqueous layer was mixed. A step of collecting the aqueous layer using a separatory funnel after adding 632 g of 4-methyltetrahydropyran to the aqueous layer and stirring for 30 minutes was repeated four times to obtain a 2.9% aqueous solution of sulfonium salt (Y-3).

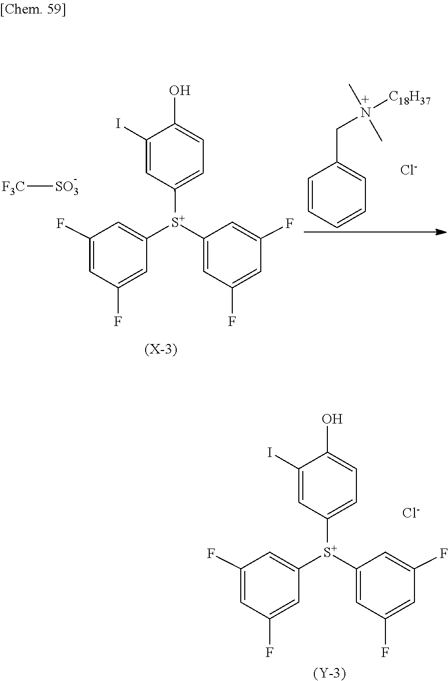

### (Synthesis of Compound (B)-1)

A mixture solution was obtained by mixing 195 g of a 2.8% aqueous solution of sulfonium salt (Y-1), 7.9 g of benzyltrimethylammonium salt (Z-1) (CAS. 2920109-86-8), and 195 g of dichloromethane, and the mixture solution was stirred at room temperature for 30 minutes, and then the organic layer was collected using a separatory funnel. Next, a step of collecting the organic layer by using a separatory funnel after adding 195 g of a 0.3% aqueous solution of a sulfonium salt (Y-1) to the organic layer and stirring at room temperature for 30 minutes was repeated three times. Furthermore, a step of collecting the organic layer using a separatory funnel after adding 195 g of pure water to the organic layer and stirring for 30 minutes was repeated three times to remove impurities. Thereafter, the solvent was evaporated by using a rotary evaporator, and further dried in vacuum by an oil pressure vacuum pump for 20 hours to obtain 9.9 g of the compound (B)-1.

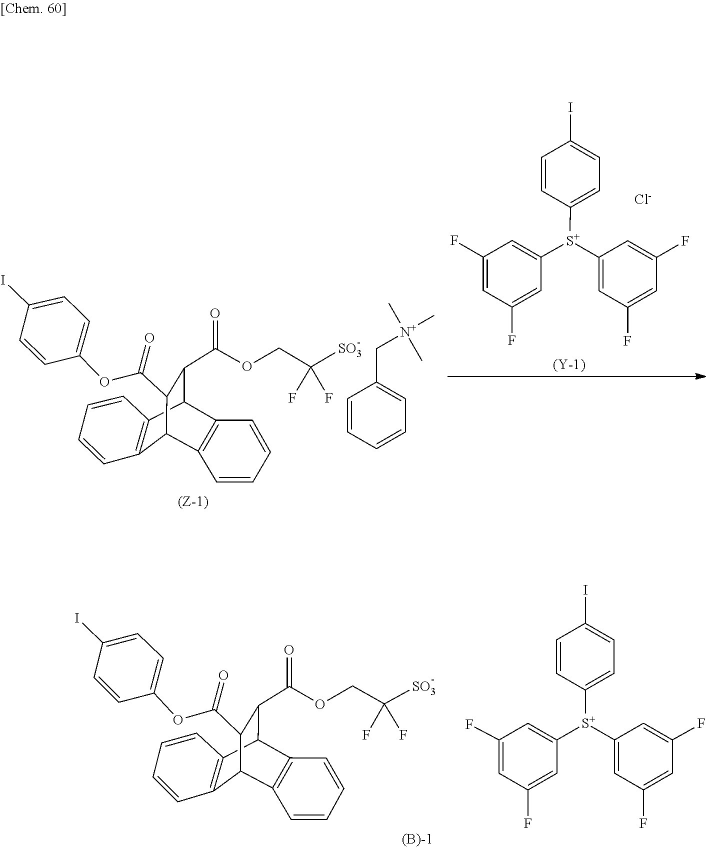

The structure of the compound (B)-1 was verified from ¹³C-NMR and: ¹⁹F-NMR.

[¹³C-NMR (150 MHz, acetone-d₆)]
a: 1C, 90 ppm
b, c: 2C, 162 ppm
d: 1C, 63 ppm
e: 1C, 118 to 122 ppm
f: 1C, 105 ppm
   [¹⁹F-NMR (150 MHz, DMSO-d₆)]
h: 2F, −113 ppm
i: 4F, −104 ppm

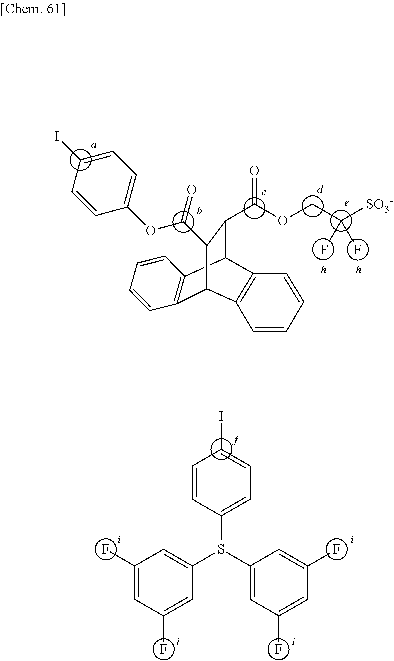

### (Synthesis of Compound (B)-2)

A mixture solution was obtained by mixing 255 g of a 3.0% aqueous solution of sulfonium salt (Y-2), 7.9 g of benzyltrimethylammonium salt (Z-1) (CAS. 2920109-86-8), and 255 g of dichloromethane, and the mixture solution was stirred at room temperature for 30 minutes, and then the organic layer was collected using a separatory funnel. Next, a step of collecting the organic layer by using a separatory funnel after adding 255 g of a 0.3% aqueous solution of a sulfonium salt (Y-2) to the organic layer and stirring at room temperature for 30 minutes was repeated three times. Furthermore, a step of collecting the organic layer using a separatory funnel after adding 255 g of pure water to the organic layer and stirring for 30 minutes was repeated three times to remove impurities. Thereafter, the solvent was evaporated by using a rotary evaporator, and further dried in vacuum by an oil pressure vacuum pump for 20 hours to obtain 10.9 g of the compound (B)-2.

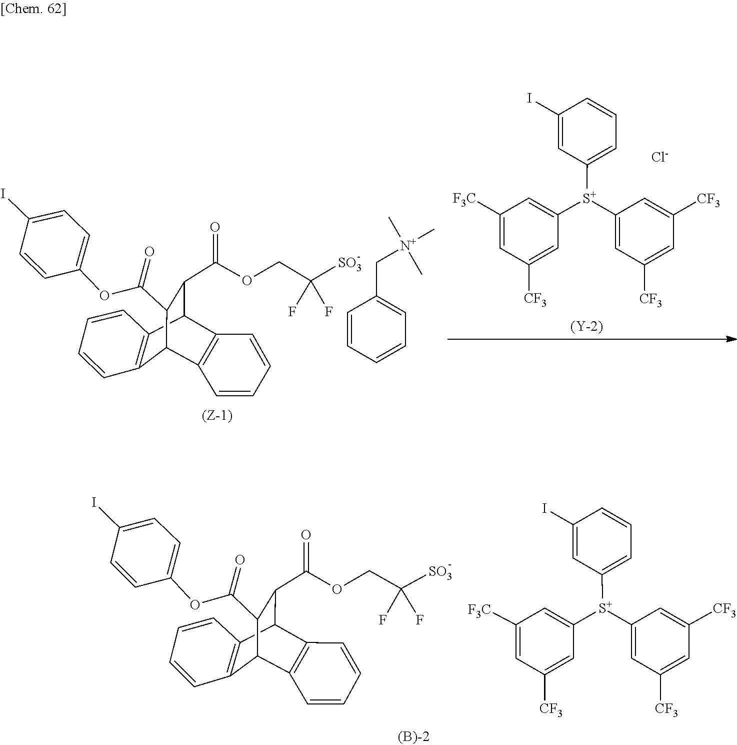

The structure of the compound (B)-2 was verified from ¹³C-NMR and: ¹⁹F-NMR.

[¹³C-NMR (150 MHz, acetone-d₆)]
a: 1C, 90 ppm
b, c: 2C, 162 ppm
d: 1C, 63 ppm
e: 1C, 118 to 122 ppm
f: 1C, 112 ppm
   [¹⁹F-NMR (150 MHz, DMSO-d₆)]
g: 2F, −113 ppm
h: 12F, −57 ppm

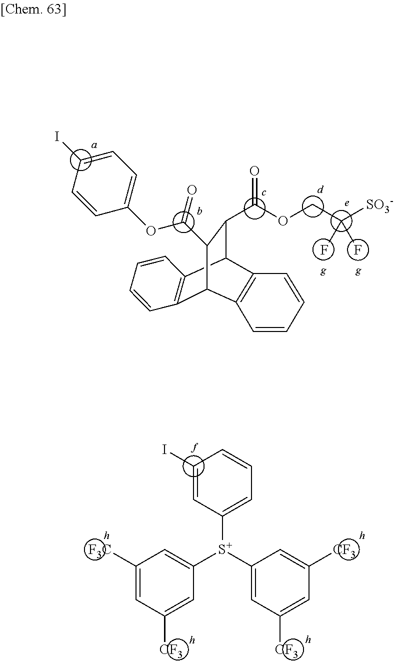

### (Synthesis of Compound (B)-3)

A mixture solution was obtained by mixing 294 g of a 2.9% aqueous solution of sulfonium salt (Y-3), 7.9 g of benzyltrimethylammonium salt (Z-1) (CAS. 2920109-86-8), and 194 g of dichloromethane, and the mixture solution was stirred at room temperature for 30 minutes, and then the organic layer was collected using a separatory funnel. Next, a step of collecting the organic layer by using a separatory funnel after adding 194 g of a 0.3% aqueous solution of a sulfonium salt (Y-3) to the organic layer and stirring at room temperature for 30 minutes was repeated three times. Furthermore, a step of collecting the organic layer using a separatory funnel after adding 194 g of pure water to the organic layer and stirring for 30 minutes, was repeated three times to remove impurities. Thereafter, the solvent was evaporated by using a rotary evaporator, and further dried in vacuum by an oil pressure vacuum pump for 20 hours to obtain 9.7 g of the compound (B)-3.

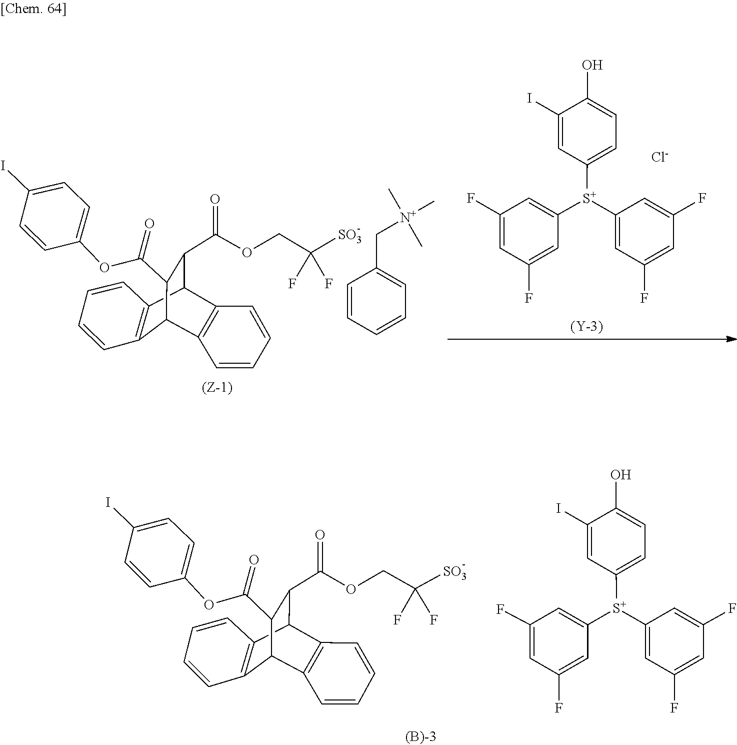

The structure of the compound (B)-3 was verified from: ¹³C-NMR, and ¹⁹F-NMR.

[¹³C-NMR (150 MHz, acetone-d₆)]
a: 1C, 90 ppm
b, c: 2C, 162 ppm
d: 1C, 63 ppm
e: 1C, 118 to 122 ppm
f: 1C, 106 ppm
g: 1C, 168 ppm
   [¹⁹F-NMR (150 MHZ, DMSO-d₆)]
h: 2F, −113 ppm
i: 4F, −104 ppm

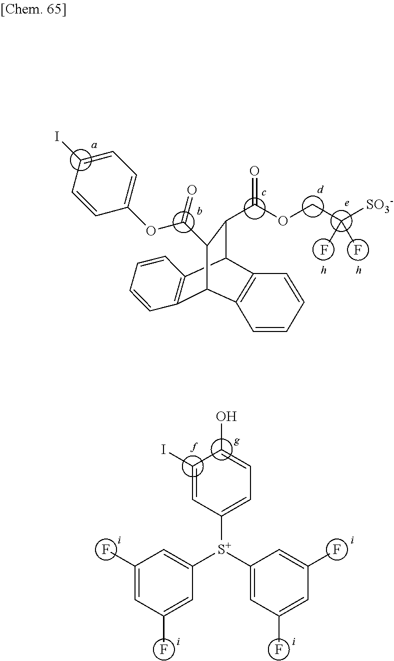

### (Synthesis of Compound (B)-4)

A mixture solution was obtained by mixing 195 g of a 2.8% aqueous solution of sulfonium salt (Y-1), 11.2 g of benzyltrimethylammonium salt (Z-2) obtained by the method described in Japanese Unexamined Patent Application, Publication No. 2023-123183, and 194 g of dichloromethane, and the mixture solution was stirred at room temperature for 30 minutes, and then the organic layer was collected using a separatory funnel. Next, a step of collecting the organic layer by using a separatory funnel after adding 194 g of a 0.3% aqueous solution of a sulfonium salt (Y-1) to the organic layer and stirring at room temperature for 30 minutes was repeated three times. Furthermore, a step of collecting the organic layer using a separatory funnel after adding 194 g of pure water to the organic layer and stirring for 30 minutes was repeated three times to remove impurities. Thereafter, the solvent was evaporated by using a rotary evaporator, and further dried in vacuum by an oil pressure vacuum pump for 20 hours to obtain 13.2 g of the compound (B)-4.

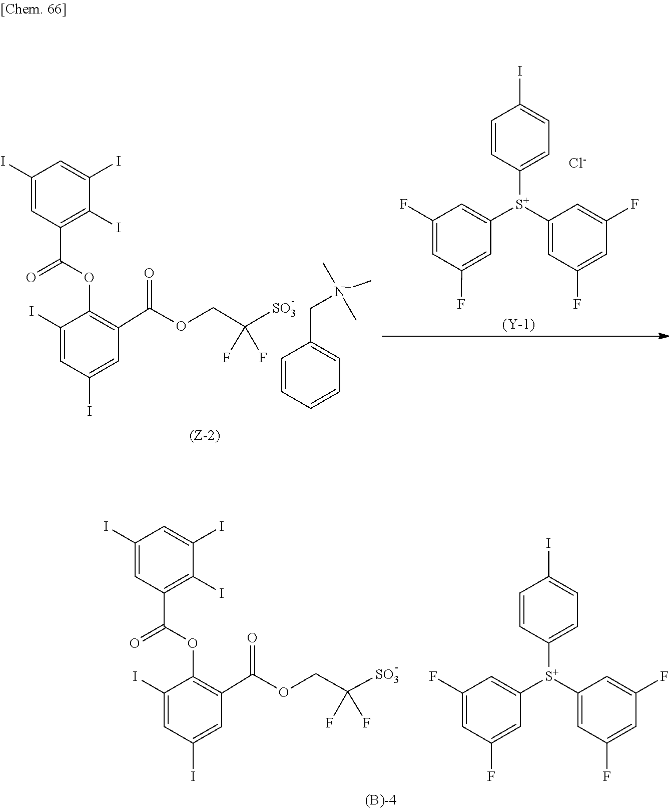

The structure of the compound (B)-4 was verified from ¹³C-NMR and ¹⁹F-NMR.

[¹³C-NMR (150 MHZ, acetone-d₆)]
a: 1C, 90 ppm
b, c: 2C, 162 ppm
d: 1C, 63 ppm
e: 1C, 118 to 122 ppm
f: 1C, 105 ppm
   [¹⁹F-NMR (150 MHZ, DMSO-d₆)]
h: 2F, −113 ppm
i: 4F, −104 ppm

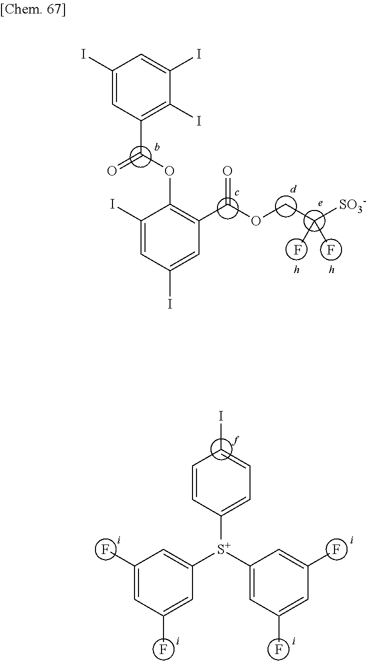

### (Synthesis of Compound (D)-2)

A mixture solution was obtained by mixing 195 g of a 2.8% aqueous solution of sulfonium salt (Y-1), 2.1 g of tetramethylammonium salicylate (CAS. 68494-18-8), and 194 g of dichloromethane were mixed, and the mixed solution was stirred at room temperature for 30 minutes, and then the organic layer was collected using a separatory funnel. Furthermore, a step of collecting the organic layer using a separatory funnel after adding 194 g of pure water to the organic layer and stirring for 30 minutes was repeated five times to remove impurities. Thereafter, the solvent was evaporated by using a rotary evaporator, and further dried in vacuum by an oil pressure vacuum pump for 20 hours to obtain 3.9 g of the compound (D)-2.

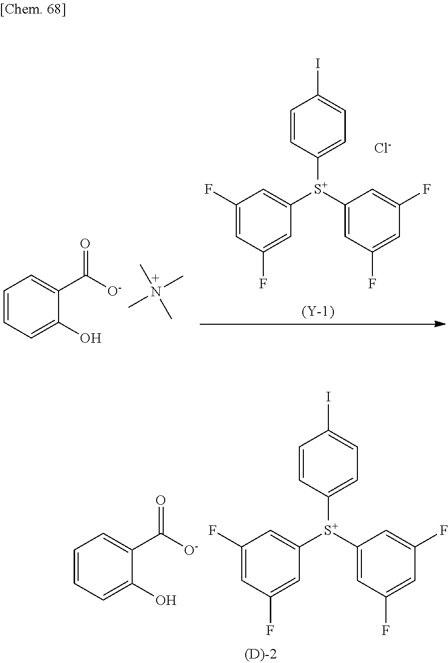

The structure of the compound (D)-2 was verified from ¹³C-NMR and ¹⁹F-NMR.

[¹³C-NMR (150 MHz, acetone-d₆)]
a: 1C, 172 ppm
b: 1C, 164 ppm
f: 1C, 105 ppm
   [¹⁹F-NMR (150 MHz, DMSO-d₆)]
h: 2F, −113 ppm
i: 4F, −104 ppm

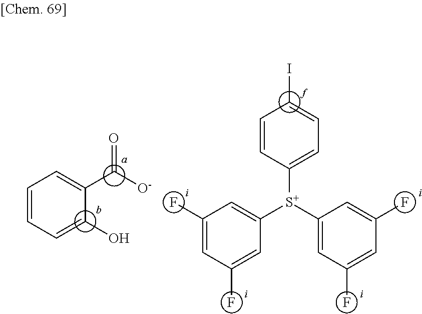

### <Content Rate of Silicon Atoms in Solid Content of Photosensitive Composition>

The content rate of silicon atoms in the solid content of the photosensitive composition was calculated as follows. In the case of photosensitive composition of Example 1, the content rate of the silicon atoms in the compound (A)-1 to be blended is 20.0% by mass. The content rate of the compound (A)-1 in the solid content of the photosensitive composition is (100/(100+30+32+3))×100≈60.6 (% by mass). Therefore, the content rate of the silicon atom in the solid content of the photosensitive composition is calculated as 20.0×(60.6/100)≈12 (% by mass).

### <<Formation of Patterned Cured Film>>

A resist organic underlayer film composition “AL412” (manufactured by Brewer Science, Inc.) was applied onto a 12-inch silicon wafer using a spin coater, and the coating film was baked on a hot plate at 205° C. for 60 seconds to form an organic underlayer film having a film thickness of 22 nm. The photosensitive composition in each example was applied onto the organic underlayer film using a spin coater, and a prebake (PAB) treatment to the coating film was carried out on a hot plate at 90° C. for 60 seconds to form a coating film having a film thickness of 30 nm.

Next, the coating film was irradiated with EUV light (13.5 nm) through a photomask by an EUV exposure apparatus NXE3400 (manufactured by ASML, NA (number of aperture)=0.33, illumination conditions: Annular σ—in=0.595, σ—out=0.817). Thereafter, post exposure bake (PEB) treatment was carried out for 60 seconds at 80° C.

Subsequently, in Examples 1 to 12 and Comparative Examples 1 to 3, development was carried out for 30 seconds with a 2.38% by mass tetramethylammonium hydroxide (TMAH) aqueous solution (product name: NMD-3, manufactured by Tokyo Ohka Kogyo Co., Ltd.) at 23° C. Thereafter, water rinsing was carried out with pure water for 30 seconds, and shake-off drying was carried out. In Examples 13 to 15, development was carried out for 13 seconds with butyl acetate at 23° C. As a result, a line and space pattern (LS pattern) having a line width of 14 nm was formed.

### [Evaluation of Optimum Exposure Amount (Eop)]

The optimum exposure amount Eop (mJ/cm²) at which an LS pattern having a line width of 14 nm was formed by the formation of the above-mentioned patterned cured film was determined. The results are shown in Table 2.

### [Evaluation of LWR (Line Width Roughness)]

Regarding an LS pattern having a line width of 14 nm formed by the formation of the patterned cured film mentioned above, 3σ, which is a scale indicating LWR, was determined.

The “3σ” indicates a triple value (3σ) (unit: nm) of a standard deviation (σ) determined from a measurement result obtained by measuring 400 line positions in a longitudinal direction of the line with a scanning electron microscope (acceleration voltage: 800 V, product name: S-9380, manufactured by Hitachi High-Technologies Corporation). The results are shown in Table 2. The roughness of the line sidewall is reduced as the 3σ value decreases, which means that a LS pattern with a more uniform width is obtained.

### [Evaluation of Dry Etching Resistance]

A photosensitive composition of each example was applied onto an 8-inch silicon wafer using a spin coater and baked on a hot plate at 90° C. for 60 seconds to form a coating film having a film thickness of 50 nm.

An organic film for comparison of etching resistance having a film thickness of 200 nm was formed by using a spin coater to coat an 8-inch silicon wafer with an 8 mass % propylene glycol monomethyl ether acetate solution of a cresol novolak resin (resin represented by the following formula, weight average molecular weight (Mw) in terms of polystyrene equivalent value measured by GPC: 33,000, molecular weight dispersion (Mw/Mn): 16.8) synthesized by a conventional method, followed by baking the coating film at 280° C. for 60 seconds on a hot plate.

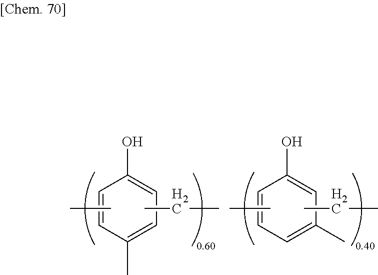

The cured film and the organic film for comparison of etching resistance were treated with a TCP dry etching apparatus (O₂ flow rate=5 sccm, Ar flow rate=15 sccm, pressure=0.05 Pa, temperature=0° C., plasma source RF output=200 W, bias RF Output=100 W) for 30 seconds.

Then, the etching speed ratio of each cured film formed by the photosensitive composition of each example to that of the organic film for comparison of etching resistance was calculated. The results are shown in Table 2.

It is shown that when the etching speed ratio is 0.5 or less, good etching resistance is achieved.

TABLE 2

| | | Eop | LWR | Silicon atom | Etching |
|---|---|---|---|---|---|
| | | (mJ/cm²) | (nm) | content rate | speed ratio |
| Example | 1 | 48 | 2.91 | 12% | 0.38 |
| | 2 | 49 | 2.88 | 9% | 0.46 |
| | 3 | 50 | 3.00 | 12% | 0.39 |
| | 4 | 48 | 2.95 | 12% | 0.37 |
| | 5 | 46 | 2.94 | 12% | 0.36 |
| | 6 | 51 | 2.99 | 11% | 0.42 |
| | 7 | 48 | 3.01 | 11% | 0.42 |
| | 8 | 46 | 2.86 | 11% | 0.42 |
| | 9 | 49 | 2.85 | 11% | 0.43 |
| | 10 | 51 | 3.03 | 14% | 0.32 |
| | 11 | 49 | 2.86 | 8% | 0.49 |
| | 12 | 50 | 2.91 | 8% | 0.50 |
| | 13 | 54 | 3.06 | 12% | 0.38 |
| | 14 | 48 | 3.01 | 12% | 0.38 |
| | 15 | 47 | 3.03 | 12% | 0.39 |
| Comparative | 1 | 48 | 3.26 | 12% | 0.38 |
| Example | 2 | 50 | 3.10 | 0% | 1.35 |
| | 3 | 50 | 3.08 | 0% | 1.31 |

From Table 2, it is shown that the photosensitive compositions of Examples 1 to 11 can form patterns with very small dimensions satisfying both etching resistance and lithography properties.

What is claimed is:

1. A photosensitive composition comprising a silicon-containing polymer (A) comprising a phenolic hydroxy group and an alkali-soluble group protected by an acid-dissociable group, and a photoacid generating agent (B),
wherein the photoacid generating agent (B) comprises a photoacid generating agent (B1) comprising a sulfonium cation comprising an iodine atom.

2. The photosensitive composition according to claim 1, wherein the sulfonium cation is a sulfonium cation represented by the following formula (b1-1): 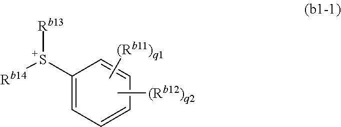
wherein in the formula (b1-1), R^{b11} represents an iodine atom, or —R^{b111}—X^{b1}, R^{b111} represents a divalent linking group not comprising an aromatic group, X^{b1} represents an aromatic group substituted with an iodine atom, R^{b12} represents a fluorine atom, a hydroxy group, a hydrocarbon group optionally having a substituent, or an alkoxy group optionally having a substituent, R^{b13} and R^{b14} each independently represents a hydrocarbon group optionally having a substituent, R^{b13} and R^{b14} optionally being bonded to each other to form a ring, q1 represents an integer of 1 or more and 4 or less, q2 represents an integer of 0 or more and 3 or less, and 1≤q1+q2≤4 is satisfied.

3. The photosensitive composition according to claim 2, wherein the divalent linking group not comprising an aromatic group as R^{b111} represents a divalent aliphatic hydrocarbon group or a group represented by the following formula (b1-1a): 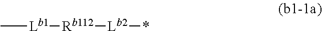
wherein in the formula (b1-1a), L^{b1} represents an ester bond, an amide bond, or an ether bond, L^{b2} represents a single bond, an ester bond, an amide bond, or an ether bond, R^{b112} represents a single bond or an alkylene group, and * represents a bonding bonded to X^{b1}.

4. The photosensitive composition according to claim 1,
wherein the silicon-containing polymer (A) comprises a constituent unit represented by the following formula (a1), and a constituent unit represented by the following formula (a2): 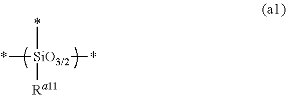
wherein in the formula (a1), R^{a11} represents an organic group having a phenolic hydroxy group, and * represents a bonding, 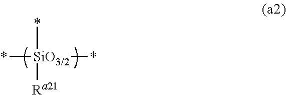
wherein in the formula (a2), R^{a21} represents an organic group having an alkali-soluble group protected by an acid-dissociable group, and * represents a bonding.

5. The photosensitive composition according to claim 4, wherein the R^{a21} represents a group represented by the following formula (a2-1) or a group represented by the following formula (a2-2): 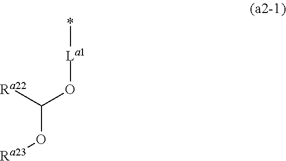
wherein in the formula (a2-1), L^{a1} represents a single bond or a divalent organic group, R^{a22} represents a hydrogen atom or a hydrocarbon group optionally having a substituent, R^{a23} represents a hydrogen atom or a hydrocarbon group optionally having a substituent, R^{a22} and R^{a23} are optionally bonded to each other to form a ring, and * represents a bonding. 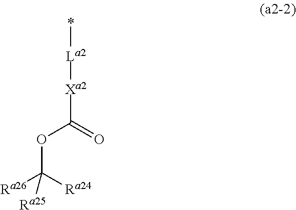
wherein in the formula (a2-2), L^{a2} represents a single bond or a divalent organic group, X^{a2} represents a single bond or O, R^{a24}, R^{a25}, and R^{a26} each independently represents a hydrocarbon group, two or more of R^{a24}, R^{a25}, and R^{a26} optionally bonded to each other to form a ring, and * represents a bonding.

6. The photosensitive composition according to claim 1, further comprising a base component (D) for controlling diffusion of an acid generated upon exposure.

7. The photosensitive composition according to claim 1, wherein a proportion of a mass of the silicon-containing polymer (A) to a mass of a solid content of the photosensitive composition is 10% by mass or more.

8. The photosensitive composition according to claim 1, further comprising a crosslinking agent (C).

9. The photosensitive composition according to claim 1, wherein the photosensitive composition is a positive type photosensitive composition.

10. A method for producing a patterned cured film, the method comprising:
forming a coating film made of the photosensitive composition according to claim 1 on a support;
exposing the coating film in a position-selective manner; and
developing the exposed coating film to form a patterned cured film.

11. The method for producing a patterned cured film according to claim 10, wherein the coating film is exposed to extreme ultraviolet.

12. The photosensitive composition according to claim 2, wherein the silicon-containing polymer (A) comprises a constituent unit represented by the following formula (a1), and a constituent unit represented by the following formula (a2), 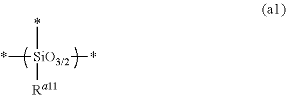
wherein in the formula (a1), R^{a11} represents an organic group comprising a phenolic hydroxy group, and * represents a bonding, 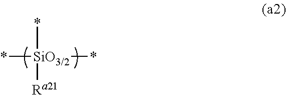
wherein in the formula (a2), R^{a21} represents an organic group comprising alkali-soluble group protected by an acid-dissociable group, and * represents a bonding.

13. The photosensitive composition according to claim 2, further comprising a base component (D) for controlling diffusion of an acid generated upon exposure.

14. The photosensitive composition according to claim 3, further comprising a base component (D) for controlling diffusion of an acid generated upon exposure.

15. The photosensitive composition according to claim 4, further comprising a base component (D) for controlling diffusion of an acid generated upon exposure.

16. The photosensitive composition according to claim 5, further comprising a base component (D) for controlling diffusion of an acid generated upon exposure.

17. The photosensitive composition according to claim 7, further comprising base component (D) for controlling diffusion of an acid generated upon exposure.

18. The photosensitive composition according to claim 8, further comprising a base component (D) for controlling diffusion of an acid generated upon exposure.

19. The photosensitive composition according to claim 12, further comprising a base component (D) for controlling diffusion of an acid generated upon exposure.

20. A method for producing a patterned cured film, the method comprising:
forming a coating film comprising the photosensitive composition according to claim 2 on a support,
exposing the coating film in a position-selective manner; and
developing the exposed coating film to form a patterned cured film.
